(19) United States
(12) Patent Application Publication
(10) Pub. No.: US 2009/0281267 A1
(43) Pub. Date: Nov. 12, 2009

(54) Material for planting and use thereof

(76) Inventors: Kanji Shimoosako, Kyotanabe-shi Kyoto (JP); Takashi Ito, Otsu-shi Shiga (JP); Shigeru Tanaka, Settsu-shi Osaka (JP); Masaru Nishinaka, Otsu-shi Shiga (JP); Mutsuaki Murakami, Settsu-shi Osaka (JP)

Correspondence Address: BIRCH STEWART KOLASCH & BIRCH, PO BOX 747, FALLS CHURCH, VA, 22040-0747, US

(21) Appl. No.: 11/919,246

(22) PCT Filed: Apr. 28, 2006
(86) PCT No.: PCT/JP2006/308936

§ 371 Date: Oct. 25, 2007

(30) Foreign Application Priority Data
Apr. 28, 2005 (JP) 2005-133737
May 13, 2005 (JP) 2005-141834
Aug. 9, 2005 (JP) 2005-231406
Aug. 11, 2005 (JP) 2005-233616
Aug. 11, 2005 (JP) 2005-233618

(51) Int. Cl. C08G 77/26; C09J 7/02; B32B 27/06; C08L 63/00; H05K 1/03

(52) U.S. Cl. 528/38; 428/354; 428/473.5; 525/403; 174/258

(57) ABSTRACT

A material for plating contains a resin layer to be subjected to electroless plating, and the resin layer contains polyimide resin having a specific structure. The material for plating has high adhesiveness with an electroless plating film formed on the surface of the resin layer even if surface roughness of the resin layer is low, and the material for plating also has high solder heat-resistance. Therefore, the material for plating is preferably applicable to manufacture of printed wiring boards etc.

### TECHNICAL FIELD

The present invention relates to a material for plating and use thereof. The present invention particularly relates to: a material for plating that is used for surfaces of various substrates when the surfaces are subjected to electroless plating, thereby improving adhesiveness between an electroless plating film and the surfaces of the substrates; and use thereof.

### BACKGROUND ART

Electroless plating is a plating technique for depositing a metal on a surface of a metal or a non-metal through reduction with a reducing agent without flowing an electric current (without using an electric energy) on the surface of the metal or the non-metal. The electroless plating is widely used for giving various functions to surfaces of insulating materials such as plastics, glasses, ceramics, and timbers. Examples of the electroless plating include: ornamental plating performed on ABS resin or polypropylene resin so as to make grills or marks of cars, knobs of home electric appliances etc.; and functional plating such as through-hole plating for printed wiring boards.

However, it is often that the electroless plating has low adhesiveness with surfaces of materials to be plated. In particular, in a case where electroless plating is used for manufacturing the printed wiring board, there is a technical problem that an electroless plating film has low adhesiveness with an insulating material.

In order to solve the above problem, a surface of an insulating resin material used for a printed wiring board is roughened through various methods so as to obtain adhesiveness with an electroless plating film through a so-called anchor effect (see Patent Document 1 for example). However, this technique is getting unable to meet recent requests for forming fine wires. This is because forming fine wires through this technique causes inclination, falling down etc. of wires due to large unevenness of the roughened surface. Therefore, in order to meet requests for forming fine wires, there is required a technique for firmly forming metal plating on a smooth surface of resin.

For that reason, a technique for firmly forming metal plating on a smooth surface of resin has been developed. For example, Patent Document 2 discloses a metal foil with resin made by applying a polyimidesiloxane precursor on a heat-resistant resin film and thereafter laminating a metal plating layer. However, Patent Document 2 juxtaposes, as a method for forming a metal layer, chrome sputter etc. and an electroless plating method. This shows that no consideration is given for a relation between (i) adhesive strength of an electroless plating film that is considered to have low adhesiveness with an insulating material and (ii) roughness of a surface to be subjected to electroless plating. Besides, Patent Document 2 does not read that the relation was confirmed. Further, Patent Document 2 does not describe solder heat-resistance that is an important property required for a printed wiring board etc. Application of electroless plating on a double-sided printed wiring board etc. makes both surfaces of some portion of a material covered by wiring pattern. If solder heat-resistance is low, blisters are produced on such surfaces.

Further, in a case of a process for manufacturing a printed wiring board, strong adhesiveness between metal plating and resin at a high temperature is required in order to allow the printed wiring board to be used in a repair step, that is, a step of exchanging an onboard electronic member considered to be defective as a result of examination. However, Patent Document 2 does not consider adhesiveness between metal plating and resin at a high temperature. Increasing the adhesiveness at a high temperature is much more difficult than increasing adhesiveness in an ordinary state.

[Patent Document 1] Japanese Unexamined Patent Publication No. 198907/2000 (Tokukai 2000-198907; published on Jul. 18, 2000).
[Patent Document 2] Japanese Unexamined Patent Publication No. 264255/2002 (Tokukai 2002-264255; published on Sep. 18, 2002).

### DISCLOSURE OF INVENTION

### Problems to be Solved by the Invention

As described above, there has not been found a material that assures high adhesiveness between a resin material and an electroless plating film even if surface roughness is low and that has solder heat-resistance sufficiently high for manufacture of printed wiring boards.

The present invention was made in view of the foregoing problems. An object of the present invention is to provide: a material for plating that is used for surfaces of various substrates when the surfaces are subjected to electroless plating, thereby improving adhesiveness between an electroless plating film and the surfaces of the substrates; and use thereof.

### Means to Solve the Problems

The inventors of the present invention made intensive studies in order to solve the problems and found that a material for plating as described below is capable of increasing adhesiveness with electroless plating and of increasing heat-resistance. Thus, the inventors completed the present invention. The present invention was completed based on this new finding and includes:

1) A material for plating, including a resin layer to be subjected to electroless plating, the resin layer containing polyimide resin having at least a siloxane structure, and the polyimide resin being obtained by causing an acid dianhydride component to react with a diamine component containing diamine represented by the following general formula (1)

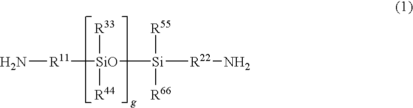

where g is an integer of 1 or more, R¹¹ and R²² are identical with each other or are different from each other and are selected from a C1-C6 alkylene group and a C1-C6 phenylene group, and R³³, R⁴⁴, R⁵⁵, and R⁶⁶ are identical with one another or are different from one another and are selected from a C1-C6 alkyl group, a C1-C6 phenyl group, a C1-C6 alkoxy group, and a C1-C6 phenoxy group.
2) The material for plating as set forth in 1), wherein the polyimide resin is made of a diamine component having 1 to 49 mol % of the diamine represented by the general formula (1) with respect to all diamines.
3) The material for plating as set forth in 1), wherein the resin layer further contains a thermosetting component.
4) The material for plating as set forth in 3), wherein the thermosetting component contains an epoxy resin component including an epoxy compound and a curing agent.
5) The material for plating as set forth in 1), wherein the polyimide resin has a glass-transition temperature ranging from 100 to 200° C.
6) The material for plating as set forth in 5), wherein the polyimide resin contains 10 to 75 mol % of the diamine represented by the general formula (1) with respect to all diamines.
7) The material for plating as set forth in 1), wherein the polyimide resin has a weight-average molecular weight Mw of 30000 to 150000 as determined by gel permeation chromatography.
8) The material for plating as set forth in 1), wherein the polyimide resin contains a functional group and/or a group obtained by protecting the functional group.
9) The material for plating as set forth in 8), wherein the functional group is at least one selected from a hydroxyl group, an amine group, a carboxyl group, an amide group, a mercapto group, and a sulfonic acid group.
10) The material for plating as set forth in any one of 1) to 9), wherein the electroless plating is electroless copper plating.
11) The material for plating as set forth in any one of 1) to 10), further comprising one or more layers other than the resin layer, the material for plating including at least two layers as a whole.
12) The material for plating as set forth in 11), wherein said one or more layers is a macromolecule film layer, and the resin layer to be subjected to electroless plating is formed on at least one surface of the macromolecule film layer.
13) The material for plating as set forth in 11), wherein said one or more layers are a macromolecule film layer and an adhesive layer, the resin layer to be subjected to electroless plating is formed on at least one surface of the macromolecule film layer, and the adhesive layer is formed on the other surface of the macromolecule film layer.
14) The material for plating as set forth in 12) or 13), wherein the macromolecule film layer is a non-thermoplastic polyimide film.
15) A single layer sheet, using a material for plating as set forth in any one of 1) to 10), the sheet being made only of the resin layer.
16) An insulating sheet, including a material for plating as set forth in any one of 11) to 14).
17) A laminate, obtained by laminating an electroless plating layer on a material for plating as set forth in any one of 1) to 14), a single layer sheet as set forth in 15), or an insulating sheet as set forth in 16).
18) A printed wiring board, including a material for plating as set forth in any one of 1) to 14), a single layer sheet as set forth in 15), or an insulating sheet as set forth in 16).
19) The printed wiring board as set forth in 18), wherein, in a case where surface roughness of the resin layer is less than 0.5 μm represented in arithmetic mean roughness Ra as measured at a cutoff value of 0.002 mm, adhesive strength at 150° C. between the resin layer and a plating layer is 5N/cm or more.
20) A solution for forming a resin layer to be subjected to electroless plating, including one selected from (i) polyimide resin having at least a siloxane structure and (ii) polyamide acid that is a precursor of the polyimide resin, the polyimide resin being obtained by causing an acid dianhydride component to react with a diamine component containing diamine represented by the general formula (1).
21) The solution as set forth in 20), wherein the polyimide resin is made of a diamine component having 1 to 49 mol % of the diamine represented by the general formula (1) with respect to all diamines.
22) The solution as set forth in 20), further including a thermosetting component.
23) The solution as set forth in 22), wherein the thermosetting component contains an epoxy resin component including an epoxy compound and a curing agent.
24) The solution as set forth in 20), wherein the polyimide resin has a glass-transition temperature ranging from 100 to 200° C.
25) The solution as set forth in 24), wherein the polyimide resin contains 10 to 75 mol % of the diamine represented by the general formula (1) with respect to all diamines.
26) The solution as set forth in 20), wherein the polyimide resin has a weight-average molecular weight Mw of 30000 to 150000 as determined by gel permeation chromatography.
27) The solution as set forth in 20), wherein the polyimide resin contains a functional group and/or a group obtained by protecting the functional group.
28) The solution as set forth in 27), wherein the functional group is at least one selected from a hydroxyl group, an amine group, a carboxyl group, an amide group, a mercapto group, and a sulfonic acid group.

For a fuller understanding of the nature and advantages of the invention, reference should be made to the ensuing detailed description taken in conjunction with the accompanying drawings.

### EFFECT OF THE INVENTION

The present invention includes a resin layer to be subjected to electroless plating and the resin layer contains polyimide resin having a specific structure. Therefore, application of the present invention on surfaces of various substrates when the substrates are subjected to electroless plating increases adhesiveness with electroless plating and also increases solder heat-resistance.

### BEST MODE FOR CARRYING OUT THE INVENTION

First, the following explains the underlying principle of the present invention. A resin layer (surface) containing polyimide resin having the predetermined siloxane structure is formed on a surface of a material to be subjected to electroless plating, and then electroless plating is carried out. At that time, the resin layer containing polyimide resin having the siloxane structure that realizes excellent adhesiveness with an electroless plating layer serves as an interlayer adhesive. Consequently, the electroless plating layer firmly adheres to the material on which the resin layer is formed. Further, the resin layer has better solder heat-resistance than a conventional adhesive resin layer. Further, because the resin layer has excellent adhesiveness with the electroless plating layer, it is unnecessary to increase surface roughness for plating. This is advantageous for making fine wires.

Taking advantage of the above excellent properties, the technique of the present invention is applicable to various ornamental plating and functional plating. The technique of the present invention is most preferably applicable to material for plating etc. for printed wiring boards, because the technique of the present invention has solder heat-resistance and allows firmly forming an electrolytic plating layer even when surface roughness is low.

The following explains embodiments of the present invention. The present invention is not limited to the following embodiments.

### 1. Material for Plating

The material for plating of the present invention includes a resin layer to be subjected to electroless plating. The resin layer includes polyimide resin having at least a siloxane structure. The polyimide resin is made by causing an acid dianhydride component and a diamine component including diamine represented by the general formula (1) to react chemically with each other. The polyimide resin is not particularly limited in terms of other specific structures.

That is, the material for plating may have any structure, may be any material, may have any form, shape, and size, as long as the material for plating includes the resin layer. Examples of the form of the material for plating include: sheet shape (film shape); a thick-layer shape (plate shape); a folded-sheet shape; a cylindrical shape; a box shape; and other complex three-dimensional shape. Further, the material for plating may be a single layer made of only the resin layer, or may be a laminate constituted of the resin layer and other layer (such as an adhesive layer for facing a configured circuit, and a macromolecule film layer).

### <1-1. Resin Layer>

The resin layer is a layer whose surface is to be subjected to electroless plating. Specific structures of the resin layer is not particularly limited as long as the resin layer contains polyimide resin having a siloxane structure represented by the general formula (1). The following details embodiments of characteristic structures of the resin layer used for the material for plating of the present invention.

<1-1-1. Resin Layer in a Case of Regulating a Composition Rate of a Diamine Component when Preparing Polyimide Resin>

The inventors of the present invention found that the amount of diamine having a predetermined siloxane structure (diaminosiloxane) that is a material of polyimide resin having a siloxane structure is related to solder heat-resistance, and the inventors studied the diaminosiloxane in detail. As a result, the inventors found that, when the rate of diamine having the siloxane structure represented by the general formula (1) is 1 to 49 mol % with respect to all diamines, it is possible to increase solder heat-resistance, which is very preferable.

The inventors are the first to pay attention to the amount of diamine having the siloxane structure in order to solve the problem. The present invention is characteristic in that it is based on the finding that usage of polyimide resin having a predetermined amount of the diaminosiloxane realizes a material capable of increasing adhesiveness with an electroless plating film and of increasing solder heat-resistance.

Specifically, it is preferable that the polyimide resin contains polyimide resin made of an acid dianhydride component and a diamine component including diamine represented by the general formula (1). That is, it is preferable that the polyimide resin is obtained by causing the acid dianhydride component and the diamine component represented by the general formula (1) to react with each other. The following explains the acid dianhydride component.

The acid dianhydride component used for the present invention can be selected from various types of acid dianhydride that are used for preparing conventionally publicly-known polyimide resin, and is not particularly limited in terms of its specific arrangement. Examples of the acid dianhydride component include: aromatic tetracarboxylic acid dianhydride such as pyromellitic acid dianhydride, 3,3′,4,4′-benzophenone tetracarboxylic acid dianhydride, 3,3′,4,4′-diphenylsulfone tetracarboxylic acid dianhydride, 1,4,5,8-naphthalene tetracarboxylic acid dianhydride, 2,3,6,7-naphthalene tetracarboxylic acid dianhydride, 3,3′,4,4′-dimethyldiphenylsilane tetracarboxylic acid dianhydride, 1,2,3,4-furan tetracarboxylic acid dianhydride, 4,4′-bis(3,4-dicarboxyphenoxy) diphenylpropanoic acid dianhydride, 3,3′,4,4′-biphenyl tetracarboxylic acid dianhydride, 2,3,3′,4′-biphenyl tetracarboxylic acid dianhydride, and p-phenylenediphthalic acid anhydride; 4,4′-hexafluoroisopropylidene diphthalic acid anhydride; 4,4′-oxydiphthalic acid anhydride, 3,4′-oxydiphthalic acid anhydride; 3,3′-oxydiphthalic acid anhydride, 4,4′-(4,4′-isopropylidenediphenoxy)bis(anhydrous phthalic acid); 4,4′-hydroquinonebis(anhydrous phthalic acid), 2,2-bis(4-hydroxyphenyl)propanedibenzoate-3,3′,4,4′-tetra carboxylic acid dianhydride; 1,2-ethylenebis(trimellitic acid monoester anhydride); and p-phenylenebis(trimellitic acid monoester anhydride). These components may be used separately. Alternatively, a combination of two or more of them can be used. In such a case, conditions such as a mixture ratio can be appropriately set by a person skilled in the art.

The following explains the diamine component. The diamine component represented by the general formula (1) is used in the present invention so as to obtain polyimide resin that firmly attaches to an electroless plating layer.

Specific examples of the diamine represented by the general formula (1) include 1,1,3,3-tetramethyl-1,3-bis(4-aminophenyl)disiloxane, 1,1,3,3-tetraphenoxy-1,3-bis(4-aminoethyl)disiloxane, 1,1,3,3,5,5-hexamethyl-1,5-bis(4-aminophenyl)trisiloxane, 1,1,3,3-tetraphenyl-1,3-bis(2-aminophenyl)disiloxane, 1,1,3,3-tetraphenyl-1,3-bis(3-aminopropyl)disiloxane, 1,1,5,5-tetraphenyl-3,3-dimethyl-1,5-bis(3-aminopropyl)trisiloxane, 1,1,5,5-tetraphenyl-3,3-dimethoxy-1,5-bis(3-aminobutyl)trisiloxane, 1,1,5,5-tetraphenyl-3,3-dimethoxy-1,5-bis(3-aminopentyl) trisiloxane, 1,1,3,3-tetramethyl-1,3-bis(2-aminoethyl)disiloxane, 1,1,3,3-tetramethyl-1,3-bis(3-aminopropyl)disiloxane, 1,1,3,3-tetramethyl-1,3-bis(4-aminobutyl)disiloxane, 1,3-dimethyl-1,3-dimethoxy-1,3-bis(4-aminobutyl)disiloxane, 1,1,5,5-tetramethyl-3,3-dimethoxy-1,5-bis(2-aminoethyl)trisiloxane, 1,1,5,5-tetramethyl-3,3-dimethoxy-1,5-bis(4-aminobutyl)ₜ risiloxane, 1,1,5,5-tetramethyl-3,3-dimethoxy-1,5-bis(5-aminopentyl) trisiloxane, 1,1,3,3,5,5-hexamethyl-1,5-bis(3-aminopropyl)trisiloxane, 1,1,3,3,5,5-hexaethyl-1,5-bis(3-aminopropyl)trisiloxane, and 1,1,3,3,5,5-hexapropyl-1,5-bis(3-aminopropyl)trisiloxane. Note that examples of relatively easily-obtainable ones of the diamine components represented by the general formula (1) include KF-8010, X-22-161 A, X-22-161B, X-22-1660B-3, KF-8008, KF-8012, and X-22-9362 (manufactured by Shin-Etsu Chemical Co., Ltd.). These diamine components may be used separately. Alternatively, a combination of two or more of them may be used.

Further, for the purpose of improving heat-resistance and moisture-resistance, the aforementioned diamine components can be used in combination with other diamine components. As the other diamine components, all types of diamine can be used, and the other diamine components are not particularly limited in terms of their specific arrangement. Specific examples of such diamines include m-phenylenediamine, o-phenylenediamine, p-phenylenediamine, m-aminobenzylamine, p-aminobenzylamine, bis(3-aminophenyl) sulfide, (3-aminophenyl) (4-aminophenyl) sulfide, bis(4-aminophenyl)sulfide, bis(3-aminophenyl)sulfoxide, (3-aminophenyl)(4-aminophenyl)sulfoxide, bis(3-aminophenyl) sulfone, (3-aminophenyl)(4-aminophenyl)sulfone, bis(4-aminophenyl)sulfone, 3,4′-diaminobenzophenone, 4,4′-diaminobenzophenone, 3,3′-diaminodiphenylmethane, 3,4′-diaminodiphenylmethane, 4,4′-diaminodiphenylmethane, 4,4′-diaminodiphenylether, 3,3′-diaminodiphenylether, 3,4′-diaminodiphenylether, bis[4-(3-aminophenoxy)phenyl]sulfoxide, bis[4-(aminophenoxy)phenyl]sulfoxide, 4,4′-diaminodiphenylether, 3,4′-diaminodiphenylether, 3,3′-diaminodiphenylether, 4,4′-diaminodiphenylthioether, 3,4′-diaminodiphenylthioether, 3,3′-diaminodiphenylthioether, 3,3′-diaminodiphenylmethane, 3,4′-diaminodiphenylmethane, 4,4′-diaminodiphenylmethane, 4,4′-diaminodiphenylsulfone, 3,4′-diaminodiphenylsulfone, 3,3′-diaminodiphenylsulfone, 4,4′-diaminobenzanilide, 3,4′-diaminobenzanilide, 3,3′-diaminobenzanilide, 4,4′-diaminobenzophenone, 3,4′-diaminobenzophenone, 3,3′-diaminobenzophenone, bis[4-(3-aminophenoxy)phenyl]methane, bis[4-(4-aminophenoxy)phenyl]methane, 1,1-bis[4-(3-aminophenoxy)phenyl]ethane, 1,1-bis[4-(4-aminophenoxy)phenyl]ethane, 1,2-bis[4-(3-aminophenoxy)phenyl]ethane, 1,2-bis[4-(4-aminophenoxy)phenyl]ethane, 2,2-bis[4-(3-aminophenoxy)phenyl]propane, 2,2-bis[4-(4-aminophenoxy)phenyl]propane, 2,2-bis[4-(3-aminophenoxy)phenyl]butane, 2,2-bis[3-(3-aminophenoxy)phenyl]-1,1,1,3,3,3-hexafluoro propane, 2,2-bis[4-(4-aminophenoxy)phenyl]-1,1,1,3,3,3-hexafluoro propane, 1,3-bis(3-aminophenoxy)benzene, 1,4-bis(3-aminophenoxy)benzene, 1,4′-bis(4-aminophenoxy)benzene, 4,4′-bis(4-aminophenoxy)biphenyl, bis[4-(3-aminophenoxy)phenyl]ketone, bis[4-(4-aminophenoxy)phenyl]ketone, bis[4-(3-aminophenoxy)phenyl]sulfide, bis[4-(4-aminophenoxy)phenyl]sulfide, bis[4-(3-aminophenoxy)phenyl]sulfone, bis[4-(4-aminophenoxy)phenyl]sulfone, bis[4-(3-aminophenoxy)phenyl]ether, bis[4-(4-aminophenoxy)phenyl]ether, 1,4-bis[4-(3-aminophenoxy)benzoyl]benzen, 1,3-bis[4-(3-aminophenoxy)benzoyl]benzen, 4,4′-bis[3-(4-aminophenoxy)benzoyl]diphenylether, 4,4′-bis[3-(3-aminophenoxy)benzoyl]diphenylether, 4,4′-bis[4-(4-amino-α,α-dimethylbenzyl)phenoxy]benzophenone, 4,4′-bis[4-(4-amino-α,α-dimethylbenzyl)phenoxy]diphenylsulfone, bis[4-{4-(4-aminophenoxy)phenoxy}phenyl]sulfone, 1,4-bis[4-(4-aminophenoxy)-α,α-dimethylbenzyl]benzene, 1,3-bis[4-(4-aminophenoxy)-α,α-dimethylbenzyl]benzene, and 3,3′-dihydroxy-4,4′-diaminophenyl.

It is preferable that the diaminosiloxane represented by the general formula (1) is 1 to 49 mol %, more preferably 3 to 45 mol %, and further more preferably 5 to 40 mol %, with respect to the whole diamine components. In a case where the diaminosiloxane is present in an amount of less than 1 mol % with respect to the whole diamine components, there is a reduction in the strength of adhesiveness between the resin layer including the polyimide resin and the electroless plating film. In a case where the diaminosiloxane is present in an amount of more than 49 mol % with respect to the whole diamine components, solder heat-resistance drops.

The polyimide resin is obtained by subjecting, to dehydration ring closure, a precursor of a polyamic acid polymer which corresponds to the polyimide resin. The precursor of polyamic acid polymer is obtained by causing a substantially equimolar reaction between an acid dianhydride component and a diamine component. The method for preparing the polyimide resin may be carried out under the same conditions as those of conventionally publicly known methods for preparing polyimide resin and is not particularly limited, except that the method uses the acid dianhydride component and the diamine component. The following explains representative processes for preparing the polyamic acid polymer solution.

Examples of representative methods for the polymerization are as follows.

(1) An aromatic diamine compound is dissolved in an organic polar solvent, and polymerization is performed by causing a reaction between the diamine compound and a substantially equimolar amount of an aromatic tetracarboxy acid dianhydride.

(2) Aromatic tetracarboxylic acid dianhydride and an excessively small molar amount of an aromatic diamine compound are allowed to react with each other in an organic polar solvent, with the result that a prepolymer having acid anhydride groups at both terminals thereof is obtained. Then, polymerization is performed in a single-stage or multistage manner with use of an aromatic diamine compound so that an aromatic tetracarboxylic acid dianhydride and the aromatic diamine compound that are used in all steps are present in substantially equimolar amounts.

(3) Aromatic tetracarboxylic acid dianhydride and an excessively large molar amount of aromatic diamine compound are allowed to react with each other in an organic polar solvent, with the result that a prepolymer having amino groups at both terminals thereof is obtained. Then, after the addition of the aromatic diamine compound to the organic polar solvent, polymerization is performed in a single-stage or multistage manner with use of aromatic tetracarboxylic acid dianhydride so that the aromatic tetracarboxylic acid diandhydride and the aromatic diamine compound that are used in all steps are present in substantially equimolar amounts.

(4) After aromatic tetracarboxylic acid dianhydride has been dissolved and/or dispersed in an organic polar solvent, polymerization is performed with use of an aromatic diamine compound so that the aromatic carboxylic acid dianhydride and the aromatic diamine compound are present in substantially equimolar amounts.

(5) Polymerization is performed by allowing a mixture of substantially equimolar amounts of aromatic tetracarboxylic acid dianhydride and an aromatic diamine compound to react with each other in an organic polar solvent.

These methods may be performed singularly, or may be performed with parts of them being combined.

The term “dissolution” used in this specification includes, in addition to a case where a solvent completely dissolves a solute, a case where a solute is uniformly dispersed in a solvent or dispersed so as to be seconds away from being substantially dissolved in the solvent. Reaction time and reaction temperature during which and at which a polyamic acid polymer is prepared can be set in the usual manner, and are not particularly limited.

An organic polar solvent for use in a polymerization reaction of polyamic acid can be suitably selected, in accordance with the aforementioned diamine component and the aforementioned acid dianhydride component, from solvents that are used for preparing conventionally publicly-known polyamic acid, and is not particularly limited. Examples of such organic polar solvents include: sulfoxide solvents such as dimethyl sulfoxide and diethyl sulfoxide; formamide solvents such as N,N-dimethyl formamide and N,N-diethyl formamide; acetoamide solvents such as N,N-dimethyl acetoamide and N,N-diethyl acetoamide; pyrrolidone solvents such as N-methyl-2-pyrrolidone and N-vinyl-2-pyrrolidone; phenol solvents such as phenol, o-, m-, or p-cresol, xylenol, halogenated phenol, and catechol; hexamethyl phosphoramide; and γ-butyrolactone. Furthermore, according to need, these organic polar solvents can be used in combination with an aromatic hydrocarbon such as xylene or toluene.

A solution of the polyamic acid polymer obtained by the method is subjected to dehydration ring closure by a thermal or chemical method, so that polyimide resin is obtained. The solution of the polyamic acid polymer can be subjected to dehydration ring closure appropriately in the usual manner, and a specific method therefor is not particularly limited. For example, a thermal method of dehydrating a polyamic acid solution by heat-treating it or a chemical method of performing dehydration by using a dehydrating agent can be used. Further, a method of performing imidization by heating under reduced pressure can be used. The following explains each of the methods.

Examples of the thermal method for dehydration ring closure include a method of evaporating a solvent while accelerating an imidization reaction by heat-treating the polyamic acid solution. This method makes it possible to obtain solid polyimide resin. The conditions for heating are not particularly limited. However, it is preferable that heating be performed for a period of 1 second to 200 minutes at a temperature of not more than 200° C.

Further, examples of the chemical method for dehydration ring closure include a method of evaporating an organic solvent by causing a dehydration reaction through the addition of not less than stoichiometric quantities of a dehydrating agent and a catalyst to the polyamic acid solution. This makes it possible to obtain solid polyimide resin. Examples of the dehydrating agent include aliphatic acid anhydride such as anhydrous acetic acid and aromatic acid anhydride such as anhydrous benzoic acid. Further, examples of the catalyst include aliphatic tertiary amines such as triethylamine, aromatic tertiary amines such as dimethylaniline, and heterocyclic tertiary amines such as pyridine, α-picoline, β-picoline, γ-picoline, and isoquinoline. The conditions for chemical dehydration ring closure preferably include a temperature of not more than 100° C. The organic solvent is preferably evaporated within a period of approximately 5 minutes to 120 minutes at a temperature of not more than 200° C.

Further, there is another method for obtaining polyimide resin. This method excludes the evaporation of a solvent from the aforementioned thermal or chemical method for dehydration ring closure. Specifically, first, polyimide resin is deposited by pouring, into a poor solvent, a polyimide solution obtained by performing a thermal imidization process or a chemical imidization process. Thereafter, solid polyimide resin is obtained by removing an unreacted monomer from the polyimide resin thus deposited, and then by purifying and drying the polyimide resin from which the unreacted monomer has been removed. The poor solvent preferably has such properties as to be mixed well with a solvent but unlikely to dissolve polyimide resin. Examples of the poor solvent include, but are not limited to, acetone, methanol, ethanol, isopropanol, benzene, methyl cellosolve, and methyl ethyl ketone; various types of conventionally publicly-known solvent that have such properties can be used.

The following explains a method for imidizing a polyamic acid polymer solution by heating it under reduced pressure. According to this method for imidization, water generated by imidization is removed from a system. This makes it possible to inhibit hydrolysis of polyamic acid, thereby making it possible to obtain a high-molecular weight of polyimide. Further, according to this method, an opened-ring product, contained as impurities in acid dianhydride serving as raw material, whose either or both rings are opened is subjected to ring closure again. Therefore, it is expected that a higher-molecular weight of polyimide is obtained.

The heating conditions for the method for imidization by heating under reduced pressure preferably include a temperature range of 80° C. to 400° C., more preferably not less than 100 C, at which imidization is efficiently performed and water is efficiently removed, or even more preferably not less than 120° C. The maximum temperature is preferably not more than a temperature at which the target polyimide resin is thermally decomposed, and is usually a temperature at which normal imidization is completed, i.e., a temperature of approximately 250° C. to 350° C.

It is preferable that the pressure to be reduced be lower. Specifically, it is preferable that the pressure to be reduced be in a range of 1×10⁴ to 1×10² Pa, preferably 8×10⁴ to 1×10² Pa, and more preferably 7×10⁴ to 1×10² Pa. This is because in a case where the pressure to be reduced is low, a reduction in efficiency of removal of water generated by imidization may prevent the imidization from sufficiently progressing, or may cause a reduction in molecular weight of the resulting polyimide.

The foregoing has explained polyimide resin. Examples of relatively easily-obtainable polyimide resin, containing a siloxane structure, which can be used for the resin layer of the present invention include X-22-8917, X-22-8904, X-22-8951, X-22-8956, X-22-8984, and X-22-8985 that are manufactured by Shin-Etsu Chemical Co., Ltd. They are commercially available in the form of a polyimide solution.

For the purpose of improving various properties such as heat resistance, moisture resistance, and elastic modulus at a high temperature, it is possible to allow the resin layer to contain other thermoplastic resin or thermosetting resin in addition to the aforementioned polyimide resin. Examples of the thermoplastic resin include a polysulfone resin, a polyethersulfone resin, a polyphenyleneether resin, a phenoxy resin, and a thermoplastic polyimide resin (that does not have a siloxane structure). These thermoplastic resins can be used separately or in combination.

Further, examples of the thermosetting resin include a bismaleimide resin, a bisallylnadiimide resin, a phenol resin, a cyanate resin, an epoxy resin, an acrylic resin, a methacrylic resin, a triazine resin, a hydrosilyl cured resin, an allyl cured resin, and an unsaturated polyester resin. These thermosetting resins can be used separately or in combination. In addition to the aforementioned thermosetting resins, thermosetting polymers containing a reactive group in side chains can also be used. The thermosetting polymers containing a reactive group in side chains are those thermosetting polymers which have a reactive group such as an epoxy group, an allyl group, a vinyl group, an alkoxysilyl group or a hydrosilyl group in the side chains or terminals of polymer chains.

Furthermore, for the purpose of improving adhesiveness with the electroless plating layer, the resin layer can be allowed to contain additives through the addition of the additives to the resin layer, the application of the additives to a surface of the resin layer, or the like. As the various additives, conventionally publicly-known components can be suitably used to such an extent that the foregoing purpose is achieved, and the various additives are not particularly limited. Specific examples of the various additives include organic thiol compounds.

The resin layer can be allowed to contain conventionally publicly-known additives as needed in addition to the aforementioned components. Examples of such conventionally publicly-known additives include antioxidants, light stabilizers, fire retardants, antistatic agents, heat stabilizers, ultraviolet absorbers, conductive fillers (various organic fillers and inorganic fillers), inorganic fillers, and various reinforcing agents. These additives can be appropriately selected in accordance with the type of polyimide resin, and are not limited in terms of type. Further, these additives may be used separately or in combination. Note that the conductive fillers are those fillers which are obtained by giving conductivity to various base material substances by covering the base material substances with conductive substances such as carbon, graphite, metal particles, and indium tin oxide. By adding organic fillers and inorganic fillers, it is possible to make surface roughness be in such an extent that formation of fine wires is not prevented, thereby improving adhesiveness with an electroless plating film.

However, it is preferable that the aforementioned other various components be added to the resin layer in adherence with the objects of the present invention. That is, it is preferable that the other various components be added to the resin layer so as not to increase the surface roughness of the resin layer to such an extent that the formation of fine wires is adversely affected. Further, it is preferable that the other various components be added to the resin layer in such combination as not to cause a reduction in adhesiveness between the resin layer and the electroless plating layer.

Further, it is preferable that the resin layer has a thickness of not less than 10 Å.

Further, the material for plating may be a sheet-shape (alternatively, film-shape). In a case where the material for plating is a sheet-shape, the material for plating may be a sheet-shape laminate made of a resin layer and other layer, or may be a single sheet-shape layer made of only the resin layer. In a case where the material for plating is a sheet-shape laminate, the resin layer is formed on at least one surface (alternatively, on both surfaces) of the sheet. In a case where the material for plating is a single sheet-shape layer, both surfaces of the sheet can be used as a surface on which an electroless plating layer is to be formed.

Note that, in a case where the material for plating is a sheet-shape (alternatively, film-shape), it is preferable that some kind of an inserting paper (protecting sheet) is provided on the sheet. In a case where the sheet is made by flow-casting, applying, and drying a resin solution on a supporter, the supporter can be used as an inserting paper. That is, the sheet-shape material for plating is integrally laminated on the supporter and thereafter the supporter is detached, so that the supporter serves as an inserting paper. Preferable examples of the supporter include: resin films such as PET; and metal foils such as aluminum foils and copper foils. Another method is detaching the sheet-shape material for plating from the supporter and attaching, to the sheet-shape material for plating, a resin sheet (ex. Teflon®) as a new inserting paper. In either cases, it is preferable that the inserting paper can be detached from the resin layer and the inserting paper is smooth enough not to make, on the surface of the resin layer, unevenness or scars that impair formation of fine wires.

Further, the resin layer is advantageous in that the resin layer has high adhesiveness with the electroless plating layer even when surface roughness is low. The surface roughness of the present invention can be represented in arithmetic mean roughness Ra as measured at a cutoff value of 0.002 mm. Note that the term “arithmetic mean roughness Ra” is defined in JIS B 0601 (revised on Feb. 1, 1994). Particularly, the numerical value of “arithmetic mean roughness Ra” used in the present invention refers to a numerical value calculated by observing a surface with optical interferotype surface structure analyzer. The term “cutoff value” used in this present invention is described in JIS B 0601 mentioned above, and refers to a wavelength that is to be set in obtaining a roughness curve from a profile curve (actual measurement data). That is, the “value Ra of arithmetic mean roughness as measured at a cutoff value of 0.002 mm” is an arithmetic mean roughness calculated from a roughness curve obtained by removing, from actual measurement data, irregularities having a wavelength longer than 0.002 mm.

It is preferable that the surface roughness of the resin layer be less than 0.5 μm in arithmetic mean roughness Ra as measured at a cutoff value of 0.002 mm. In a case where this condition is satisfied, especially when the material for plating is used for a printed wiring board, excellent fine wires can be obtained. In order that the resin layer has such a surface, it is preferable that the resin layer is not subjected to physical surface roughness such as sandblasting.

With the arrangement, the resin layer has high adhesiveness with the electroless plating layer without surface roughening. Further, the material for plating of the present invention has high adhesiveness with other materials. Therefore, the material for plating of the present invention is advantageous in that: when the material for plating of the present invention is formed on a surface of a material to be subjected to electroless plating and then electroless plating is carried out, the material for plating of the present invention and the electroless plating firmly attach to each other. Further, as the material for plating of the present invention has a predetermined amount of polyimide resin having a predetermined structure, the material for plating of the present invention has high solder heat-resistance. Accordingly, the material for plating of the present invention is preferably applicable to manufacture of printed wiring boards. Further, as the material for plating of the present invention has high adhesiveness with an electroless plating layer without surface roughening and has sufficient solder heat-resistance, the material for plating of the present invention is preferably applicable to manufacture of printed wiring boards such as flexible printed wiring boards, rigid printed wiring boards, multi-layered flexible printed wiring boards, and build-up wiring boards that require formation of fine wires.

### <1-1-2. Resin Layer Including Polyimide Resin and Thermosetting Component>

The following explains another embodiment of the present invention. It is preferable that the resin layer is a layer whose surface is to be subjected to electroless plating, and the resin layer includes polyimide resin having a siloxane structure represented by the general formula (1) and a thermosetting component. The resin layer is not particularly limited in terms of other specific arrangements.

Out of explanations of the polyimide resin, an explanation identical with that of <1-1-1> is omitted here and an explanation different from that of <1-1-1> is made here. The explanation different from that of <1-1-1> relates to a composition rate of diamine having a siloxane structure represented by the general formula (1) out of diamine components. Specifically, the diamine represented by the general formula (1) is present in an amount preferably ranging from 5 to 98 mol %, more preferably from 8 to 95 mol %, with respect to all diamine components. This is because: when the diamine represented by the general formula (1) is present in an amount of less than 5 mol % with respect to all diamine components, there is a possibility that the resulting polyimide resin does not have sufficient adhesiveness with a plating copper layer. Further, when the diamine represented by the general formula (1) is present in an amount of more than 98 mol % with respect to all diamine components, there is a possibility that the resulting polyimide resin has too much viscosity, which impairs operativity. As described above, the polyimide resin having viscosity is unpreferable because there is a possibility that foreign matters such as dusts attach to the polyimide resin and the foreign matters cause defective plating when plating copper is formed. For that reason, the diamine represented by the general formula (1) is contained in all diamine components preferably at a ratio of 5 to 98 mol % with respect to all diamine components. When the diamine is contained at a ratio of 8 to 95 mol % with respect to all diamine components, the resulting polyimide resin is in a further preferable state.

The explanation in <1-1-2> is different from the explanation in <1-1-1> in that the resin layer includes a thermosetting component as well as polyimide resin. Except for this point, the explanation in <1-1-1> is applicable to the explanation in <1-1-2>.

The following explains the thermosetting component used in the resin layer. Conventionally publicly-known resin having a thermosetting property is preferably used as the thermosetting component. The thermosetting component is not particularly limited in terms of its specific arrangements. Examples of the resin constituting the thermosetting component include a bismaleimide resin, a bisallylnadiimide resin, a phenol resin, a cyanate resin, an epoxy resin, an acrylic resin, a methacrylic resin, a triazine resin, a hydrosilyl cured resin, an allyl cured resin, and an unsaturated polyester resin. These thermosetting resins can be used separately or in combination.

In addition to the aforementioned thermosetting components, thermosetting polymers containing a reactive group in side chains can also be used. The thermosetting polymers containing a reactive group in side chains are those thermosetting polymers which have a reactive group such as an epoxy group, an allyl group, a vinyl group, an alkoxysilyl group or a hydrosilyl group in the side chains or terminals of polymer chains. In order to improve heat-resistance, adhesiveness etc., an additive may be added to the thermosetting component as needed. Examples of the additive include: a radical reaction initiator such as organic peroxide; a reaction accelerator; triallyl cyanurate; triallyl isocyanurate; a generally-used epoxy-curing agent such as acid dianhydride family, amine family, and imidazole family; a cross-linking auxiliary agent; and various coupling agents.

Out of these thermosetting components, it is preferable to use a thermosetting component that contains an epoxy resin component including an epoxy compound and a curing agent. This is because epoxy resin is superior in its workability, electric properties etc. The following details an example of the present invention to which epoxy resin is applied as a thermosetting component. However, the present invention is not limited to this example.

The epoxy resin of the present invention may be any epoxy resin as long as it has two or more reactive epoxy groups in molecules. Specific examples of the epoxy resin include: epoxy resins such as a bisphenol epoxy resin, a bisphenol A novolak epoxy resin, a biphenyl epoxy resin, a phenol novolak epoxy resin, an alkyl phenol novolak epoxy resin, a polyglycolic epoxy resin, a cyclic aliphatic epoxy resin, a cresol novolak epoxy resin, a glycidyl amine epoxy resin, a naphthalene epoxy resin, an urethane-modified epoxy resin, a rubber-modified epoxy resin, and an epoxy-modified polysiloxane; halogenated ones of the above epoxy resins; and crystalline epoxy resins having a melting point. These epoxy resins may be used singularly, or two or more of these resins may be used in combination at any rate.

Out of these epoxy resins, it is more preferable to use: an epoxy resin having at least one aromatic ring and/or aliphatic ring in molecular chains; a biphenyl epoxy resin having a biphenyl structure; a naphthalene epoxy resin having a naphthalene structure, and a crystalline epoxy resin having a melting point. These epoxy resins are easily-available, have high compatibility, and make cured resin highly heat-resistive and highly insulative.

Out of the above epoxy resins, it is further more preferable to use the crystalline epoxy resin or an epoxy resin represented by the following formulae:

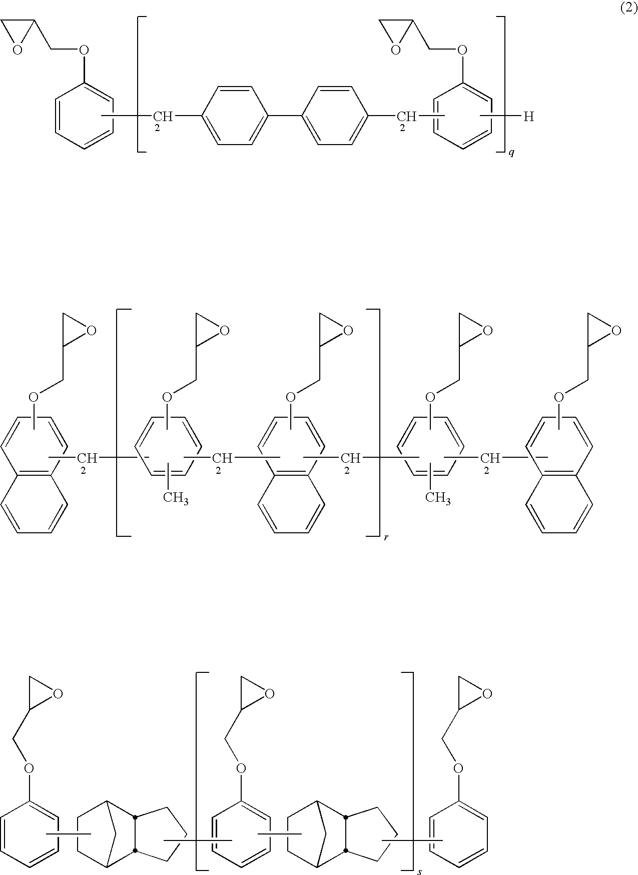

where q, r, and s are independently indicative of any integer. By using these epoxy resins, it is possible to provide the material for plating of the present invention with properties such as heat-resistance, and to make the properties balanced well.

The crystalline epoxy resin is not particularly limited as long as it has a melting point and a crystalline structure. Specifically, preferable examples of the crystalline epoxy resin include: YX4000H (manufactured by Japan Epoxy Resins Co., Ltd., biphenyl epoxy resin) and EXA7337 (manufactured by Dainippon Ink Incorporated, xanthene epoxy resin).

The epoxy resin of the present invention may be any one of the above epoxy resins. However, it is preferable that the epoxy resin has high-purity. When the epoxy resin having high-purity is used for the material for plating of the present invention, the material for plating can be electrically insulative with high-reliability. In the present invention, the reference of the high-purity is density with which halogen and alkaline metal are contained in epoxy resin. Specifically, the density with which the halogen and alkaline metal are contained in epoxy resin is preferably not more than 25 ppm, and further preferably not more than 15 ppm in a case where the halogen and the alkaline metal are extracted at 120° C. and under 2 atmospheric pressures. When the density with which the halogen and the alkaline metal are contained is higher than 25 ppm, the cured resin gets unreliable in terms of its electric insulation property.

Further, as for the resin layer of the present invention containing polyimide resin (thermoplastic polyimide) having a siloxane structure and a thermosetting component, it is preferable that an epoxy group contained in 100 g of a resin composition constituting the resin layer and a hydroxyl group resulting from a ring-opening reaction of the epoxy group are present in amounts ranging from 0.01 mol to 0.2 mol. As for the epoxy resin used for the thermosetting component of the present invention, it is preferable that the amount of the epoxy resin to be combined with the polyimide resin component having the siloxane structure is determined in consideration of an epoxy value (epoxy equivalent weight) of the epoxy resin.

That is, in a case where epoxy resin whose epoxy equivalent weight is large is used, even if a composition amount of the epoxy resin is larger compared with a case where epoxy resin whose epoxy equivalent weight is small, it is possible that the number of moles of the epoxy group contained in 100 g of the resin composition constituting the resin layer and the hydroxyl group resulting from the ring-opening reaction are 0.2 mol or less.

Compounding too much epoxy resin means that less amount of polyimide resin is compounded. At that time, excellent properties of polyimide resin such as dielectric property, electric insulation property, and adhesiveness with electroless plating tend to drop.

That is, in order to realize, in a good balance, adhesiveness, heat-resistance, electric insulation property etc. of the material for plating of the present invention, it is required that number of moles of the epoxy group contained in 10 g of the resin composition constituting the resin layer and number of moles of the hydroxyl group resulting from the ring-opening reaction of the epoxy group are 0.2 mol or less. Further, it is preferable to select epoxy resin whose epoxy equivalent weight is suitable for determining composition amounts.

On the other hand, compounding too little epoxy resin means that solder heat-resistance drops. For that reason, it is preferable that number of moles of the epoxy group contained in 100 g of the resin composition constituting the resin layer and number of moles of the hydroxyl group resulting from the ring-opening reaction of the epoxy group are 0.1 mol or more.

In consideration of the above, the epoxy equivalent weight of the epoxy resin to be used is preferably 150 or more, more preferably 170 or more, and most preferably 190 or more. Further, the upper limit of the epoxy value of the epoxy resin is preferably 700 or less, more preferably 500 or less, and most preferably 300 or less. Therefore, the epoxy value of the epoxy is preferably not less than 150 and not more than 700.

This is because: in a case where the epoxy equivalent weight of the epoxy resin curing component is less than 150, the composition amount of the epoxy resin is required to be small in order that number of moles of the epoxy group contained in 10 g of the resin composition including the polyimide resin and the thermosetting component and number of moles of the hydroxyl group resulting from the ring-opening reaction of the epoxy group are 0.2 or less. This reduces solder heat-resistance of the material for plating of the present invention. On the other hand, in a case where the epoxy value is more than 700, crosslinking density of the cured resin drops. This may reduce solder heat-resistance.

It is preferable that the epoxy resin used in the thermosetting component of the material for plating of the present invention is cured by a suitable curing agent or a suitable curing accelerator.

The curing agent for the epoxy resin is not particularly limited as long as it is a compound having two or more active hydrogens in one molecule. Examples of an active hydrogen source include functional groups such as an amino group, a carboxyl group, a phenol hydroxyl group, an alcoholic hydroxyl group, and a thiol group. Compounds containing these functional groups are preferably used. Out of these compounds, it is particularly preferable to use an amine epoxy curing agent having an amino group, and a polyphenol epoxy curing agent having a phenol hydroxyl group. Usage of the epoxy curing agent allows obtaining a material for plating having well-balanced properties.

Examples of the polyphenol epoxy curing agent include phenolnovolak, xylylenenovolak, bisphenol A novolak, triphenylmethanenovolak, biphenylnovolak, and dicyclopentadienephenolnovolak. The polyphenol epoxy curing agent is not particularly limited in terms of its specific arrangements. Note that, in order to realize high dielectric property, hydroxy equivalent weight of the polyphenol epoxy curing agent is preferably large. The hydroxy equivalent weight is preferably 100 g/eq or more, more preferably 150 g/eq or more, and further more preferably 200 g/eq or more.

Further, the amine epoxy curing agent component includes at least one amine component. The amine epoxy curing agent component may be conventionally publicly-known amine epoxy curing agent component. Examples of the amine epoxy curing agent component include: monoamines such as aniline, benzylamine, and aminohexane; diamines that were cited as diamine components used in the aforementioned manufacture of polyamide acid; and polyamines such as diethylenetriamine, tetraethylenepentaamine, and pentaethylenehexamine.

Further, out of the above amines, it is preferable to use aromatic diamine. It is preferable that the above amine contains aromatic diamine whose molecular weight is 300 or more. It is more preferable that the above amine contains aromatic diamine whose molecular weight is 300 or more and 600 or less. Usage of the above aromatic diamine allows the cured resin to have good heat-resistance and good dielectric property. Further, in a case where the molecular weight of the aromatic diamine is less than 300, the cured resin contains more polar groups in its structure, and as a result dielectric property may be impaired. That is, the dielectric ratio and the dielectric dissipation factor of the cured resin may increase. On the other hand, in a case where the molecular weight is more than 600, crosslinking density of the cured resin drops and as a result heat-resistance may be impaired.

It is preferable that the aromatic diamine is conventionally publicly-known aromatic diamine and is not particularly limited. Specific examples of the aromatic diamine include 1,4-diaminobenzene, 1,3-diaminobenzene, 2,5-dimethyl-1,4-diaminobenzene, 1,2-diaminobenzene, benzidine, 3,3′-dichlorobenzidine, 3,3′-dimethylbenzidine, 3,3′-dimethoxybenzidine, 3,3′-dihydroxybenzidine, 3,3′,5,5′-tetramethylbenzidine, 2,2′-dimethyl-4,4′-diaminobiphenyl, 2,2′-bis(trifluoromethyl)-4,4′-diaminobiphenyl, 3,3′-diaminodiphenylmethane, 3,4′-diaminodiphenylmethane, 4,4′-diaminodiphenylmethane, 4,4′-diaminodiphenylpropane, 4,4′-diaminodiphenylhexafluoropropane, 4,4′-diaminodiphenylsilane, 4,4′-diaminodiphenyldiethylsilane, 4,4′-diaminodiphenylethylphosphineoxide, 4,4′-diaminodiphenyl N-methylamine, 4,4′-diaminodiphenyl N-phenylamine, 3,3′-diaminodiphenylether, 3,4′-diaminodiphenylether, 4,4′-diaminodiphenylether, 3,3′-diaminodiphenylthioether, 3,4′-diaminodiphenylthioether, 4,4′-diaminodiphenylthioether, 3,3′-diaminodiphenylsulfone, 3,4′-diaminodiphenylsulfone, 4,4′-diaminodiphenylsulfone, 3,3′-diaminobenzanilide, 3,4′-diaminobenzanilide, 4,4′-diaminobenzanilide, 3,3′-diaminobenzophenone, 3,4′-diaminobenzophenone, 4,4′-diaminobenzophenone, 1,3-bis(3-aminophenoxy)benzene, 1,3-bis(4-aminophenoxy)benzene, 1,4-bis(3-aminophenoxy)benzene, 1,4-bis(4-aminophenoxy)benzene, bis[4-(3-aminophenoxy)phenyl]methane, bis[4-(4-aminophenoxy)phenyl]methane, 1,1-bis[4-(3-aminophenoxy)phenyl]ethane, 1,1-bis[4-(4-aminophenoxy)phenyl]ethane, 1,2-bis[4-(3-aminophenoxy)phenyl]ethane, 1,2-bis[4-(4-aminophenoxy)phenyl]ethane, 2,2-bis[4-(3-aminophenoxy)phenyl]propane, 2,2-bis[4-(4-aminophenoxy)phenyl]propane, 2,2-bis[4-(3-aminophenoxy)phenyl]butane, 2,2-bis[4-(4-aminophenoxy)phenyl]butane, 2,2-bis[4-(3-aminophenoxy)phenyl]-1,1,1,3,3,3-hexafluoro propane, 2,2-bis[4-(4-aminophenoxy)phenyl]-1,1,1,3,3,3-hexafluoro propane, 4,4′-bis(3-aminophenoxy)biphenyl, 4,4′-bis(4-aminophenoxy)biphenyl, bis[4-(3-aminophenoxy)phenyl]ketone, bis[4-(4-aminophenoxy)phenyl]ketone, bis[4-(3-aminophenoxy)phenyl]sulfide, bis[4-(4-aminophenoxy)phenyl]sulfide, bis[4-(3-aminophenoxy)phenyl]sulfone, bis[4-(4-aminophenoxy)phenyl]sulfone, bis[4-(3-aminophenoxy)phenyl]ether, bis[4-(4-aminophenoxy)phenyl]ether, 1,4-bis[4-(3-aminophenoxy)benzoyl]benzene, 1,3-bis[4-(3-aminophenoxy)benzoyl]benzene, 4,4′-bis[3-(4-aminophenoxy)benzoyl]diphenylether, 4,4′-bis[3-(3-aminophenoxy)benzoyl]diphenylether, 4,4′-bis[4-(4-amino-α,α-dimethylbenzyl)phenoxy]benzophenone, 4,4′-bis[4-(4-amino-α,α-dimethylbenzyl)phenoxy]diphenylsulfone, bis[4-{4-(4-aminophenoxy)phenoxy}phenyl]sulfone, 1,4-bis[4-(4-aminophenoxy)-α,α-dimethylbenzyl]benzene, 1,3-bis[4-(4-aminophenoxy)-α,α-dimethylbenzyl]benzene, 1,5-diaminonaphthalene, 9,9′-bis(4-aminophenyl)fluorene. These diamines may be used singularly or two or more of them may be used in combination at any rate.

Out of them, it is more preferable to use 2,2-bis[4-(3-aminophenoxy)phenyl]propane, 2,2-bis[4-(4-aminophenoxy)phenyl]propane, 2,2-bis[3-(3-aminophenoxy)phenyl]-1,1,1,3,3,3-hexafluoro propane, 2,2-bis[4-(4-aminophenoxy)phenyl]-1,1,1,3,3,3-hexafluoro propane, bis[4-(3-aminophenoxy)phenyl]sulfone, bis[4-(4-aminophenoxy)phenyl]sulfone, bis[4-(3-aminophenoxy)phenyl]ether, and bis[4-(4-aminophenoxy)phenyl]ether. These compounds are preferable due to their handleability such as high solubility and high availability etc. Further, when the amino component contains these compounds, the cured resin increases its properties such as heat-resistance (e.g. high glass-transition temperature) and dielectric property.

As for the composition amount of the polyimide resin and the thermosetting component, the thermosetting component is preferably 1 to 100 weight parts, more preferably 3 to 70 weight parts, and most preferably 5 to 50 weight parts with respect to 100 weight parts of the polyimide resin. Note that, the composition amount of the cured resin and the curing agent in the curing component differs according to the kinds of the cured resin and curing agent, and therefore the composition amount is not determined uniquely. The composition amount may be a suitable one.

Further, the curing accelerator in the present invention may be a conventionally publicly-known curing accelerator. The curing accelerator is not particularly limited in terms of its specific arrangements. Specific examples of the curing accelerator include: phosphine compounds such as imidazole compounds and triphenylphosphine; amine compounds such as tertiary amine, trimethanolamine, triethanolamine, and tetraethanolamine; and borate compounds such as 1,8-diaza-bicyclo [5,4,0]-7-undeceniumtetraphenylborate. These curing accelerators may be used singularly or two or more of them may be used in combination at any rate.

Out of these curing accelerators, imidazole compounds are preferable. Specific examples of the imidazole compounds include: imidazoles such as imidazole, 2-ethylimidazole, 2-ethyl-4-methylimidazole, 2-phenylimidazole, 2-undecylimidazole, 1-benzyl-2-methylimidazole, 2-heptadecylimidazole, 2-isopropylimidazole, 2,4-dimethylimidazole, and 2-phenyl-4-methylimidazole; imidazolines such as 2-methylimidazoline, 2-ethylimidazoline, 2-isopropylimidazoline, 2-phenylimidazoline, 2-undecylimidazoline, 2,4-dimethylimidazoline, and 2-phenyl-4-methylimidazoline; and azine imidazoles such as 2,4-diamino-6-[2′-methylimidazolyl-(1′)]-ethyl-s-triazine, 2,4-diamino-6-[2′-undecylimidazolyl-(1′)]-ethyl-s-triazine, and 2,4-diamino-6-[2′-ethyl-4′-methylimidazolyl-(1′)]-ethyl-s-triazine. These imidazole may be used singularly or two or more of them may be used in combination at any rate.

The used amount (mixing ratio) of these curing accelerators is not particularly limited as long as the amount accelerates a reaction between the epoxy resin component and epoxy curing agent and the amount does not impair dielectric property of the cured resin. In general, the amount preferably ranges from 0.01 to 10 weight parts, and more preferably ranges from 0.1 to 5 weight parts with respect to 100 weight parts of all the amounts of the epoxy resin components.

Further, more preferable examples of the curing accelerators include 2-ethyl-4-methylimidazole, 2-phenyl-4-methylimidazole, and 2,4-diamino-6-[2′-undecylimidazolyl-(1′)]-ethyl-s-triazine due to their availability, high solubility in a solvent, etc.

The material for plating has, on its surface, a resin layer to be subjected to electroless plating. The resin layer includes: polyimide resin with a siloxane structure having good adhesiveness with an electroless plating film; and a thermosetting component that has high heat-resistance. Consequently, the material for plating or a laminate of the material for plating has high adhesive strength with the electroless plating film without surface roughening, and has good heat-resistance. Further, the material for plating has high adhesive strength at a high temperature.

Further, taking advantage of the above good properties, the material for plating is applicable to printed wiring boards. Examples of the printed wiring boards include flexible printed wiring boards, rigid printed wiring boards, multi-layered flexible printed wiring boards, multi-layered rigid printed wiring boards, and build-up wiring boards that require formation of fine wire s.

That is, a resin layer (surface) containing (i) polyimide resin having the siloxane structure and (ii) a thermosetting component is formed on a surface of a material to be subjected to electroless plating, and thereafter the surface of the material is subjected to electroless plating. In this case, the resin layer containing (i) the polyimide resin having the siloxane structure that has good adhesiveness with an electroless plating layer and (ii) the thermosetting component serves as an interlayer adhesive. Therefore, the electroless plating layer and the material on which the resin layer is formed attach firmly to each other. Further, the resin layer contains the thermosetting component and as a result has higher solder heat-resistance compared with a conventional adhesive resin layer. Further, the resin layer has good adhesiveness with the electroless plating layer and therefore it is unnecessary to increase roughness of the surface to be plated. This is advantageous in forming fine wires.

Taking advantage of the above excellent properties, the technique of the present invention is applicable to ornamental plating and functional plating. Above all, the technique of the present invention is preferably applicable to material for plating for printed wiring boards etc., taking advantage that the technique exhibits heat-resistance and allows firmly forming the electroless plating layer even when the surface roughness is low.

### <1-1-3. Resin Layer Characterized in Glass-transition Temperature of Polyimide Resin>

The following explains further another embodiment of the resin layer of the present invention. It is preferable that the resin layer has the siloxane structure represented by the general formula (1) and contains polyimide resin whose glass-transition temperature ranges from 100 to 200° C. The resin layer is not particularly limited in terms of other specific arrangements.

Further, it is preferable that the polyimide resin having the siloxane structure is made of an acid dianhydride component and a diamine component including diamine represented by the general formula (1), and the diamine represented by the general formula (1) is 10 to 75 mol % with respect to all diamines. This arrangement results in polyimide resin that is excellent in adhesive strength with plating copper at a normal temperature and a high temperature.

Note that, explanation of the polyimide resin will be made only as to parts different from the explanation made in another embodiments of the resin layer.

The inventors of the present invention found that a layer containing polyimide resin having a siloxane structure allows electroless plating to attach firmly with the layer even when a surface of the layer is smooth. Besides, the inventors studied a relation among properties of polyimide resin to be used, especially glass-transition temperature, solder heat-resistance and adhesiveness at a high temperature of the polyimide resin to be used. As a result, the inventors found that glass-transition temperature being in a range of 100 to 200° C. is very important to compatibility between adhesiveness with electroless plating and solder heat-resistance. Further, glass-transition temperature being in a range of 100 to 200° C. allows improving adhesiveness at a high temperature as well as adhesiveness in an ordinary state. The inventors are the first to pay attention to glass-transition temperature of the polyimide resin having a siloxane structure in order to attain high adhesiveness with electroless plating both in an ordinary state and at a high temperature and to attain compatibility of high adhesiveness and high solder heat-resistance.

“Layer” in the present invention means a layer whose thickness is 1 nm or more. The thickness may be even or uneven.

Further, as described above, the resin layer contains polyimide resin whose glass-transition temperature ranges from 100 to 200° C. “Glass-transition temperature” in the present invention is obtained by manufacturing a film made of the polyimide resin and measuring dynamic viscoelasticity of the film under the following conditions.

That is, dynamic viscoelasticity of the film is measured by DMS6100 (manufactured by SII NanoTechnology Inc.) with the temperature rising rate being 3° C./min from a room temperature to 300° C. and with measurement being carried out in the TD direction of the film. The obtained tan δ peak top temperature is regarded as glass-transition temperature. An example of manufacture of the film is as follows: a solution containing polyimide resin having a siloxane structure is flow-casted and applied on a shine surface of a rolled copper foil (BHY-22B-T; manufactured by Nikko Materials Co., Ltd.) and is dried at 60° C. for 1 minute, at 80° C. for 1 minute, at 100° C. for 3 minutes, at 120° C. for 1 minute, at 140° C. for 1 minute, at 150° C. for 3 minutes, and at 180° C. for 30 minutes, and after etching out the rolled copper foil, dried at 60° C. for 30 minutes. The thickness is not particularly limited. However, it is preferable that the thickness is 10 μm or more.

The glass-transition temperature of the polyimide resin having the siloxane structure preferably ranges from 100 to 200° C., and more preferably ranges from 105 to 195° C. When the glass-transition temperature is less than 100° C., the resulting material for plating tends to have lower adhesiveness at a high temperature. When the glass-transition temperature is more than 200° C., the resulting material for plating tends to have lower adhesiveness at an ordinary state and at a high temperature.

Further, it is preferable that the polyimide resin having the siloxane structure is made of an acid dianhydride component and a diamine component including diamine represented by the general formula (1), and the diamine represented by the general formula (1) is 10 to 75 mol % with respect to all diamines. This results in polyimide resin having high adhesiveness with plating copper at a high temperature.

The polyimide resin includes the diamine represented by the general formula (1) and as a result has high adhesiveness with an electroless plating film even when surface roughness is low. Further, a glass-transition temperature tends to be low when much amount of diamine represented by the general formula (1) is contained with respect to all diamines, although it varies depending on the kinds of acid dianhydride and diamine to be used. Therefore, in order that the polyimide resin has a glass-transition temperature ranging from 100 to 200° C., it is preferable that the polyimide resin contains much amount of diamine represented by the general formula (1) with respect to all diamines.

Further, usage of diamine having flexibility which will be mentioned later tends to lower glass-transition temperature. The diamine represented by the general formula (1) is present in an amount preferably ranging from 10 to 75 mol %, more preferably ranging from 13 to 60 mol %, and further more preferably ranging from 15 to 49 mol % with respect to all diamines. When the diamine represented by the general formula (1) is within the above range, it is possible to obtain a material for plating having good adhesiveness and good solder heat-resistance in an ordinary state and at a high temperature.

Further, the acid dianhydride component and the diamine component explained in another embodiments of the resin layer are preferably used as the acid dianhydride component and the diamine component of the present embodiment. Further, the polyimide resin may include a combination between the diamine component represented by the general formula (1) and other diamine component. Other diamine component may be any diamine and may preferably be diamine explained in another embodiments of the resin layer.

As described above, a glass-transition temperature tends to be low when much amount of diamine represented by the general formula (1) is contained with respect to all diamines, although it varies depending on the kinds of acid dianhydride and diamine to be used. Therefore, in order that the polyimide resin has a glass-transition temperature ranging from 100 to 200° C., it is preferable that the polyimide resin contains much amount of diamine represented by the general formula (1) with respect to all diamines.

Further, usage of much diamine having flexibility tends to lower glass-transition temperature. The diamine having flexibility is diamine having a flexible structure, such as an ether group, a sulfone group, a ketone group, and a sulfide group. The diamine having flexibility is preferably represented by the following general formula (3)

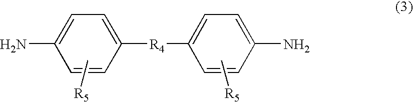

where R₄ is a group selected from bivalent organic groups represented by the following formula:

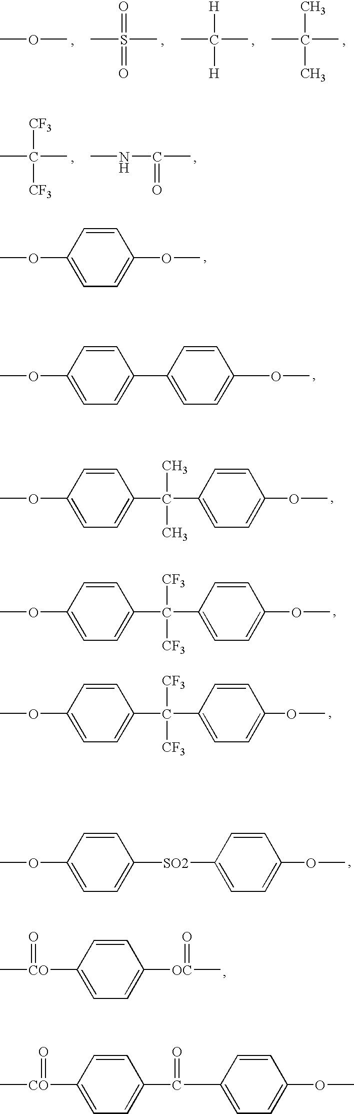

and where two R₅ are identical with each other or different from each other and R₅ is a group selected from H—, CH₃—, —OH, —CF₃, —SO₄, —COOH, —CO—NH₂, Cl—, Br—, F—, and CH₃O—.

Further, the diamine represented by the general formula (1) is present in an amount preferably ranging from 10 to 75 mol %, more preferably ranging from 13 to 60 mol %, and further more preferably ranging from 15 to 49 mol % with respect to all diamines.

The method for preparing polyimide is the same as the method explained in another embodiments of the resin layer.

Further, polyimide resin may contain other component for the purpose of improving heat-resistance, reducing adhesiveness, etc. The other component may be resin such as thermoplastic resin and thermosetting resin.

Examples of the thermoplastic resin include polysulfone resin, polyethersulfone resin, polyphenyleneether resin, phenoxy resin, and thermoplastic polyimide resin. These thermoplastic resins may be used singularly or may be used in combination as needed. Further, examples of the thermosetting resin include bismaleimide resin, bisallylnadiimide resin, phenol resin, cyanate resin, epoxy resin, acrylic resin, methacrylic resin, triazine resin, hydrosilyl cured resin, allyl cured resin, and unsaturated polyesther resin. These thermosetting resins may be used singularly or may be used in combination as needed. In addition to the aforementioned thermosetting resins, thermosetting polymers containing a reactive group in side chains can also be used. The thermosetting polymers containing a reactive group in side chains are those thermosetting polymers which have a reactive group such as an epoxy group, an allyl group, a vinyl group, an alkoxysilyl group or a hydrosilyl group in the side chains or terminals of polymer chains.

In addition, the resin layer may contain additives as with another embodiments. Further, it is preferable that polyimide resin contained in the resin layer is 100 weight parts with respect to 100 or less weight parts of other component.

Further, as with another embodiments, the resin layer has an advantage that, even when surface roughness is low, the resin layer has high adhesive strength with an electroless plating layer. The surface roughness of the resin layer may preferably be not more than 0.5 μm represented in arithmetic mean roughness Ra as measured at a cutoff value of 0.002 mm. In a case where this condition is satisfied, when the material for plating of the present invention is used for printed wiring boards, it is possible to form fine wires excellently. In order to allow the resin layer to have such surface, it is preferable that physical surface roughness such as sand blast is not carried out.

As described above, by prescribing a structure and glass-transition temperature of polyimide resin used in the resin layer, it is possible to firmly attach the electroless plating layer to a smooth surface in particular. Further, the resin layer has high adhesiveness with other material, has high solder heat-resistance, and has high adhesive strength at a high temperature. Accordingly, the resin layer is preferably applicable to manufacture of printed wiring boards. Further, as the resin layer has high adhesiveness with an electroless plating layer while having a smooth surface, has sufficient solder heat-resistance, and has adhesive strength at a high temperature, the resin layer is preferably applicable to manufacture of printed wiring boards such as flexible printed wiring boards, rigid printed wiring boards, multi-layered flexible printed wiring boards, and build-up wiring boards that require formation of fine wirings.

### <1-1-4. Resin Layer Characterized by Weight-average Molecular Weight of Polyimide Resin>

The following explains further another embodiment of the resin layer of the present invention. It is preferable that the resin layer has a siloxane structure represented by the general formula (1) and contains polyimide resin having weight-average molecular weight Mw of 30000 to 150000 as determined by gel permeation chromatography.

Further, it is more preferable that the polyimide resin having the siloxane structure is made of an acid dianhydride component and a diamine component including diamine represented by the general formula (1), the polyimide resin is made of an acid dianhydride component and a diamine component including diamine represented by the general formula (1), and the polyimide resin is obtained by adding, to the diamine component of 1 mol, the acid dianhydride component of 0.95 to 1.05 mol. This results in polyimide resin having high adhesive strength with electroless plating copper.

The inventors of the present invention found that a layer containing the polyimide resin having the siloxane structure allows electroless plating to attach firmly with the layer even when a surface of the layer is smooth. Besides, the inventors studied, as properties of polyimide resin to be used, a relation between the molecular amount and solder heat-resistance of the polyimide resin. As a result, the inventors found that when the molecular amount is in a specific range, the polyimide resin has notable adhesiveness with electroless plating and notable solder heat-resistance. That is, the inventors found that, in order to attain compatibility between adhesiveness with electroless plating and solder heat-resistance, it is important for the polyimide resin to have the siloxane structure and to have weight-average molecular weight Mw of 30000 to 150000 as determined by gel permeation chromatography. The inventors of the present invention was the first to pay attention to molecular weight of the polyimide resin having the siloxane structure in order to attain compatibility between adhesiveness with electroless plating and solder heat-resistance.

The material for plating of the present invention includes at least a resin layer to be subjected to electroless plating. A preferable method for electroless plating is such that: the material for plating of the present invention is formed on a surface of a material to be subjected to electroless plating, and then the material is subjected to electroless plating. With this, the material for plating of the present invention serves as an interlayer adhesive and as a result electroless plating firmly attaches to the material. Taking advantage of this, the material for plating is applicable to ornamental plating and functional plating. Among them, the material for plating is applicable to printed wiring boards, taking advantage that the material for plating allows firmly forming an electroless plating layer while having low surface roughness and has solder heat-resistance.

Further, the resin layer contains polyimide resin having the siloxane structure and having weight-average molecular weight Mw of 30000 to 150000 as determined by gel permeation chromatography. With this structure, the resin layer has high adhesiveness with an electroless plating film and has high solder heat-resistance.

The weight-average molecular weight Mw of the polyimide resin used for the resin layer is more preferably 35000 to 140000, and further more preferably 40000 to 130000. When Mw is less than 30000, the resin layer does not have sufficient solder heat-resistance. When Mw is more than 150000, solubility of polyimide resin is impaired. This disables preparation of a polyimide resin solution or sufficient flowability of resin.

The weight-average molecular weight Mw was determined as follows: HLC-8220GPC and GPC-8020 (each manufactured by Tosoh Corporation) was used as measuring devices, two TSK gel Super AWM-H (manufactured by Tosoh Corporation) that were connected with each other were used as a column, TSK guardcolumn Super AW-H (manufactured by Tosoh Corporation) was used as a guardcolumn, and N,N-dimethylformamide including 0.02M of phosphoric acid and 0.03M of lithium bromide was used as a mobile phase. A sample was made by dissolving the polyimide resin in a solvent identical with the mobile phase so that density of the polyimide resin was 0.1 weight %. Under these conditions, gel permeation chromatography was applied to the sample at column temperature of 40° and with flow rate of 0.6 ml/min. Thus, the weight-average molecular weight Mw was determined.

It is preferable that the polyimide resin is made of an acid dianhydride component and a diamine component including diamine represented by the general formula (1). Further, it is preferable that the polyimide resin is obtained by adding, to the diamine component of 1 mol, the acid dianhydride component in a range of 0.95 to 1.05 mol.

Here, the amount of added acid dianhydride component in the present specification is an amount in a case where purities of the diamine component and the acid dianhydride component are assumed to be 100%. Therefore, in a case where purities of the diamine component and the acid dianhydride component are less than 100%, consideration of the purities is required, which changes the range of the acid dianhydride component. For example, in a case where the diamine component is a component of diamine 1 (whose purity is A %) and the acid dianhydride component is a component of acid dianhydride 2 (whose purity is B), the amount of acid dianhydride 2 to be added preferably ranges from (0.95×A/B) mol to (1.05×A/B) mol. For example, in a case where the purity of the diamine component is 100% and the purity of the acid dianhydride is 98%, the amount of the acid dianhydride component to be added ranges from 0.969 to 1.071 mol with respect to the diamine component of 1 mol.

In a case where functional group equivalent weights of the acid dianhydride component and the diamine component are shown, molecular weights are calculated from the functional group equivalent weights and accordingly the amount of the acid dianhydride component to be added is determined.

The acid dianhydride component to be added here may be that explained in the above embodiments. Further, by using the diamine component represented by the general formula (1), the resin layer including the resulting polyimide resin firmly attaches to the electroless plating layer.

Further, the polyimide resin may contain other diamine component in combination with the aforementioned diamine component. Examples of the other diamine component may be any diamine and may be the same as the diamine component explained in the above embodiments.

Here, the diamine represented by the general formula (1) is present in an amount preferably ranging from 1 to 75 mol %, more preferably ranging from 3 to 60 mol %, and further more preferably ranging from 5 to 49 mol % with respect to all diamines. When the diamine represented by the general formula (1) is present in an amount less than 1 mol % or more than 75 mol %, there is a case where the resin layer does not have enough adhesive strength with an electroless plating film.

The method for preparing polyimide may be the same as that explained in the above embodiments.

Examples of methods for obtaining polyimide resin having weight-average molecular weight Mw of 30000 to 150000 include: (i) a method for controlling, in consideration of purities of acid dianhydride and a diamine component used as materials for polyamide acid that is a precursor of polyimide resin, a ratio of the acid dianhydride to the diamine component; (ii) a method for controlling a temperature and time in polymerization; (iii) a method for controlling viscosity of polyamide acid; and (iv) a method for controlling a condition for imidization. These methods may be carried out singularly or may be carried out in combination.

(i) The following explains the case of controlling, in consideration of purities of acid dianhydride and a diamine component used as materials for polyamide acid that is a precursor of polyimide resin, a ratio of the acid dianhydride to the diamine component. In order to obtain polyimide resin having weight-average molecular weight Mw of 30000 to 150000, it is preferable to add, to the diamine component of 1 mol, the acid dianhydride component of 0.95 mol to 1.05 mol.

(ii) In the case of controlling a temperature and time in polymerization, a higher temperature tends to lower molecular weight and longer time tends to lower the molecular weight. There is a case where too short time does not provide sufficient molecular weight. Therefore, the temperature and the time in polymerization preferably range from 0 to 45° C. and 30 to 200 minutes, respectively.

(iii) In the case of controlling viscosity of polyamide acid, the viscosity of polyamide acid before imidization preferably ranges from 6 to 3000 poises.

(iv) The following explains the case of controlling the condition for imidization.

In imidization of polyamide acid, decomposition of polyamide acid and imidization of polyamide acid occur together. Although some differences exist due to composition, polyamide acid tends to be more decomposed as a temperature rises. Therefore, molecular weight of polyimide tends to be lower as a temperature rises. Further, in a case of a chemical imidization method, polyamide acid tends to be more decomposed as more amount of a dehydrating agent is used. On the other hand, as for heating in imidization, imidization tends to proceed more as temperature-rising speed is higher. In the case of the chemical imidization method, imidization tends to proceed more as more amount of a catalyst is used. Therefore, in accordance with these tendencies, temperature in imidization, temperature-rising speed, the amount of a dehydrating agent, and the amount of a catalyst are selected, so that a desired molecular weight of polyimide is obtained.

Explanations were made above as to polyimide resin. The resin layer may include other component for the purpose of improving heat-resistance, reducing viscosity, etc. Examples of the other component include resins such as thermal resins and thermosetting resins and additives explained in the above embodiments.

Note that the other component combined with the polyimide resin is present in an amount which does not allow surface roughness of the resin layer to be so large as to adversely affect formation of fine wires, and which does not allow adhesiveness between the resin layer and the electroless plating film to be low. It is preferable that the amount of polyimide resin contained in the resin layer is 100 weight parts with respect to 100 or less weight parts of the other component.

Further, the resin layer is advantageous in that the resin layer has high adhesive strength with an electroless plating layer even when the resin layer has small surface roughness. Here, the surface roughness of the resin layer is preferably less than 0.5 μm in arithmetic mean roughness Ra as measured at a cutoff value of 0.002 mm. In a case where this condition is satisfied, when the material for plating of the present invention is used for printed wiring boards in particular, it is possible to form good fine wires.

As described above, by prescribing a structure and weight-average molecular weight Mw of the polyimide resin to be used, it is possible to firmly attach the electroless plating layer to a smooth surface in particular. Further, the resin layer has high adhesiveness with other material and has high solder heat-resistance. Accordingly, the resin layer is preferably applicable to manufacture of printed wiring boards. Further, as the resin layer has high adhesiveness with an electroless plating layer while having a smooth surface, and has sufficient solder heat-resistance, the resin layer is preferably applicable to manufacture of printed wiring boards such as flexible printed wiring boards that requires formation of fine wirings.

<1-1-5. Resin layer Characterized by Polyimide Resin Having a Functional Group etc.>

The following explains further another embodiment of the resin layer of the present invention. It is preferable that the resin layer contains polyimide resin having a siloxane structure represented by the general formula (1) and having a functional group and/or a group obtained by protecting the functional group. The “functional group and/or a group obtained by protecting the functional group” may be hereinafter referred to as “functional group etc.”

Here, a functional group in the present invention is a group of atoms that is abundant in a chemical reaction. Although the functional group is not particularly limited, the functional group is preferably at least one selected from a hydroxyl group, an amine group, a carboxyl group, an amide group, a mercapto group, and a sulfonic acid group, in order to attain compatibility between adhesiveness with electroless plating and solder heat-resistance. Further, by using these functional groups, it is possible to present a good adhesive layer for adhesion with resin materials. Further, it is preferable that the polyimide resin is made of: an acid dianhydride component; and a diamine component containing diamine represented by the general formula (1) and diamine including a functional group and/or a group obtained by protecting the functional group.

The inventors of the present invention found that the layer containing polyimide resin having the siloxane structure allows electroless plating to firmly attach to the surface of the layer even when the surface is smooth. Besides, the inventors was the first to find that addition of the functional group etc. to the polyimide resin used in the present embodiment attains compatibility between adhesiveness with electroless plating and solder heat-resistance. The inventors was the first to introduce a functional group to polyimide resin having the siloxane structure in order to attain compatibility between adhesiveness with electroless plating at an ordinary state and solder heat-resistance.

Further, the resin layer contains polyimide resin that has the siloxane structure and has a functional group and/or a group obtained by protecting the functional group. The functional group makes chemical interactions with resin materials and as a result increases adhesive strength with the resin materials.

Further, the functional group may be a group obtained by protecting a functional group. Here, “a group obtained by protecting a functional group” in the present invention refers to a group resulting from a reaction between a functional group and a chemical compound that reacts with the functional group. For example, in a case where the functional group is a hydroxyl group, an amino group, or an amide group, an example of the group obtained by protecting the functional group is an acetylated group resulting from a reaction between the functional group and acetic anhydride etc. On the other hand, in a case where the functional group is a mercapto group, an example of the group obtained by protecting the functional group is a group resulting from a reaction between the functional group and an unsaturated polyester compound.

The group obtained by protecting a functional group does not reduce adhesiveness with an electroless plating film or resin, and accordingly can be used without any change. Further, the group may be given back to the original functional group by desorbing the protecting group through a desorption reaction. Further, the functional group and the group obtained by protecting the functional group may be exist together.

The polyimide resin may be made of a material such as (A) a material including (i) an acid dianhydride component that contains acid dianhydride having a siloxane structure and containing a functional group and/or a group obtained by protecting the functional group and (ii) a diamine component, (B) a material including (i) an acid dianhydride component that contains acid dianhydride having a siloxane structure and acid dianhydride containing a functional group and/or a group obtained by protecting the functional group and (ii) a diamine component, (C) a material including (i) an acid dianhydride component and (ii) a diamine component that contains diamine having a siloxane structure and having a functional group and/or a group obtained by protecting the functional group, and (D) a material including (i) an acid dianhydride component and (ii) a diamine component that contains diamine having a siloxane structure and diamine having a functional group and/or a group obtained by protecting the functional group. Out of the materials, it is preferable to use (D) a material including (i) an acid dianhydride component and (ii) a diamine component that contains diamine having a siloxane structure and diamine having a functional group and/or a group obtained by protecting the functional group, because the material has advantages such as high availability. Further, it is preferable that polyimide resin is made of (i) an acid dianhydride component and (ii) a diamine component that includes diamine represented by the general formula (1) and diamine having a functional group and/or a group obtained by protecting the functional group. It is preferable that the acid dianhydride component is that explained in another embodiments as described above.

It is preferable that the diamine component is represented by the general formula (1). Consequently, a resin layer containing the resulting polyimide resin firmly attaches to an electroless plating layer. Specific examples of the diamine component represented by the general formula (1) preferably include those explained in another embodiments.

Further, it is preferable that the diamine component contains diamine having a functional group and/or a group obtained by protecting the functional group. It is more preferable that the diamine component contains, as a functional group in particular, diamine having a group selected from a hydroxyl group, an amino group, a carboxyl group, an amide group, a mercapto group, and a sulfonic acid group. Examples of these diamines include 3,3′-dihydroxy-4,4′-diaminobiphenyl, 4,3′-dihydroxybiphenyl-3,4′-diamine, 3,3′-diaminobiphenyl-4,4′-diol, 3,3′-diaminobenzhydrol, 2,2′-diaminobisphenol A, 1,3-diamino-2-propanol, 1,4-diamino-2-butene, 4,6-diaminoresorcinol, 2,6-diaminohydroquinone, 5,5′-methylene-bis(anthranilic acid), 3,5-diaminobenzoic acid, 3,4-diaminobenzoic acid, 4,4′-diaminobenzanilide, 3,4′-diaminobenzanilide, 3,3′-diaminobenzanilide, 2,5-diaminobenzene-1,4-dithiol, 4,4′-diamino-3,3′-disulfanilbiphenyl, 3,3′-dimethyl-4,4′-diaminobiphenyl-6,6′-disulfonic acid, and 4,4′-diaminodiphenyl-2,2′-disulfonic acid. These diamines may be used singularly or two or more of them may be used in combination. Further, functional groups of these diamines may be groups obtained by protecting functional groups.

Further, the polyimide resin may contain other diamine component in combination with the aforementioned diamine component. Examples of the other diamine component may be any diamine. Specifically, the other diamine component may preferably be the same as the diamine component explained in the above embodiments.

Here, the diamine represented by the general formula (1) is present in an amount preferably ranging from 1 to 75 mol %, more preferably ranging from 3 to 60 mol %, and further more preferably ranging from 5 to 49 mol % with respect to all diamines. When the diamine represented by the general formula (1) is present in an amount less than 1 mol % or more than 75 mol %, there is a case where the polyimide resin does not have enough adhesive strength with an electroless plating film and does not have enough solder heat-resistance.

Further, diamine containing a functional group and/or a group obtained by protecting the functional group is present in an amount preferably ranging from 1 to 99 mol % and more preferably ranging from 3 to 99 mol % with respect to all diamines. When the diamine containing a functional group is present in an amount less than 1 mol %, there is a case where the polyimide resin does not have enough adhesive strength with an electroless plating film and does not have enough solder heat-resistance. Further, at that time, adhesive strength with resins tends to be lower.

The method for preparing polyimide may be the method explained above and is not particularly limited.

An explanation was made above as to polyimide resin. In addition to polyimide resin, a resin layer may contain other component for the purpose of improving heat-resistance, reducing viscosity, etc. Examples of the other component include resins such as thermoplastic resins and thermosetting resins and additives explained in the above embodiments.

Note that it is important for the other component combined with the polyimide resin to be present in an amount which does not allow surface roughness of the resin layer to be so large as to adversely affect formation of fine wires, and which does not allow adhesiveness between the resin layer and the electroless plating film to be low. Further, it is preferable that polyimide resin contained in the resin layer is 100 weight parts with respect to 100 or less weight parts of the other component.

Further, the resin layer has an advantage that, even when surface roughness is low, the resin layer has high adhesive strength with an electroless plating layer. The surface roughness of the resin layer may preferably be not more than 0.5 μm represented in arithmetic mean roughness Ra as measured at a cutoff value of 0.002 mm. In a case where this condition is satisfied, when the material for plating of the present invention is used for printed wiring boards, it is possible to form good fine wires.

As described above, the resin layer contains polyimide resin that has a specific siloxane structure and that has a functional group and/or a group obtained by protecting the functional group. Consequently, the resin layer allows an electroless plating layer to firmly attach to a smooth surface of the resin layer. Further, the resin layer has high adhesiveness with other materials and has high solder heat-resistance and high adhesive strength. Consequently, the resin layer is preferably applicable to manufacture of printed wiring boards. Further, taking advantage that the resin layer has high adhesive strength with an electroless plating layer even when the resin layer has a smooth surface and that the resin layer has sufficient solder heat-resistance, the resin layer is preferably applicable to manufacture of flexible printed wiring boards that require formation of fine wires.

### 1-2. Electroless Plating Layer

An electroless plating layer formed on a resin layer of the material for plating of the present invention may preferably be a conventionally publicly known electroless plating layer, and the electroless plating layer is not particularly limited in terms of its specific arrangements. Examples of the electroless plating layer include electroless copper plating, electroless nickel plating, electroless gold plating, electroless silver plating, and electroless tin plating. All electroless plating layers are applicable to the present invention. In terms of industries and electric properties such as migration resistance, the electroless copper plating and the electroless nickel plating are preferable out of the electroless plating layers. The electroless copper plating is most preferable for printed wiring boards.

Further, a plating solution for forming the electroless copper plating layer may preferably be a conventionally publicly known plating solution. The plating solution is not particularly limited in terms of its specific arrangements. The plating solution may be a plating solution for forming any general electroless copper plating layer. In a case of multiple-layered printed wiring boards etc., it is general and preferable to carry out a desmear treatment on a via-hole for maintaining internal layer connection, before carrying out a plating treatment. The desmear treatment is carried out so as to remove resin smear produced in making a hole by laser etc.

The electroless plating layer may be a layer made only of electroless plating. Alternatively, the electroless plating layer may be a plating layer that is formed to have a desired thickness by forming electroless plating and then forming an electrolytic plating layer. The thickness of a plating layer may be one that is applicable to conventionally publicly known printed wiring boards, and is not particularly limited. In consideration of formation of fine wires, the thickness is preferably 25 μm or less, more preferably 20 μm or less, and further more preferably 15 μm or less.

The material for plating of the present invention may have any arrangements as long as the material for plating includes the resin layer. For example, in a case where the material for plating of the present invention is used for printed wiring boards, particularly rigid printed wiring boards such as build-up wiring boards, the material for plating may be made only of the resin layer, that is, the material for plating may be a single sheet.

Further, the material for plating may be made of the resin layer and other layer (such as an additive layer C to face a configured circuit). An example of the layer C is an adhesive layer. A more specific example of the layer C is a resin layer containing thermoplastic polyimide resin and a thermosetting component.

That is, the material for plating of the present invention may include not only the resin layer to be subjected to electroless plating but also other layer, and consist of two or more layers. For example, the material for plating may be a laminated material for plating that consists of a resin layer A/a macromolecule film layer B, or may be a laminated material for plating that consists of a resin layer A/a macromolecule film layer B/a layer C. The following explains a use example of the laminated material for plating of the present invention. This use example is a structure of a laminated material for plating in which other layer is a macromolecule film layer and the resin layer is formed on the macromolecule film layer. The following explains a material for plating that consists of two or more layers.

### 2. Material for Plating Consisting of Two or More Layers

### 2-1. Embodiment 1

A laminated material for plating of the present invention has, for example, on at least one surface of a macromolecule film layer, a resin layer to be subjected to electroless plating. The resin layer is a resin layer explained in <1-1. Resin layer> and is not particularly limited in terms of other specific arrangements. The laminated material for plating is applicable to, for example, printed wiring boards, and particularly to flexible printed wiring boards.

The material for plating consisting of two or more layers may be the material for plating consisting of a resin layer/a macromolecule layer, or may be the material for plating consisting of a resin layer/a macromolecule film layer/a resin layer.

Further, it is preferable that the laminated material for plating consisting of two or more layer has, on one surface of a macromolecule film layer, a resin layer to be subjected to electroless plating, the resin layer is a resin layer explained in <1-1. Resin layer>, and the adhesive layer is formed on the other surface of the macromolecule film layer. That is, the laminated material for plating may consist of a resin layer/a macromolecule film layer/an adhesive layer to face a circuit.

The resin layer and the electroless plating layer may preferably be those explained in the above item <1> and therefore explanations thereof are omitted here. The following details a macromolecule film layer and an adhesive layer.

### <2-1-1. Macromolecule Film Layer>

A macromolecule film for the laminated material for plating of the present invention is used for realizing a low thermal expansion coefficient and toughness of the laminated material for plating. Further, in a case of using the laminated material for plating as a flexible printed wiring board, dimensional stability is required. For that reason, it is preferable to use a macromolecule film having a thermal expansion coefficient of 20 ppm or less. Further, it is preferable to use a macromolecule film having high heat-resistance and low water-absorbency so as to prevent deficiencies such as: plastic deformation due to heat in processing; and swelling due to a volatile component.

Further, in order to form a via-hole having a minor diameter, the thickness of the macromolecule film layer is preferably 50 μm or less, more preferably 35 μm or less, and further more preferably 25 μm or less. Note that, the lower limit of the thickness is preferably 1 μm or more and more preferably 2 μm or more. In other words, it is preferable that the macromolecule film is not so thick and has sufficient electrical insulation.

The macromolecule film layer may be a single layer or may consist of two or more layers. In a case of the macromolecule film layer being a single layer, examples of a material of the macromolecule film layer include: polyolefin such as polyethylene, polypropylene, and polybutene; polyester such as ethylene-vinylalcohol copolymer, polystyrene, polyethyleneterephthalate, polybutyleneterephthalate, and ethylene-2,6-naphthalate; nylon-6, nylon-11, aromatic polyamide, polyamideimide resin, polycarbonate, polyvinyl chloride, polyvinylidene chloride, polyketone resin, polysulfone resin, polyphenylenesulfide resin, polyetherimide resin, fluorosis resin, polyarylate resin, liquid crystal polymer resin, polyphenylenether resin, and non-thermoplastic polyimide resin.

Further, in order to provide high adhesiveness with the resin layer, thermosetting resin and/or thermoplastic resin may be formed on one side or both sides of the macromolecule layer that is a single layer, or the one side or the both sides of the macromolecule layer that is a single layer may be processed with organic matters such as organic monomers and coupling agents. In particular, it is preferable to use non-thermoplastic polyimide resin as the macromolecule film layer because usage of the non-thermoplastic polyimide resin further increases adhesiveness with the resin layer. Further, a plurality of the macromolecule films explained above as the macromolecule film that is a single layer may be laminated via an adhesive so as to be used as a laminated macromolecule film layer.

A preferable example of the macromolecule film layer that meets properties as described above is a non-thermoplastic polyimide film. The following explains a case where the non-thermoplastic polyimide film is used as the macromolecule film layer. The present invention is not limited to this embodiment.

The non-thermoplastic polyimide film that can be used as the macromolecule film layer can be manufactured through conventionally publicly known methods. The methods are not specifically limited. For example, the non-thermoplastic polyimide film is made by flow-casting and applying polyamide acid on a supporter and imidizing the polyamide acid chemically or thermally. Out of the methods, in terms of toughness, breaking strength, and productivity of the film, a more preferable method is to cause a polyamide acid organic solvent solution to react with (i) a chemically converting agent (dehydrating agent) represented by acid anhydride such as acetic anhydride and (ii) a catalyst represented by tertiary amine etc. such as isoquinoline, β-picoline, and pyridine. That is, a chemically imidizing method. Besides, the chemically imidizing method combined with a thermal cure method is further more preferable.

Basically, the polyamide acid may be any conventionally and publicly known polyamide acid and is not particularly limited. For example, the polyamide acid is manufactured by dissolving at least one of aromatic acid dianhydride and at least one of diamine in an organic solvent so that both solutes have substantially the same molar amount, and then stirring the resulting polyamide acid organic solvent solution, under a controlled temperature condition, till the acid dianhydride and the diamine are completely polymerized.

Examples of acid dianhydride that can be used for manufacturing the non-thermoplastic polyimide of the present invention include aromatic tetracarboxylic acid dianhydrides such as pyromellitic acid dianhydride, 3,3′,4,4′-benzophenonetetracarboxylic acid dianhydride, bis(3,4-dicarboxyphenyl)sulfone dianhydride, 2,3,3′,4′-biphenyltetracarboxylic acid dianhydride, 3,3′,4,4′-biphenyltetracarboxylic acid dianhydride, oxydiphthalic acid dianhydride, bis(2,3-dicarboxyphenyl)methane dianhydride, bis(3,4-dicarboxyphenyl)methane dianhydride, 1,1-bis(2,3-dicarboxyphenyl)ethane dianhydride, 1,1-bis(3,4-dicarboxyphenyl)ethane dianhydride, 1,2-bis(3,4-dicarboxyphenyl)ethane dianhydride, 2,2-bis(3,4-dicarboxyphenyl)propane dianhydride, 1,3-bis(3,4-dicarboxyphenyl) propane dianhydride, 4,4′-hexafluoroisopropylidenediphthal acid anhydride, 1,2,5,6-naphthalenetetracarboxylic acid dianhydride, 2,3,6,7-naphthalenetetracarboxylic acid dianhydride, 3,4,9,10-perylenetetracarboxylic acid dianhydride, p-phenylenebis(trimellitic acid monoester acid anhydride), etylenebis(trimellitic acid monoester acid anhydride), bisphenol A bis(trimellitic acid monoester acid anhydride), 4,4′-(4,4′-isopropylidenediphenoxy)bis(phthalic anhydride), and p-phenylenediphthalic acid anhydride, and their resemblances. These may be used singularly or two or more of them may be used in combination at any rate.

Out of the above acid dianhydrides, it is preferable to use pyromellitic acid dianhydride, oxydiphthalic acid dianhydride, 3,3′,4,4′-benzophenonetetracarboxylic acid dianhydride, 3,3′,4,4′-biphenyltetracarboxylic acid dianhydride, or p-phenylenebis(trimellitic acid monoester acid anhydride). These acid dianhydrides are preferable because they are comparatively easily available and they become films that are well balanced in terms of their properties such as elastic modulus, a linear expansion coefficient, water absorbency etc.

Further, examples of diamines that are useable for synthesizing non-thermoplastic polyimide include 1,4-diaminobenzene(p-phenylenediamine), 1,3-diaminobenzene, 1,2-diaminobenzene, 3,3′-dichlorobenzidine, 3,3′-dimethylbenzidine, 3,3′-dimethoxybenzidine, 3,3′-dihydroxybenzidine, 3,3′,5,5′-tetramethylbenzidine, 4,4′-diaminodiphenylpropane, 4,4′-diaminodiphenylhexafluoropropane, 1,5-diaminonaphthalene, 4,4′-diaminodiphenyldiethylsilane, 4,4′-diaminodiphenylsilane, 4,4′-diaminodiphenylethylphosphineoxide, 4,4′-diaminodiphenyl N-methylamine, 4,4′-diaminodiphenyl N-phenylamine, 4,4′-diaminodiphenylether, 3,4′-diaminodiphenylether, 3,3′-diaminodiphenylether, 4,4′-diaminodiphenylthioether, 3,4′-diaminodiphenylthioether, 3,3′-diaminodiphenylthioether, 3,3′-diaminodiphenylmethane, 3,4′-diaminodiphenylmethane, 4,4′-diaminodiphenylmethane, 4,4′-diaminodiphenylsulfone, 3,4′-diaminodiphenylsulfone, 3,3′-diaminodiphenylsulfone, 4,4′-diaminobenzanilide, 3,4′-diaminobenzanilide, 3,3′-diaminobenzanilide, 4,4′-diaminobenzophenone, 3,4′-diaminobenzophenone, 3,3′-diaminobenzophenone, bis[4-(3-aminophenoxy)phenyl]methane, bis[4-(4-aminophenoxy)phenyl]methane, 1,1-bis[4-(3-aminophenoxy)phenyl]ethane, 1,1-bis[4-(4-aminophenoxy)phenyl]ethane, 1,2-bis[4-(3-aminophenoxy)phenyl]ethane, 1,2-bis[4-(4-aminophenoxy)phenyl]ethane, 2,2-bis[4-(3-aminophenoxy)phenyl]propane, 2,2-bis[4-(4-aminophenoxy)phenyl]propane, 2,2-bis[4-(3-aminophenoxy)phenyl]butane, 2,2-bis[3-(3-aminophenoxy)phenyl]-1,1,1,3,3,3-hexafluoro propane, 2,2-bis[4-(4-aminophenoxy)phenyl]-1,1,1,3,3,3-hexafluoro propane, 1,3-bis(3-aminophenoxy)benzene, 1,4-bis(3-aminophenoxy)benzene, 1,4′-bis(4-aminophenoxy)benzene, 4,4′-bis(4-aminophenoxy)biphenyl, 4,4′-bis(3-aminophenoxy)biphenyl, bis[4-(3-aminophenoxy)phenyl]ketone, bis[4-(4-aminophenoxy)phenyl]ketone, bis[4-(3-aminophenoxy)phenyl]sulfide, bis[4-(4-aminophenoxy)phenyl]sulfide, bis[4-(3-aminophenoxy)phenyl]sulfone, bis[4-(4-aminophenoxy)phenyl]sulfone, bis[4-(3-aminophenoxy)phenyl]ether, bis[4-(4-aminophenoxy)phenyl]ether, 1,4-bis[4-(3-aminophenoxy)benzoyl]benzen, 1,3-bis[4-(3-aminophenoxy)benzoyl]benzen, 4,4′-bis[3-(4-aminophenoxy)benzoyl]diphenylether, 4,4′-bis[3-(3-aminophenoxy)benzoyl]diphenylether, 4,4′-bis[4-(4-amino-α,α-dimethylbenzyl)phenoxy]benzophenone, 4,4′-bis[4-(4-amino-α,α-dimethylbenzyl)phenoxy]diphenylsulfone, bis[4-{4-(4-aminophenoxy)phenoxy}phenyl]sulfone, 1,4-bis[4-(4-aminophenoxy)-α,α-dimethylbenzyl]benzene, 1,3-bis[4-(4-aminophenoxy)-α,α-dimethylbenzyl]benzene, and 4,4′-diaminodiphenylethylphosphineoxide, and their resemblances. These may be used singularly or two or more of them may be used in combination at any rate.

Out of the diamines, it is preferable to use 2,2′-bis[4-(3-aminophenoxy)phenyl]propane, 4,4′-diaminodiphenylether, 4,4′-diaminobenzanilide, and p-phenylenediamine. These diamines are preferable because they are comparatively easily available and they become films that are well balanced in terms of their properties such as elastic modulus, a linear expansion coefficient, water absorbency etc.

Further, in the present invention, preferable combinations of acid dianhydride and diamine are: a combination of pyromellitic acid dianhydride and 4,4′-diaminodiphenylether; a combination of pyromellitic acid dianhydride and 4,4′-diaminodiphenylether and p-phenylenediamine; a combination of pyromellitic acid dianhydride and p-phenylenebis(trimellitic acid monoester acid anhydride) and 4,4′-diaminodiphenylether and p-phenylenediamine; a combination of pyromellitic acid dianhydride, p-phenylenebis(trimellitic acid monoester acid anhydride), and 3,3′,4,4′-biphenyltetracarboxylic acid dianhydride and 4,4′-diaminodiphenylether and p-phenylenediamine; and a combination of pyromellitic acid dianhydride and 3,3′,4,4′-benzophenonetetracarboxylic acid dianhydride and 4,4′-diaminodiphenylether, p-phenylenediamine, and 2,2-bis[4-(3-aminophenoxy)phenyl]propane. Non-thermosetting polyimide obtained by combining these monomers have excellent properties such as suitable elastic modulus, dimensional stability, and low water absorbency, and therefore are appropriate for the material for plating of the present invention.

Preferable examples of organic solvents for synthesizing polyamide acid include amide solvents such as N,N-dimethylformamide, N,N-dimethylacetoamide, and N-methyl-2-pyrrolidone. Especially, N,N-dimethylformamide is preferably used.

Further, in a case of imidization through a chemical cure method, examples of chemical imidizing agents to be added to a polyamide acid composition include aliphatic acid anhydride, aromatic acid anhydride, N,N′-dialkylcarbodiimide, low aliphatic halide, halogenated low aliphatic halide, halogenated low fatty acid anhydride, arylphosphonic acid dihalide, thionyl halide, and combinations of two or more of them. Out of the organic solvents, it is particularly preferable to use aliphatic anhydrides such as acetic anhydride, propionic anhydride, and butyric anhydride singularly, or to use combinations of two or more of them.

It is preferable to add these chemical imidizing agents in an amount ranging from 1 to 10 times, preferably from 1 to 7 times, and further preferably from 1 to 5 times with respect to number of moles of polyamide acid portion in the polyamide acid solution. Further, in order to perform imidization effectively, it is preferable to use catalysts as well as the chemical imidizing agents. Examples of the catalysts include aliphatic tertiary amines, aromatic tertiary amines, and heterocyclic tertiary amines. It is particularly preferable to use a catalyst selected from the heterocyclic tertiary amines. Specific examples include quinoline, isoquinoline, β-picoline, and pyridine. These catalysts are added in an amount ranging from 1/20 to 10 times, preferably from 1/15 to 5 times, and further preferably from 1/10 to 2 times with respect to number of moles of the chemical imidizing agent. When the amounts of the chemical imidizing agents and the catalysts are too small, imidization does not proceed effectively. On the other hand, when the amounts of the chemical imidizing agents and the catalysts are too large, imidization proceeds faster and becomes uncontrollable.

Organic or inorganic fillers, plasticizers such as organic phosphorous compounds, and antioxidants may be added, through publicly known methods, to the non-thermoplastic polyimide films that are obtained through publicly known methods. At least one surface of the non-thermoplastic polyimide film may be subjected to: publicly known physical surface treatments such as a corona discharge treatment, a plasma discharge treatment, and an ion gun treatment; and chemical surface treatments such as a primer treatment, thereby providing further better properties with the surface.

The thickness of the thermoplastic polyimide film preferably ranges from 2 μm to 125 μm, and more preferably ranges from 5 μm to 75 μm. When the thickness is less than the range, the laminated material for plating does not have sufficient stiffness and gets uncontrollable. On the other hand, when the thickness of the film is too large, it is requested that, in manufacturing printed wiring boards, the width of a circuit gets wider in consideration of impedance control. This goes against requests of downsizing and highly integrating the printed wiring boards.

Further, the non-thermoplastic polyimide film used for the macromolecule film layer has a low linear expansion coefficient. For example, a polyimide film having a linear expansion coefficient of 10 to 20 ppm is industrially manufactured and comparatively easily available. Therefore, the polyimide film is applicable to the macromolecule film layer. In order to control a linear expansion coefficient of the non-thermoplastic polyimide film, monomers having inflexible structures and monomers having flexible structures are combined at a suitable rate. Other than this method, the linear expansion coefficient of the resulting non-thermoplastic polyimide film can be controlled in accordance with factors such as: the order of adding an acid anhydride component and a diamine component when synthesizing a polyamide acid solution; selection between chemical imidization and thermal imidization; and temperature condition under which polyamide acid is converted into polyimide.

Tensile elastic modulus of the non-thermoplastic polyimide film is measured based on ASTM D882-81. When the elastic modulus is low, the stiffness of the film drops and the film gets uncontrollable. On the other hand, when the elastic modulus is too high, flexibility of the film decreases and therefore roll-to-roll process gets difficult or the film gets brittle. For example, a polyimide film having elastic modulus of 3 to 10 GPa, and a polyimide film having elastic modulus of 4 to 7 GPa are industrially produced and comparatively easily available. These products are applicable.

As with the linear expansion coefficient, the tensile elastic modulus can be controlled by: combining monomers having inflexible structures and monomers having flexible structures at a suitable rate; controlling the order of adding an acid anhydride component and a diamine component when synthesizing a polyamide acid solution; selecting between chemical imidization and thermal imidization; and temperature condition under which polyamide acid is converted into polyimide.

### <2-1-2. Adhesive Layer>

The adhesive layer may be a conventionally publicly known adhesive and is not particularly limited in terms of its specific arrangements. For example, the adhesive layer is preferably used for laminating the laminated material for plating on other substrate (such as a substrate having a surface where circuits are configured). At that time, it is preferable that the adhesive layer is so workable that, when the material for plating is laminated on the surface where the circuits are configured, the adhesive flows between the circuits and fills in the circuits.

It is preferable that the adhesive layer contains thermosetting resin compositions because the thermosetting resin compositions generally have high workability. Examples of the thermosetting resin compositions include: thermosetting resin such as epoxy resin, phenol resin, thermosetting polyimide resin, cyanate ester resin, hydrosilyl cured resin, bismaleimide resin, bisallylnadiimide resin, acrylic resin, methacrylic resin, allyl resin, and unsaturated polyester resin; and thermosetting resin compositions obtained by combining thermosetting polymers containing a reactive group in side chains containing a reactive group such as an allyl group, vinyl group, an alkoxysilyl group, and a hydrosilyl group with a suitable thermosetting agent and a suitable curing catalyst.

In the adhesive layer, thermoplastic macromolecules may be added to the thermosetting resin compositions. Specific examples include: a thermosetting resin composition including epoxy resin and phenoxy resin; a thermosetting resin composition including epoxy resin and thermoplastic polyimide resin; and a thermosetting resin composition including cyanate resin and thermoplastic polyimide resin. The laminated material for plating using the thermosetting resin composition including epoxy resin and thermoplastic polyimide resin is most preferable because the laminated material for plating is well balanced in terms of properties required for a laminated material for plating. Further, in order to realize low thermal expansion, fillers may be added to the adhesive layer.

Further, the adhesive layer may be a complex of fiber and resin. At that time, the complex of fiber and resin is in B-stage (semi-cured state).

The following explains the complex of fiber and resin. Fiber used in the complex is not particularly limited. It is preferable that the fiber is at least one selected from papers, glass textile, glass bonded-textile, aramid textile, aramid bonded-textile, and polytetrafluoroethylene. The papers may be made of pulp such as paper pulp, dissolving pulp, and synthetic pulp that are prepared from raw materials such as woods, tree bark, cotton, linen, and synthetic resin. The glass textile or the glass bonded-textile may be made of E glass, D glass, or other glass. The aramid textile or the aramid bonded-textile may be made of aromatic polyamide or aromatic polyamideimide. Here, the aromatic polyamide is conventionally publicly known meta-aromatic polyamide, para-aromatic polyamide, or copolymerized aromatic polyamide thereof. The polytetrafluoroethylene may preferably have continuous fine polyporous structure as a result of a drawing process.

Resin useable for the complex is not particularly limited. In terms of heat-resistance etc., it is preferable that the resin is at least one selected from epoxy resin, thermosetting polyimide resin, cyanate ester resin, hydrosilyl cured resin, bismaleimide resin, bisallylnadiimide resin, acrylic resin, methacrylic resin, allyl resin, unsaturated polyester resin, polysulfone resin, polyethersulfone resin, thermoplastic polyimide resin, polyphenyleneether resin, polyolefin resin, polycarbonate resin, and polyester resin.

An example of the complex of fiber and resin is a prepreg layer.

### 2-2. Embodiment 2

As described above, the material for plating may be made of any material and may have any form as long as the material for plating includes the resin layer. For example, the material for plating may be made of the resin layer and an adhesive layer C to face a configured circuit.

### 2-3. Embodiment 3

The material for plating may be made of the resin layer and a complex obtained by putting the aforementioned complex of fiber and resin in C-stage, or may be made of a resin layer/C-staged complex of fiber and resin/a resin layer.

### 3. Solution for Forming Resin Layer

In order to manufacture the material for plating, it is preferable to use a solution containing the polyimide resin. That is, it is preferable that the solution of the present invention is for forming a resin layer to be subjected to electroless plating, the solution at least contains polyimide resin having a siloxane structure or polyamide acid that is a precursor of the polyimide resin, and the polyimide resin is obtained by causing an acid dianhydride component to react with a diamine component including diamine represented by the general formula (1). In this specification, the solution is referred to as a “basic solution”

The basic solution is used for forming the resin layer explained in the item <1>. Specifically, the basic solution contains polyimide resin having the siloxane structure. As described in the item <1>, the basic solution may contain not only polyamide resin but also various other components within the scope of the purpose of the present invention. Further, the basic solution may use any solvent that dissolves these resin components. “Dissolution” here means that the resin component of 1 weight % or more dissolves in the solvent or evenly disperses in the solvent.

The basic solution is applied on a desired material by conventionally publicly known methods such as immersion, coating by spray, and spin-coating and is dried, so that the resin layer is formed.

Further, in order to manufacture the material for plating, it is preferable that the basic solution is a solution containing polyamide acid that is a precursor of polyimide resin. That is, the present invention includes a solution that is used for forming a resin layer in the material for plating and that contains polyamide acid having the siloxane structure. Such solution is also an example of the basic solution.

The basic solution is used for forming the resin layer. Specifically, the basic solution contains polyamide acid having the siloxane structure. As described above, the basic solution may contain not only the polyamide acid solution and the thermosetting component but also other components. Further, the basic solution may use any solvent that dissolves these resin components.

The basic solution may be applied on a desired material through publicly known methods such as immersion, coating by spray, and spin-coating and is imidized, so that the resin layer is formed. Imidization may be carried out through a thermal method in which the polyamide acid solution is subjected to a thermal treatment and is dehydrated, or may be carried out through a chemical method in which the polyamide acid solution is dehydrated with a dehydrating agent. Further, imidization may be carried out by heating the polyamide acid solution at a reduced pressure. Out of these methods, it is preferable to carry out imidization through the thermal method in which the polyamide acid solution is subjected to a thermal treatment and is dehydrated, because the method has a simple treatment and is high in its manufacture efficiency.

Further, in the basic solution, the polyimide resin is preferably made of a diamine component that contains 1 to 49 mol % of diamine represented by the general formula (1) with respect to all diamines.

Further, the basic solution preferably contains a thermosetting component.

Further, in the basic solution, the thermosetting component preferably contains an epoxy resin component that includes an epoxy compound and a curing agent.

Further, in the basic solution, it is preferable that the polyimide resin preferably has a glass-transition temperature ranging from 100 to 200° C. Further, in the basic solution, it is more preferable that the polyimide resin contains 10 to 75 mol % of diamine represented by the general formula (1) with respect to all diamines.

Further, in the basic solution, it is preferable that the polyimide resin has weight-average molecular weight Mw of 30000 to 150000 as determined by gel permeation chromatography. Further, in the basic solution, it is preferable that the polyimide resin is obtained by adding 0.95 to 1.05 mol of an acid dianhydride to 1 mol of a diamine component including diamine represented by the general formula (1).

Further, in the basic solution, it is preferable that the polyimide resin contains a functional group and/or a group obtained by protecting the functional group. Further, in the basic solution, it is more preferable that the functional group is at least one selected from a hydroxyl group, an amino group, a carboxyl group, an amide group, a mercapto group, and a sulfonic acid group.

### 4. Method for Manufacturing Material for Plating

The method for manufacturing the material for plating may use the solution explained in the item <3> and is not particularly limited in terms of factors such as other steps, conditions, and equipment.

An example of the method for manufacturing the material for plating is to apply a solution containing at least the polyimide resin on a desired material such as an internal layer wiring board and a macromolecule film through publicly known methods such as immersion, coating by spray, spin coating, roll coating, bar coating, and gravure coating, and to dry the solution, thereby forming a resin layer.

Another example of the method for manufacturing the material for plating is to prepare the polyamide acid solution, to apply the solution on a desired material such as an internal layer wiring board and a macromolecule film through publicly known methods such as immersion, coating by spray, spin coating, roll coating, bar coating, and gravure coating, and to imidize the solution, thereby forming a resin layer. Here, when applying the solution on the desired material such as an internal layer wiring board and a macromolecule film and imidizing the solution so as to form the resin layer, imidization requires high temperature. This may cause thermal change of a material, dimensional change of the material, and remaining stress of the material. Therefore, the method using the polyimide resin solution is more preferable as the method for manufacturing the material for plating of the present invention.

Further, as described above, the material for plating may be a sheet-shaped single layer material (single layer sheet) made only of the resin layer. At that time, the sheet-shaped material made of the resin layer can be obtained by flow-casting and applying on any supporter a solution to form a resin layer for electroless plating and by drying the solution. Note that, a laminated material for plating can be easily obtained by laminating the sheet-shaped material on a desired material such as an internal layer wiring board and a macromolecule film layer.

Further, by forming the resin layer on an insulating material, an insulating sheet can be obtained.

### 5. Laminate, Printed Wiring Board, etc.

Further, the present invention includes a laminate obtained by laminating an electroless plating layer on a surface of a resin layer of the material for plating, the single layer sheet, the insulating sheet, etc.

The material for plating is preferably applicable to a printed wiring board etc. That is, the present invention includes a printed wiring board that includes the material for plating, the single layer sheet, or the insulating sheet. The printed wiring board is not particularly limited in terms of its specific structures as long as the printed wiring board uses the material for plating etc.

Further, the printed wiring board may include an electroless plating layer and a resin layer containing polyamide resin having the siloxane structure. The electroless plating layer may be formed on the resin layer.

The material for plating can be preferably applicable to conventionally publicly known printed wiring boards and is not particularly limited in terms of its specific applications. Examples of the printed wiring boards include flexible printed wiring boards, rigid printed wiring boards, multi-layered flexible printed wiring boards, multi-layered rigid wiring boards, and build-up wiring boards.

The method for manufacturing the printed wiring board includes a step of forming, on any substrate, a resin layer containing polyimide resin having the siloxane structure, and a step of forming an electroless plating layer on the resin layer. The method is not particularly limited in terms of factors such as other specific steps, conditions, and equipment. The following explains some examples of the method for manufacturing the printed wiring board.

First, the following explains a case where a printed wiring board is manufactured by using a sheet-shaped material for plating. The sheet-shaped material for plating has a resin layer on which the aforementioned inserting paper (protecting sheet) is formed. The sheet-shaped material for plating having a resin layer on which an inserting paper is formed and an internal layer substrate on which a circuit pattern is formed are laminated in this order. Then, the inserting paper is detached, a surface of the resin layer is exposed, and the surface is subjected to electroless plating, so that a metal layer for a circuit pattern is formed. Thus, a printed wiring board is obtained.

In a case where a flexible printed wiring board is used as an internal layer substrate in the above step, it is possible to manufacture a multi-layered flexible wiring board. In a case where a printed wiring board including a glass-epoxy substrate etc. is used as an internal layer substrate, it is possible to manufacture a multi-layered rigid wiring board or a build-up wiring board.

The multi-layered printed wiring board requires formation of a via for electric connection in a vertical direction. In the printed wiring board of the present invention, it is possible to form a via through publicly known methods such as laser, mechanical drill, punching, and chemical etching and to make the via conductive through publicly known methods such as electroless plating.

Lamination of the material for plating and the internal layer substrate may be performed through a thermo compression treatment such as a thermo press treatment, a vacuum press treatment, a laminate treatment (thermo laminate treatment), a vacuum laminate treatment, a thermo roll laminate treatment, and a vacuum thermo roll laminate treatment. Out of the treatments, the treatments under vacuum, that is, the vacuum press treatment, the vacuum laminate treatment, and the vacuum thermo roll laminate treatment allow the material for plating to be embedded in a space between circuits in a better way without voids. Thus, the treatments under vacuum are more preferable.

Further, it is possible to perform a heat treatment on the resin layer after forming an electroless plating layer on the surface of the resin layer or after forming a circuit pattern on the electroless plating layer through etching etc. This further increases adhesiveness of the electroless plating layer with the resin layer, and as a result preferable.

As described above, a resin layer containing polyimide resin having a specific structure is used for a surface of a substrate (material) on which an electroless plating layer is to be formed. This increases adhesive strength with the electroless plating layer without surface roughening and increases heat-resistance.

Further, the material for plating, the laminate, the printed wiring board etc. of the present invention allow the plating layer to adhere to the resin layer under a high temperature, although the material for plating, the laminate, and the printed wiring board etc. have very low surface roughness.

Specifically, in a case where the resin layer contains the polyimide resin and the thermosetting component, when the surface roughness of the resin layer on which a plating layer is to be formed is 0.5 μm or less, more preferably 0.1 μm or less, in arithmetic mean roughness Ra as measured at a cutoff value of 0.002 mm, adhesive strength between the plating layer and the resin layer at 150° C. is 5N/cm or more, which is a good effect. This is shown in an example that will be mentioned later.

Further, in a case where the resin layer contains polyimide resin whose glass-transition temperature is characteristic, when the surface roughness of the resin layer on which a plating layer is to be formed is 0.5 μm or less, more preferably 0.1 μm or less, in arithmetic mean roughness Ra as measured at a cutoff value of 0.002 mm, adhesive strength between the plating layer and the resin layer at 120° C. is 5N/cm or more, more preferably 8N/cm or more, which is a good effect. This is shown in an example that will be mentioned later.

The resin layer attaches well to the plating layer in an ordinary state. The adhesiveness between the resin layer and the plating layer may be represented by “adhesive strength at ordinary state” and “adhesive strength after PCT”.

Specifically, in a case where the resin layer in the material for plating, the laminate, or the printed wiring board of the present invention contains the polyimide resin and the thermosetting component, it is preferable that adhesiveness between the resin layer and the plating layer is such that “adhesive strength at ordinary state” is 5N/cm or more, and/or it is preferable that adhesiveness between the resin layer and the plating copper layer is such that “adhesive strength after PCT” is 3N/cm or more.

Further, in a case where the resin layer of the material for plating, the laminate, and the printed wiring board of the present invention contains polyimide resin whose glass-transition temperature is characteristic, adhesiveness between the resin layer and the plating layer is such that “adhesive strength at ordinary state” is preferably 6N/cm or more and further preferably 9N/cm or more, and/or adhesiveness between the resin layer and the plating copper layer is such that “adhesive strength after PCT” is preferably 3N/cm or more and further preferably 6N/cm or more.

Further, in a case where the resin layer of the material for plating, the laminate, and the printed wiring board of the present invention contains polyimide resin whose weight-average molecular weight is characteristic, adhesiveness between the resin layer and the plating layer is such that “adhesive strength at ordinary state” is preferably 6N/cm or more and further preferably 9N/cm or more, and/or adhesiveness between the resin layer and the plating copper layer is such that “adhesive strength after PCT” is preferably 3N/cm or more and further preferably 5N/cm or more.

Further, in a case where the resin layer of the material for plating, the laminate, and the printed wiring board of the present invention contains polyimide resin having a functional group etc., adhesiveness between the resin layer and the plating layer is such that “adhesive strength at ordinary state” is preferably 5N/cm or more and further preferably 11N/cm or more, and/or adhesiveness between the resin layer and the plating copper layer is such that “adhesive strength after PCT” is preferably 3N/cm and further preferably 6N/cm or more.

The term “arithmetic mean roughness Ra” is defined in JIS B 0601 (revised on Feb. 1, 1994). Particularly, the numerical value of “arithmetic mean roughness Ra” used in the present invention refers to a numerical value calculated by observing a surface with optical interferotype surface structure analyzer. The method used in the measurement will be detailed in the examples that will be mentioned later. The term “cutoff value” used in the present invention is described in JIS B 0601 mentioned above, and refers to a wavelength that is to be set in obtaining a roughness curve from a profile curve (actual measurement data). That is, the “value Ra of arithmetic mean roughness as measured at a cutoff value of 0.002 mm” is an arithmetic mean roughness calculated from a roughness curve obtained by removing, from actual measurement data, irregularities having a wavelength longer than 0.002 mm. The “adhesive strength at ordinary state”, the “adhesive strength after PCT”, and adhesiveness between the resin layer and the plating layer at a high temperature may be evaluated through a method for evaluating “plating adhesiveness in ordinary state”, “plating adhesiveness after PCT”, “plating adhesiveness at 120° C.”, and “plating adhesiveness at 150° C.” that will be shown in the later-mentioned examples.

Taking advantage that the material for plating of the present invention has high adhesive strength with an electroless plating layer without surface roughening, the material for plating of the present invention is preferably applicable to manufacture of printed wiring boards such as flexible printed wiring boards, rigid printed wiring boards, multi-layered flexible printed wiring boards, multi-layered rigid wiring boards, and build-up wiring boards that require formation of minute wires.

Further, the material for plating is combined with a surface or both surfaces of a macromolecule film layer such as a non-thermoplastic polyimide film, thereby providing a plating laminate whose material increases its strength, toughness, and elastic modulus, whose linear expansion coefficient drops and dimensional stability rises, and whose material is more easily dealt with. Further, by forming, on one surface of the non-thermoplastic polyimide film, a resin layer that uses the material for plating and that is to be subjected to electroless plating, and by forming, on the other surface, an adhesive layer containing thermoplastic polyimide resin and a thermosetting component, it is possible to manufacture a build-up substrate having increased dimensional stability or a coreless build-up substrate.

The following further details embodiments of the present invention by showing examples. The present invention is not limited to the following examples and various modifications are possible as to details.

The embodiments and concrete examples of implementation discussed in the foregoing BEST MODE FOR CARRYING OUT THE INVENTION serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### EXAMPLES

### Example A

In the present example, solder heat-resistance and formative property of fine wires that are properties of the material for plating were evaluated as described below. In the present example, a resin layer on which electroless plating was to be formed is referred to as a layer A and a layer to face a configured circuit is referred to as a layer B.

[Solder Heat-resistance]

A copper-clad laminate (CCL-HL950K Type SK, manufactured by MITSUBISHI GAS CHEMICAL COMPANY. INC.) and the layer B of a material for plating having a supporter were caused to face each other, and the material for plating and the supporter were heated and pressurized at 170° C. under a pressure of 1 MPa in a vacuum for 6 minutes, and thereafter the supporter was detached and the copper-clad laminate and the layer B were dried at 180° C. for 60 minutes in a hot-air oven. Thus, a laminate was obtained. Thereafter, a copper layer was formed on the surface of the layer A that was exposed. The copper layer was formed in such a manner that, after desmear and electroless copper plating, an electrolytic plating copper layer whose thickness was 18 μm was formed on the electroless plating copper. The laminate was heated and dried at 180° C. for 30 minutes and was cut into pieces each of which had a size of 15 mm by 30 mm. The pieces were left for 200 hours under conditions that the temperature was 30° C. and the moisture was 70%, and thus test pieces were obtained. The test pieces were put into an IR reflow oven under a condition that the peak temperature was 260° C. and thus a solder heat-resistance test was performed. The IR reflow oven was a reflow oven FT-04 manufactured by CIS. This test was repeated three times and an unswollen piece was regarded as ◯ and a swollen piece was regarded as X. Desmear and electroless copper plating were performed through processes shown in Tables 1 and 2 as presented below.

[Formative Property of Fine Wires]

The layer B of a material for plating having a supporter and a copper-clad laminate (CCL-HL950K Type SK, manufactured by MITSUBISHI GAS CHEMICAL COMPANY. INC.) were processed, caused to face a wired surface of a wiring board having wires formed to have a height of 18 μm and a line and space (L/S) of 50 μm/50 μm, heated and pressurized at 170° C. under a pressure of 1 MPa in a vacuum for 6 minutes, and thereafter a supporter was detached, and the layer B, the copper-clad laminate, and the wiring board were dried at 180° C. for 60 minutes in a hot-air oven. Thus, a laminate made of the material for plating/the BT substrate was obtained. Thereafter, a via-hole whose internal diameter was 30 μm was made, with UV-YAG laser, right above an electrode of the BT substrate so that the via-hole extended to the electrode. Then, the whole surface of the substrate was subjected to electroless plating, and then heated at 180° C. for 30 minutes. Thereafter, a resist pattern was formed on the formed copper plating layer and electrolytic copper plating whose thickness was 10 μm was formed. Thereafter, the resist pattern was detached, the exposed plating copper was removed through sulfuric acid/hydrogen peroxide etchant, thereby obtaining a printed wiring board having wires whose L/S=10 μm/10 μm. When the wiring of the printed wiring board was made well without any breakage or defective shape, the wiring was evaluated as being passable (◯). When the wiring has breakage or defective shape, the wiring was evaluated as being a failure (x).

TABLE 1

| | | | | Process | Process |
|---|---|---|---|---|---|
| Step | Composition of solution | | | temp. | time |
| Swelling | Swelling Dip | 500 | ml/l | 60° C. | 5 min |
| | Securiganth P | | | | |
| | Sodium hydroxide | 3 | g/l | | |
| Washing | | | | | |
| Micro etching | Concentrate | 550 | ml/l | 80° C. | 5 min |
| | compact CP | | | | |
| | Sodium hydroxide | 40 | g/l | | |
| Washing | | | | | |
| Neutralization | Reduction Solution | 50 | ml/l | 40° C. | 5 min |
| | Securiganth P500 | | | | |
| | Sulfuric acid | 70 | ml/l | | |

TABLE 2

| | | | | Process | Process |
|---|---|---|---|---|---|
| Step | Composition of solution | | | temp. | time |
| Cleaner | Cleaner Securiganth 902 | 40 | ml/l | 60° C. | 5 min |
| conditioner | Cleaner Additive 902 | 3 | ml/l | | |
| | Sodium hydroxide | 20 | g/l | | |
| Washing | | | | | |
| Predip | Predip Neoganth-B | 20 | ml/l | Room | 1 min |
| | Sulfuric acid | 1 | ml/l | temp. | |
| Providing | Activator Neoganth 834 | 40 | ml/l | 40° C. | 5 min |
| catalyst | conc | | | | |
| | Sodium hydroxide | 4 | g/l | | |
| | Boric acid | 5 | g/l | | |
| Washing | | | | | |
| Activation | Reducer Neoganth | 1 | g/l | Room | 2 min |
| | Sodium hydroxide | 5 | g/l | temp. | |
| Washing | | | | | |
| Electroless | Basic Solution Printoganth | 80 | ml/l | 32° C. | 15 min |
| copper | MSKDK | | | | |
| plating | Copper Solution | 40 | ml/l | | |
| | Printoganth MSK | | | | |
| | Reducer Cu | 14 | ml/l | | |
| | Stabilizer Printoganth | 3 | ml/l | | |
| | MSKDK | | | | |

### Example 1 of Synthesizing Polyimide Resin

24 g (0.03 mol) of KF-8010 (manufactured by Shin-Etsu Chemical Co., Ltd.), 24 g (0.12 mol) of 4,4′-diaminodiphenylether, and N,N-dimethylformamide (hereinafter referred to as DMF) were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus, a DMF solution having polyamide acid whose solid content density was 30% was obtained. The polyamide acid solution was put in a tray coated with Teflon® and was depressurized and heated at 200° C. for 120 minutes at 665 Pa in a vacuum oven. Thus, polyimide resin 1 was obtained.

### Example 2 of Synthesizing Polyimide Resin

37 g (0.045 mol) of KF-8010 (manufactured by Shin-Etsu Chemical Co., Ltd.), 21 g (0.105 mol) of 4,4′-diaminodiphenylether, and N,N-dimethylformamide (hereinafter referred to as DMF) were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus, a DMF solution having polyamide acid whose solid content density was 30% was obtained. The polyamide acid solution was put in a tray coated with Teflon® and was depressurized and heated at 200° C. for 120 minutes at 665 Pa in a vacuum oven. Thus, polyimide resin 2 was obtained.

### Example 3 of Synthesizing Polyimide Resin

49 g (0.06 mol) of KF-8010 (manufactured by Shin-Etsu Chemical Co., Ltd.), 18 g (0.09 mol) of 4,4′-diaminodiphenylether, and N,N-dimethylformamide (hereinafter referred to as DMF) were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus, a DMF solution having polyamide acid whose solid content density was 30% was obtained. The polyamide acid solution was put in a tray coated with Teflon® and was depressurized and heated at 200° C. for 120 minutes at 665 Pa in a vacuum oven. Thus, polyimide resin 3 was obtained.

### Example 4 of Synthesizing Polyimide Resin

37 g (0.045 mol) of KF-8010 (manufactured by Shin-Etsu Chemical Co., Ltd.), 31 g (0.105 mol) of 1,3-bis(3-aminophenoxy)benzene, and N,N-dimethylformamide (hereinafter referred to as DMF) were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus, a DMF solution having polyamide acid whose solid content density was 30% was obtained. The polyamide acid solution was put in a tray coated with Teflon® and was depressurized and heated at 200° C. for 120 minutes at 665 Pa in a vacuum oven. Thus, polyimide resin 4 was obtained.

### Example 5 of Synthesizing Polyimide Resin

73 g (0.09 mol) of KF-8010 (manufactured by Shin-Etsu Chemical Co., Ltd.), 12 g (0.06 mol) of 4,4′-diaminodiphenylether, and N,N-dimethylformamide (hereinafter referred to as DMF) were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus, a DMF solution having polyamide acid whose solid content density was 30% was obtained. The polyamide acid solution was put in a tray coated with Teflon® and was depressurized and heated at 200° C. for 120 minutes at 665 Pa in a vacuum oven. Thus, polyimide resin 5 was obtained.

### Example 6 of Synthesizing Polyimide Resin

97 g (0.12 mol) of KF-8010 (manufactured by Shin-Etsu Chemical Co., Ltd.), 6 g of (0.03 mol)-4,4′-diaminodiphenylether, and N,N-dimethylformamide (hereinafter referred to as DMF) were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus, a DMF solution having polyamide acid whose solid content density was 30% was obtained. The polyamide acid solution was put in a tray coated with Teflon® and was depressurized and heated at 200° C. for 120 minutes at 665 Pa in a vacuum oven. Thus, polyimide resin 6 was obtained.

### Example 7 of Synthesizing Polyimide Resin

41 g (0.143 mol) of 1,3-bis(3-aminophenoxy)benzene, 1.6 g (0.007 mol) of 3,3′-dihydroxy-4,4′-diaminobiphenyl, and DMF were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus, a DMF solution having polyamide acid whose solid content density was 30% was obtained. The polyamide acid solution was put in a tray coated with Teflon® and was depressurized and heated at 200° C. for 180 minutes at 665 Pa in a vacuum oven. Thus, polyimide resin 7 was obtained.

### Example 1 of Preparation of Solution for Forming Layer A

Polyimide resin 1 was dissolved in dioxolane and a solution (A-a) for forming a layer A was obtained. Solid content density was set to 5 weight %.

### Example 2 of Preparation of Solution for Forming Layer A

Polyimide resin 2 was dissolved in dioxolane and a solution (A-b) for forming a layer A was obtained. Solid content density was set to 5 weight %.

### Example 3 of Preparation of Solution for Forming Layer A

Polyimide resin 3 was dissolved in dioxolane and a solution (A-c) for forming a layer A was obtained. Solid content density was set to 5 weight %.

### Example 4 of Preparation of Solution for Forming Layer A

Polyimide resin 4 was dissolved in dioxolane and a solution (A-d) for forming a layer A was obtained. Solid content density was set to 5 weight %.

### Example 5 of Preparation of Solution for Forming Layer A

Polyimide resin 5 was dissolved in dioxolane and a solution (A-e) for forming a layer A was obtained. Solid content density was set to 5 weight %.

### Example 6 of Preparation of Solution for Forming Layer A

Polyimide resin 6 was dissolved in dioxolane and a solution (A-f) for forming a layer A was obtained. Solid content density was set to 5 weight %.

### Example 1 of Preparation of Solution for Forming Layer B

Polyimide resin 7 was dissolved in dioxolane and a solution (A-g) whose solid content density was 25 weight % was obtained. On the other hand, 32.1 g of YX4000H (biphenylepoxy resin; manufactured by Japan Epoxy Resins Co., Ltd.), 17.9 g of bis[4-(3-aminophenoxy)phenyl]sulfone (diamine; manufactured by Wakayama Seika Kogyo Co., Ltd.), and 0.2 g of 2,4-diamino-6-[2′-undecylimidazolyl-(1′)]-ethyl-s-triazine (epoxy curing agent; manufactured by Shikoku Chemicals Corporation) were dissolved in dioxolane and a solution (A-h) whose solid content density was 50% was obtained. 50 g of the solution (A-g) and 50 g of the solution (A-h) were mixed with each other and a solution (A-i) for forming the layer B was obtained.

### Example 1

The solution (A-a) for forming the layer A was flow-casted and applied on a surface of a polyethyleneterephthalate film (product name: Cerapeel HP, manufactured by Toyo Metallizing Co., Ltd.) that serves as a supporter. Thereafter, the solution and the supporter were dried at 60° C. in a hot-air oven and a material made of the layer A whose thickness was 2 μm and the supporter was obtained. Further, the solution for forming the layer B was flow-casted and applied on the surface of the layer A of the material made of the layer A and the supporter, and was dried at 60° C., 100° C., 120° C., and 150° C. Thus was obtained a material for plating having a supporter, which was made of the layer B whose thickness was 38 μm/the layer A whose thickness was 2 μm/the supporter. The material for plating having the supporter was evaluated in accordance with evaluation procedure of evaluation items as described above. The result of the evaluation is shown in Table 3.

### Examples 2 to 4

Using the solution for forming the layer A shown in Table 3, a material for plating having a supporter that was made of the layer B/the layer A/the supporter was obtained through the sama procedure as Example 1. The resulting material for plating having the supporter was evaluated in accordance with evaluation procedure of the evaluation items. The result of the evaluation was shown in Table 3.

### Example 5

The solution (A-b) for forming the layer A was flow-casted and applied on a surface of polyimide film (j) (product name: APICAL NPI, manufactured by KANEKA CORPORATION) of 25 μm. Thereafter, the solution and the polyimide film were dried at 60° C. in the hot-air oven and a material made of the layer A whose thickness was 2 μm/a macromolecule film was obtained. Further, the solution for forming the layer B was flow-casted and applied on the surface of the macromolecule film of the material made of the layer A/the macromolecule film, and dried at 60° C., 100° C., 120° C., and 150° C. Thus was obtained a material for plating made of the layer B whose thickness was 38 μm/the macromolecule film/the layer A whose thickness was 2 μm. The material for plating was evaluated in accordance with evaluation procedure of the evaluation items. A polyethyleneterephthalate film (product name: Cerapeel HP, manufactured by Toyo Metallizing Co., Ltd.) was used as an inserting film for lamination. The result of the evaluation was shown in Table 3.

### Example 6

The solution (A-b) for forming the layer A was flow-casted and applied on the surface of a copper-clad laminate (CCL-HL950K Type SK, manufactured by MITSUBISHI GAS CHEMICAL COMPANY. INC.) by a spin coater, and then dried at 60° C., 150° C., and 180° C. in a hot-air oven. Thus was obtained a material for plating made of the layer A whose thickness was 2 μm/the copper-clad laminate. The material for plating was subjected to desmear, electroless plating, and electrolytic copper plating so as to be a laminate. The laminate was tested in a solder heat-resistance test.

Further, a via-hole whose internal diameter was 30 μm was made, with UV-YAG laser, right above an electrode of a BT substrate that was an internal layer so that the via-hole extended to the electrode. Then, the whole surface of the substrate was subjected to electroless copper plating and then heated at 180° C. for 30 minutes. Thereafter, a resist pattern is formed on the formed copper layer and electrolytic copper plating whose thickness was 10 μm was made. Then, the resist pattern was detached, plating copper that was further exposed was removed by sulfuric acid/hydrogen peroxide etchant, and a printed wiring board having wiring whose L/S was 10 μm/10 μm was made. The printed wiring board was evaluated in terms of its formative property of fine wires.

The result of the evaluation is shown in Table 3.

### Example 7

A material for plating was obtained in the same manner as Example 6 except that a solution (A-k) for forming the layer A, obtained by adjusting solid content density to be 10 in Example 2 of preparation, was used, and the thickness of the layer A was set to 5 μm. The material for plating was evaluated in terms of its solder heat-resistance and formative property of fine wires. The result of the evaluation is shown in Table 3.

Samples made by covering both surfaces of the material for plating of the present invention with copper were used in the solder heat-resistance tests in Examples 1 to 7. Table 3 shows that the samples exhibit sufficient solder heat-resistance.

### Comparative Example 1

A material for plating having a supporter, which was made of the layer B/the layer A/the supporter, was obtained in the same manner as Example 1 except that the solution (A-e) for forming the layer A was used. The obtained material for plating having a supporter was evaluated in accordance with the evaluation items. The result of the evaluation is shown in Table 4.

### Comparative Example 2

A material for plating having a supporter, which was made of the layer B/the layer A/the supporter, was obtained in the same manner as Example 1 except that the solution (A-f) for forming the layer A was used. The obtained material for plating having a supporter was evaluated in accordance with the evaluation items. The result of the evaluation is shown in Table 4.

Table 4 shows that Comparative Examples 1 and 2 are excellent in their formative property of fine wires because Comparative Examples 1 and 2 allowed an electroless plating film to be firmly formed on a smooth surface, but Comparative Examples 1 and 2 were inferior in their solder heat-resistance.

TABLE 3

| | Ex. | Ex. | Ex. | Ex. | Ex. | Ex. | Ex. |
|---|---|---|---|---|---|---|---|
| | 1 | 2 | 3 | 4 | 5 | 6 | 7 |
| Solution for | (A-a) | (A-b) | (A-c) | (A-d) | (A-b) | (A-b) | (A-k) |
| forming | | | | | | | |
| layer A | | | | | | | |
| Solution for | (A-i) | (A-i) | (A-i) | (A-i) | (A-i) | — | — |
| forming | | | | | | | |
| layer B | | | | | | | |
| Macro- | — | — | — | — | (j) | — | — |
| molecule | | | | | | | |
| film | | | | | | | |
| Solder | ◯ | ◯ | ◯ | ◯ | ◯ | ◯ | ◯ |
| heat- | | | | | | | |
| resistance | | | | | | | |
| Formative | ◯ | ◯ | ◯ | ◯ | ◯ | ◯ | ◯ |
| property of | | | | | | | |
| fine wires | | | | | | | |
| L/S = 10 μm/ | | | | | | | |
| 10 μm | | | | | | | |

TABLE 4

| | Comparative example | Comparative example |
|---|---|---|
| | 1 | 2 |
| Solution for forming | (A-e) | (A-f) |
| layer A | | |
| Solution for forming | (A-i) | (A-i) |
| layer B | | |
| Solder heat-resistance | X | X |
| Formative property of | ◯ | ◯ |
| fine wires | | |
| L/S = 10 μm/10 μm | | |

### Example B

### Example of Synthesizing Solution for Forming Resin Layer to be Subjected to Electroless Plating: A-1)

KF-8010 (manufactured by Shin-Etsu Chemical Co., Ltd.) and 4,4′-diaminodiphenylether which serve as diamine components were stirred and dissolved in N,N-dimethylformamide (hereinafter referred to as DMF) so that a molar ratio of KF-8010 to 4,4′-diaminodiphenylether is 1:1. Then, 78 g of 4,4′-(4,4′-isopropylidenediphenoxy)bisphthalic acid anhydride that was approximately equimolar to the diamine components was added and stirred for approximately 1 hour and as a result a DMF solution containing polyamide acid whose solid content density was 30% was obtained. The polyamide acid solution was put in a tray coated with Teflon® and was depressurized and heated at 200° C. for 120 minutes at 665 Pa, and as a result polyimide resin was obtained.

The obtained polyimide resin having siloxane structure was dissolved in dioxolane so that solid content density of the polyimide resin was 10 weight % with respect to the dioxolane, thereby providing a polyimide solution. 196 weight parts of YX4000H (biphenyl epoxy resin manufactured by Japan Epoxy Resins Co., Ltd.), 108 weight parts of bis[4-(3-aminophenoxy)phenyl]sulfone (diamine manufactured by Wakayama Seika Kogyo Co., Ltd.), and 1.3 weight parts of 2,4-diamino-6-[2′-undecylimidazolyl-(1′)]-ethyl-s-triazine (epoxy curing accelerator manufactured by Shikoku Chemicals Corporation) were dissolved in dioxolane so that solid content density was 10%, thereby providing an epoxy compound solution. The polyimide solution and the epoxy compound solution were mixed with each other so that weight ratio of the solutions was 9:1. Thus was prepared a solution (A-1) which contained the polyimide resin component having a siloxane structure and the epoxy resin component so that weight ratio of the components were 9:1 and which was used for forming a resin layer to be subjected to electroless plating.

YX4000H was pulverized and extracted in pure water at 121° C. for 24 hours. The quantity of ionic impurity (Cl⁻, Br⁻, SO₄²⁻, Na⁺) in this extracted water was determined by ion chromatography. The quantity was 3 ppm.

### Example of Synthesizing Solution for Forming Resin Layer to be Subjected to Electroless Plating: A-2

A solution (A-2) was synthesized in the same manner as the synthesization example (A-1) except that the polyimide solution and the epoxy compound solution were mixed with each other so that weight ratio of the solutions was 7:3. The solution (A-2) contained the polyimide resin component having a siloxane structure and the epoxy resin component with weight ratio of the components being 7:3, and was used for forming a resin layer to be subjected to electroless plating.

### Example of Synthesizing Solution for Forming Resin Layer to be Subjected to Electroless Plating: A-3

A solution (A-3) was synthesized in the same manner as the synthesization example (A-1) except that KF-8010 manufactured by Shin-Etsu Chemical Co., Ltd. and 4,4′-diaminodiphenylether that were diamine components were dissolved so that molar ratio of the diamine components was 1:2. The solution (A-3) contained the polyimide resin component having a siloxane structure and the epoxy resin component with weight ratio of the components being 9:1, and was used for forming a resin layer to be subjected to electroless plating.

### Example of Synthesizing Solution for Forming Resin Layer to be Subjected to Electroless Plating: A-4

A solution (A-4) was synthesized in the same manner as the synthesization example (A-1) except that the epoxy compound solution was obtained by dissolving, in dioxolane, 290 weight parts of “NC-3000H” (epoxy resin manufactured by NIPPON KAYAKU CO., LTD.), 126 weight parts of “NC-30” (phenol resin manufactured by GUN EI CHEMICAL INDUSTRY CO., LTD.), and 1.3 weight parts of 2,4-diamino-6-[2′-undecylimidazolyl-(1′)]-ethyl-s-triazine (epoxy curing accelerator manufactured by Shikoku Chemicals Corporation) so that solid content density was 10%. The solution (A-4) contained the polyimide resin component having a siloxane structure and the epoxy resin component with weight ratio of the components being 9:1, and was used for forming a resin layer to be subjected to electroless plating.

### Example of Synthesizing Solution for Forming Resin Layer to be Subjected to Electroless Plating: A-5

Without mixing with an epoxy compound solution, the polyimide solution obtained in the synthesization example (A-1) was regarded as a solution (A-5) which contained no epoxy resin component and which was used for forming a resin layer to be subjected to electroless plating.

### Example of Synthesizing Solution for Forming Resin Layer to be Subjected to Electroless Plating: A-6

41 g of 1,3-bis(3-aminophenoxy)benzene was stirred and dissolved in DMF, and equimolar 4,4′-(4,4′-isopropylidenediphenoxy)bisphthalic acid anhydride was added and stirred for approximately 1 hour. Thus was obtained a DMF solution containing polyamide acid whose solid content density was 30%. The polyamide acid solution was put in a tray coated with Teflon® and was depressurized and heated at 200° C. for 180 minutes at 665 Pa in a vacuum oven. Thus, polyimide resin was obtained. A solution (A-6) was synthesized in the same manner as the synthesization example (A-1) except that the solution (A-6) was prepared from the polyimide solution obtained by dissolving the obtained polyimide resin in dioxolane so that solid content density was 10 weight %. The solution (A-6) contained a polyimide resin component having no siloxane structure and an epoxy resin component with weight ratio of the components being 9:1, and was used for forming a resin layer to be subjected to electroless plating.

### Example of Synthesizing Solution for Forming Adhesive Layer: C-1

41 g of 1,3-bis(3-aminophenoxy)benzene was stirred and dissolved in DMF, and equimolar 4,4′-(4,4′-isopropylidenediphenoxy)bisphthalic acid anhydride was added and stirred for approximately 1 hour. Thus was obtained a DMF solution containing polyamide acid whose solid content density was 30%. The polyamide acid solution was put in a tray coated with Teflon® and was depressurized and heated at 200° C. for 180 minutes at 665 Pa in a vacuum oven. Thus, polyimide resin was obtained. The obtained polyimide resin was dissolved in dioxolane so that solid content density of the polyimide resin was 20 weight %, thereby providing a polyimide solution. 196 weight parts of YX4000H (biphenyl epoxy resin manufactured by Japan Epoxy Resins Co., Ltd.), 108 weight parts of bis[4-(3-aminophenoxy)phenyl]sulfone (diamine manufactured by Wakayama Seika Kogyo Co., Ltd.), and 1.2 weight parts of 2,4-diamino-6-[2′-undecylimidazolyl-(1′)]-ethyl-s-triazine (epoxy curing agent manufactured by Shikoku Chemicals Corporation) were dissolved in dioxolane so that solid content density was 40%, thereby providing an epoxy compound solution. The polyimide solution and the epoxy compound solution were mixed with each other so that weight ratio of the solutions was 2:1. Thus was synthesized a solution (C) which contained the thermoplastic polyimide resin component and the epoxy resin component with weight ratio of the components being 1:1.

### Example 8

The solution (A-1) of the synthesization example (A-1) for forming a resin layer to be subjected to electroless plating was flow-casted and applied on a surface of a polyethleneterephthalate film (product name: Cerapeel HP manufactured by Toyo Metallizing Co., Ltd.) serving as a supporter, and then heated and dried in a hot-air oven at 60° C., 100° C., and 150° C. each for 1 minute. Thus, a material for plating including a resin layer whose thickness was 25 μm was obtained.

The obtained material for plating and a glass epoxy copper-clad laminate “RISHOLITE CS-3665” (manufactured by RISHO KOGYO CO., LTD., copper foil thickness 18 μm, plate thickness 0.6 mm) were caused to face each other, and were heated and pressurized at 170° C. under a pressure of 1 MPa in a vacuum for 6 minutes. Thereafter, the polyethyleneterephthalate film serving as a supporter was detached and the material for plating and the glass epoxy copper-clad laminate were heated at 130° C. for 10 minutes, 150° C. for 10 minutes, and 180° C. for 30 minutes. Thus was obtained a laminate made of the material for plating including a resin layer/the copper-clad laminate.

A plating copper layer (thickness 8 μm) was formed on the surface of an exposed resin layer of the obtained laminate through desmear, electroless plating, and electric copper under conditions shown in Tables 5 and 6, and thereafter dried at 180° C. for 30 minutes. Thus, a plating substrate was made. Plating adhesiveness of the obtained plating substrate was measured in an ordinary state, at a time after Pressure Cooker Test (PCT), and at 150° C. in accordance with JPCA-BU01-1998 (published by Japan Printed Circuits Association). “Plating adhesiveness in ordinary state”, “plating adhesiveness after PCT”, and “plating adhesiveness at 150° C.” were measured under the following conditions.
In ordinary state: adhesive strength measured after the plating substrate was left for 24 hours in an atmosphere where the temperature was 23° C. and the moisture was 50%.
After PCT: adhesive strength measured after the plating substrate was left for 96 hours in an atmosphere where the temperature was 121° C. and the moisture was 100%.
At 150° C.: adhesive strength measured in 150° C. environment.

TABLE 5

| | Composition of | | | Process | Process |
|---|---|---|---|---|---|
| Step | solution | | | temp. | time |
| Swelling | Swelling Dip | 500 | ml/l | 60° C. | 5 min |
| | Securiganth P | | | | |
| | Sodium hydroxide | 3 | g/l | | |
| Washing | | | | | |
| Micro | Concentrate compact | 550 | ml/l | 80° C. | 5 min |
| etching | CP | | | | |
| | Sodium hydroxide | 40 | g/l | | |
| Washing | | | | | |
| Neutralization | Reduction Solution | 50 | ml/l | 40° C. | 5 min |
| | Securiganth P500 | | | | |
| | Sulfuric acid | 70 | ml/l | | |

TABLE 6

| | Composition of | | | Process | Process |
|---|---|---|---|---|---|
| Step | solution | | | temp. | time |
| Cleaner | Cleaner Securiganth | 40 | ml/l | 60° C. | 5 min |
| conditioner | 902 | | | | |
| | Cleaner Additive 902 | 3 | ml/l | | |
| | Sodium hydroxide | 20 | g/l | | |
| Washing | | | | | |
| Predip | Predip Neoganth-B | 20 | ml/l | Room | 1 min |
| | Sulfuric acid | 1 | ml/l | temp. | |
| Providing | Activator Neoganth | 40 | ml/l | 40° C. | 5 min |
| catalyst | 834 conc | | | | |
| | Sodium hydroxide | 4 | g/l | | |
| | Boric acid | 5 | g/l | | |
| Washing | | | | | |
| Activation | Reducer Neoganth | 1 | g/l | Room | 2 min |
| | Sodium hydroxide | 5 | g/l | temp. | |
| Washing | | | | | |
| Electroless | Basic Solution | 80 | ml/l | 32° C. | 15 min |
| copper | Printoganth MSKDK | | | | |
| plating | Copper Solution | 40 | ml/l | | |
| | Printoganth MSK | | | | |
| | Reducer Cu | 14 | ml/l | | |
| | Stabilizer Printoganth | 3 | ml/l | | |
| | MSKDK | | | | |
| Washing | | | | | |
| Acid | 98% H₂SO₄ | 100 | mll | Room | 0.5 min |
| activation | | | | temp. | |
| Electrolytic | CuSO₄•5H₂O | 70 | g/l | RT | 20 min |
| copper | 98% H₂SO₄ | 200 | g/l | 2 | |
| plating | NaCl | 80 | g/l | A/dm2 | |
| | TOP LUCINA 81HL | 2.5 | ml/l | | |
| | TOP LUCINA | 10 | ml/l | | |
| | MAKE-UP | | | | |

Further, a plating substrate was cut into a piece whose width was 15 mm and whose length was 30 mm, was conditioned in terms of its humidity at 30° C. with 60% RH for 192 hours, and then subjected to a reflow test at 260° C. three times. As a result, there was no swelling of plating. The reflow test was carried out as follows.

A copper-clad laminate (CCL-HL950K Type SK, manufactured by MITSUBISHI GAS CHEMICAL COMPANY. INC.) and the surface B of the material for plating having a supporter were caused to face each other, and the copper-clad laminate and the material for plating were heated and pressurized at 170° C. under a pressure of 1 MPa in a vacuum for 6 minutes. Thereafter, the supporter was detached and the copper-clad laminate and the material for plating were dried at 180° C. for 60 minutes in a hot-air oven. Thus, a laminate was obtained. Thereafter, a copper layer was formed on the surface of the layer A that was exposed. The copper layer was formed in such a manner that, after desmear and electroless copper plating, an electrolytic plating copper layer whose thickness was 18 μm was formed on the electroless plating copper. The laminate was subjected to a heating and dry treatment at 180° C. for 30 minutes and was cut into pieces each of which had a size of 15 mm by 30 mm. The pieces were left for 200 hours under conditions that the temperature was 30° C. and the moisture was 70%, and thus test pieces were obtained. The test pieces were put in an IR reflow oven under a condition that peak temperature was 260° C. and thus a solder heat-resistance test was performed. The IR reflow oven was a reflow oven FT-04 manufactured by CIS. This test was repeated three times and an unswollen piece was regarded as ◯ and a swollen piece was regarded as X. Desmear and electroless copper plating were performed through processes shown in Tables 1 and 2 as presented above.

Using a sample that had been subjected to as far as desmear process in the sample-preparing processes, surface roughness Ra of the surface of the resin layer was measured out of the items for measuring adhesiveness. Arithmetic mean roughness Ra of the surface of the resin layer was measured by an optical interferotype surface roughness meter (New View 5030 system manufactured by ZYGO Corporation).

TABLE 7

| | | |
|---|---|---|
| Measurement | Objective lens | 50 power |
| condition | | Mirau |
| | Image zoom | 2 |
| | FDA Res | Normal |
| Analysis condition | Remove | Cylinder |
| | Filter | High Pass |
| | Filter Low Waven | 0.002 mm |

The obtained result is shown in Table 8.

TABLE 8

| | Ex. 8 | Comparative Ex. 3 |
|---|---|---|
| Molar ratio of siloxane | 50% | 50% |
| diamine to all diamines in | | |
| resin of surface A | | |
| Kind of thermosetting | YX4000H/BAPS-M | — |
| component | | |
| Amount of thermosetting | 10% | None |
| component | | |
| Structure | Single layer sheet | Single layer sheet |
| Adhesive strength | 10 | 11 |
| (ordinary state) N/cm | | |
| Adhesive strength | 6 | 7 |
| (after PCT) N/cm | | |
| Adhesive strength | 6 | 4 |
| (150° C.) N/cm | | |
| Anti-reflow property | Unswollen with | Swollen with |
| | 3 reflow tests | 1 reflow test |
| Arithmetic mean roughness | 0.1 μm | 0.1 μm |
| Ra | | |

YX4000H: manufactured by Japan Epoxy Resins Co., Ltd., biphenyl epoxy resin (product name)
BAPS-M: bis[4-(3-aminophenoxy)phenyl]sulfone that is diamine manufactured by Wakayama Seika Kogyo Co., Ltd
NC-3000H: epoxy resin manufactured by NIPPON KAYAKU CO., LTD (product name)
NC-30: phenol resin manufactured by GUN EI CHEMICAL INDUSTRY CO., LTD (product name)

### Comparative Example 3

A laminate made of a material for plating/copper-clad laminate was obtained in the same manner as Example 1 except that the solution (A-5) which was obtained in the synthesization example (A-5) and which did not contain a thermosetting component was used. The obtained laminate was measured in terms of its plating adhesiveness (in an ordinary state, after PCT, and at 150° C.), reflow test, and Ra. The result of the measurement is shown in Table 8.

### Example 9

The solution (A-1) of the synthesization example (A-1) for forming a resin layer to be subjected to electroless plating was flow-casted and applied on a surface of a polyethleneterephthalate film (product name: Cerapeel HP manufactured by Toyo Metallizing Co., Ltd.) serving as a supporter, and then heated and dried in a hot-air oven at 60° C., 100° C., and 150° C. each for 30 seconds. Thus, a material for plating A-1 including a resin layer whose thickness was 2 μm was obtained. Further, a resin layer was formed on the material for plating A-1, and the solution (C) of the synthesization example (C) containing the thermoplastic polyimide resin component and the epoxy resin component was applied on the surface of the resin layer, and heated and dried at 80° C., 100° C., 120° C., and 150° C. each for 1 minute. Thus, a material for plating including a supporter/a resin layer A whose thickness was 2 μm/a layer C whose thickness was 38 μm was obtained.

The obtained material for plating was detached from the PET film serving as the supporter, the material for plating was caused to face a glass epoxy copper-clad laminate “RISHOLITE CS-3665” (manufactured by RISHO KOGYO CO., LTD., copper foil thickness 18 μm, plate thickness 0.6 mm) so that the layer C and the glass epoxy copper-clad laminate face each other, and was heated and pressurized at 170° C. under a pressure of 3 MPa in a vacuum for 60 minutes. Thus, a laminate made of the material for plating including a resin layer/the copper-clad laminate was obtained.

The obtained laminate made of the material for plating/the copper-clad laminate was measured in terms of its plating adhesiveness (in an ordinary state, after PCT, and at 150° C.), reflow test, and Ra. The result of the measurement is shown in Table 9.

TABLE 9

| | Ex. 9 | Ex. 10 | Comparative Ex. 4 |
|---|---|---|---|
| Molar ratio of | 50% | 50% | None |
| siloxane | | | |
| diamine to all | | | |
| diamines in | | | |
| resin of | | | |
| surface A | | | |
| Kind of | YX4000H/ | YX4000H/ | YX4000H/BAPS-M |
| thermosetting | BAPS-M | BAPS-M | |
| component | | | |
| Amount of | 10% | 30% | 10% |
| thermosetting | | | |
| component | | | |
| Structure | Layer A/ | Layer A/layer C | Layer A/layer C |
| | layer C | | |
| Adhesive | 10 | 9 | 3 |
| strength | | | |
| (ordinary | | | |
| state) N/cm | | | |
| Adhesive | 6 | 6 | 1 |
| strength | | | |
| (after PCT) | | | |
| N/cm | | | |
| Adhesive | 6 | 7 | 1 |
| strength | | | |
| (150° C.) N/cm | | | |
| Anti-reflow | Unswollen with | Unswollen with | Unswollen with |
| property | 3 reflow tests | 3 reflow tests | 3 reflow tests |
| Arithmetic | 0.1 μm | 0.1 μm | 0.1 μm |
| mean | | | |
| roughness Ra | | | |

### Example 10

A laminate made of a material for plating including a resin layer/copper-clad laminate was obtained in the same manner as Example 9 except that the solution (A-2) of the synthesization example (A-2) for forming a resin layer to be subjected to electroless plating was used.

The obtained laminate made of the material for plating/the copper-clad laminate was measured in terms of its plating adhesiveness (in an ordinary state, after PCT, and at 150° C.), reflow test, and Ra. The result of the measurement is shown in Table 9.

### Comparative Example 4

A laminate made of a material for plating including a resin layer/copper-clad laminate was obtained in the same manner as Example 9 except that the solution (A-6) of the synthesization example (A-6) for forming a resin layer to be subjected to electroless plating was used.

The obtained laminate made of the material for plating/the copper-clad laminate was measured in terms of its plating adhesiveness (in an ordinary state, after PCT, and at 150° C.), reflow test, and Ra. The result of the measurement is shown in Table 9.

### Example 11

The solution (A-1) of the synthesization example (A-1) for forming a resin layer to be subjected to electroless plating was flow-casted and applied on the surface of a non-thermoplastic polyimide film (product name: APICAL NPI, manufactured by KANEKA CORPORATION) whose thickness was 12.5 μm. Thereafter, the solution (A-1) was heated and dried at 60° C. in a hot-air oven. Thus was obtained a polyimide film having a resin layer whose thickness was 2 μm.

Thereafter, the solution (C) of the synthesization example (C) was flow-casted and applied on the surface of the non-thermoplastic polyimide film opposite to the formed resin layer, and heated and dried at 80° C., 100° C., 120° C., and 150° C. each for 30 seconds in the hot-air oven. Thus was obtained a material for plating made of 2 μm of a resin layer A/12.5 μm of a non-thermoplastic polyimide film layer B/10 μm of a layer C.

The obtained material for plating and a glass epoxy copper-clad laminate “RISHOLITE CS-3665” (manufactured by RISHO KOGYO CO., LTD., copper foil thickness 181 μm, plate thickness 0.6 mm) were caused to face each other so that the resin layer faces outward, and were heated and pressurized at 170° C. under a pressure of 3 MPa in a vacuum for 60 minutes. Thus was obtained a laminate made of a material for plating including a resin layer/a copper-clad laminate.

The obtained laminate made of the material for plating/the copper-clad laminate was measured in terms of its plating adhesiveness (in an ordinary state, after PCT, and at 150° C.), reflow test, and Ra. The result of the measurement is shown in Table 10.

TABLE 10

| | | | | Comparative |
|---|---|---|---|---|
| | Ex. 11 | Ex. 12 | Ex. 13 | Ex. 5 |
| Molar ratio of | 50% | 33% | 50% | 50% |
| siloxane | | | | |
| diamine to all | | | | |
| diamines in | | | | |
| resin of | | | | |
| surface A | | | | |
| Kind of | YX4000H/ | YX4000H/ | NC3000H/ | — |
| thermosetting | BAPS-M | BAPS-M | NC30 | |
| component | | | | |
| Amount of | 10% | 10% | 10% | None |
| thermosetting | | | | |
| component | | | | |
| Structure | Layer A/ | Layer A/ | Layer A/ | Layer A/ |
| | layer B/ | layer B/ | layer B/ | layer B/ |
| | layer C | layer C | layer C | layer C |
| Adhesive | 10 | 9 | 10 | 11 |
| strength | | | | |
| (ordinary | | | | |
| state) N/cm | | | | |
| Adhesive | 6 | 6 | 6 | 7 |
| strength | | | | |
| (after PCT) | | | | |
| N/cm | | | | |
| Adhesive | 6 | 7 | 6 | 4 |
| strength | | | | |
| (150° C.) N/cm | | | | |
| Anti-reflow | Unswollen | Unswollen | Unswollen | Swollen with |
| property | with 3 | with 3 | with 3 | 1 reflow test |
| | reflow tests | reflow tests | reflow tests | |
| Arithmetic | 0.1 μm | 0.1 μm | 0.1 μm | 0.1 μm |
| mean | | | | |
| roughness Ra | | | | |

### Example 12

A laminate made of a material for plating including a resin layer/a copper-clad laminate was obtained in the same manner as Example 11 except that the solution (A-3) of the synthesization example (A-3) for forming a resin layer to be subjected to electroless plating was used.

The obtained laminate made of the material for plating/the copper-clad laminate was measured in terms of its plating adhesiveness (in an ordinary state, after PCT, and at 150° C.), reflow test, and Ra. The result of the measurement is shown in Table 10.

### Example 13

A laminate made of a material for plating including a resin layer/a copper-clad laminate was obtained in the same manner as Example 11 except that the solution (A-4) of the synthesization example (A-4) for forming a resin layer to be subjected to electroless plating was used.

The obtained laminate made of the material for plating/the copper-clad laminate was measured in terms of its plating adhesiveness (in an ordinary state, after PCT, and at 150° C.), reflow test, and Ra. The result of the measurement is shown in Table 10.

### Comparative Example 5

A laminate made of a material for plating including a resin layer/a copper-clad laminate was obtained in the same manner as Example 11 except that the solution (A-5) of the synthesization example (A-5) for forming a resin layer to be subjected to electroless plating was used.

The obtained laminate made of the material for plating/the copper-clad laminate was measured in terms of its plating adhesiveness (in an ordinary state, after PCT, and at 150° C.), reflow test, and Ra. The result of the measurement is shown in Table 10.

### Example 14

The solution (A-1) of the synthesization example (A-1) for forming a resin layer to be subjected to electroless plating was flow-casted and applied on the surface of a non-thermoplastic polyimide film (product name: APICAL NPI, manufactured by KANEKA CORPORATION) whose thickness was 25 μm. Thereafter, the solution (A-1) was heated and dried at 60° C. in a hot-air oven. Thus was obtained a material for plating made of a resin layer A whose thickness was 2 μm and a non-thermoplastic polyimide film layer B.

The obtained material for plating was measured in terms of its plating adhesiveness (in an ordinary state, after PCT, and at 150° C.), reflow test, and Ra. The result of the measurement is shown in Table 11.

TABLE 11

| | Ex. 14 | Ex. 15 | Ex. 16 | Ex. 17 | Comp. Ex. 6 |
|---|---|---|---|---|---|
| Molar ratio of | 50% | 50% | 33% | 50% | None |
| siloxane | | | | | |
| diamine to all | | | | | |
| diamines in | | | | | |
| resin of | | | | | |
| surface A | | | | | |
| Kind of | YX4000H/ | YX4000H/ | YX4000H/ | NC3000/ | YX4000H/ |
| thermosetting | BAPS-M | BAPS-M | BAPS-M | NC30 | BAPS-M |
| component | | | | | |
| Amount of | 10% | 30% | 10% | 10% | 10% |
| thermosetting | | | | | |
| component | | | | | |
| Structure | Layer A/ | Layer A/ | Layer A/ | layer A/ | Layer A/ |
| | layer B | layer B | layer B | layer B | layer B |
| Adhesive | 10 | 9 | 9 | 10 | 3 |
| strength | | | | | |
| (ordinary | | | | | |
| state) N/cm | | | | | |
| Adhesive | 6 | 6 | 6 | 6 | 1 |
| strength | | | | | |
| (after PCT) | | | | | |
| N/cm | | | | | |
| Adhesive | 6 | 7 | 7 | 6 | 1 |
| strength | | | | | |
| (150° C.) N/cm | | | | | |
| Anti-reflow | Unswollen | Unswollen | Unswollen | Unswollen | Unswollen |
| property | with 3 | with 3 | with 3 | with 3 | with 3 |
| | reflow tests | reflow tests | reflow tests | reflow tests | reflow tests |
| Arithmetic | 0.1 μm | 0.1 μm | 0.1 μm | 0.1 μm | 0.1 μm |
| mean | | | | | |
| roughness Ra | | | | | |

### Example 15

The solution (A-2) of the synthesization example (A-2) for forming a resin layer to be subjected to electroless plating was flow-casted and applied on the surface of a non-thermoplastic polyimide film (product name: APICAL NPI, manufactured by KANEKA CORPORATION) whose thickness was 25 μm. Thereafter, the solution (A-2) was heated and dried at 60° C. in a hot-air oven. Thus was obtained a material for plating made of a resin layer A whose thickness was 2 μm and a non-thermoplastic polyimide film layer B.

The obtained material for plating was measured in terms of its plating adhesiveness (in an ordinary state, after PCT, and at 150° C.), reflow test, and Ra. The result of the measurement is shown in Table 11.

### Example 16

The solution (A-3) of the synthesization example (A-3) for forming a resin layer to be subjected to electroless plating was flow-casted and applied on the surface of a non-thermoplastic polyimide film (product name: APICAL NPI, manufactured by KANEKA CORPORATION) whose thickness was 25 μm. Thereafter, the solution (A-3) was heated and dried at 60° C. in a hot-air oven. Thus was obtained a material for plating made of a resin layer A whose thickness was 2 μm and a non-thermoplastic polyimide film layer B.

The obtained material for plating was measured in terms of its plating adhesiveness (in an ordinary state, after PCT, and at 150° C.), reflow test, and Ra. The result of the measurement is shown in Table 11.

### Example 17

The solution (A-4) of the synthesization example (A-4) for forming a resin layer to be subjected to electroless plating was flow-casted and applied on the surface of a non-thermoplastic polyimide film (product name: APICAL NPI, manufactured by KANEKA CORPORATION) whose thickness was 25 μm. Thereafter, the solution (A-4) was heated and dried at 60° C. in a hot-air oven. Thus was obtained a material for plating made of a resin layer A whose thickness was 2 μm and a non-thermoplastic polyimide film layer B.

The obtained material for plating was measured in terms of its plating adhesiveness (in an ordinary state, after PCT, and at 150° C.), reflow test, and Ra. The result of the measurement is shown in Table 11.

### Comparative Example 6

The solution (A-6) of the synthesization example (A-6) for forming a resin layer to be subjected to electroless plating was flow-casted and applied on the surface of a non-thermoplastic polyimide film (product name: APICAL NPI, manufactured by KANEKA CORPORATION) whose thickness was 25 μm. Thereafter, the solution (A-6) was heated and dried at 60° C. in a hot-air oven. Thus was obtained a material for plating made of a resin layer A whose thickness was 2 μm and a non-thermoplastic polyimide film layer B.

The obtained material for plating was measured in terms of its plating adhesiveness (in an ordinary state, after PCT, and at 150° C.), reflow test, and Ra. The result of the measurement is shown in Table 11.

The results of Examples 8 to 17 show that usage of polyimide resin having a siloxane structure allows high adhesive strength at an ordinary state and high adhesive strength after PCT even in a case where surface roughness of a resin layer for forming an electroless plating layer is low. In contrast, the results of Comparative Examples 4 and 6 show that no usage of the polyimide resin having a siloxane structure does not allow sufficient adhesive strength in an ordinary state and sufficient adhesive strength after PCT in the case where the surface roughness of the resin layer for forming an electroless plating layer is low.

Further, the results of Examples 8 to 17 show that solder heat-resistance is high in a case where the resin layer for forming an electroless plating layer contains a thermosetting component. The results of Examples 8 to 17 also show that adhesive strength in a high-temperature environment is high. In contrast, the results of Comparative Examples 3 to 6 show that adhesive strength in a high-temperature environment is not sufficient in a case where the resin layer for forming an electroless plating layer contains no thermosetting component or in a case where the resin layer for forming an electroless plating layer contains little thermosetting component.

As is evident from the above results, the material for plating of the present invention containing: polyimide resin having a siloxane structure; and a thermosetting component etc. has a smooth surface as well as having high plating adhesiveness and high reflow property. Therefore, the material for plating etc. of the present invention is preferably applicable to manufacture of printed wiring boards that require fine wires and heat-resistance.

### Example C

In the present example, properties of material for plating such as glass-transition temperature of polyimide resin, adhesiveness, and solder heat-resistance were evaluated as follows. A surface on which electroless plating is to be formed is referred to as a layer A and a surface to face a configured circuit is referred to as a layer B.

### [Glass-transition Temperature of Polyimide Resin]

The obtained polyimide resin was dissolved in dioxolane and a polyimide resin solution whose solid content density was 20 weight % was prepared. The solution was flow-casted and applied on a shine surface of a rolled copper foil (product name: BHY-22B-T, manufactured by Nikko Materials Co., Ltd.) and was dried at 60° C. for 1 minute, at 80° C. for 1 minute, at 100° C. for 3 minutes, at 120° C. for 1 minute, at 140° C. for 1 minute, at 150° C. for 3 minutes, and at 180° C. for 30 minutes, and after etching out the rolled copper foil, dried at 60° C. for 30 minutes. Thus was obtained a film whose thickness was 25 μm. The film thus obtained was subjected to measurement of dynamic viscoelasticity under the following measurement conditions, so that glass-transition temperature was obtained.

### (Measurement Conditions)

Measurement device: DMS6100 (manufactured by SII NanoTechnology Inc.)
Range of measured temperature: room temperature to 300° C.
Temperature rising speed: 3° C./min
Glass-transition temperature: tan 5 peak top temperature was regarded as glass-transition temperature
Sample: TD direction was regarded as a measurement direction

### [Adhesiveness]

A layer B of a material for plating having a supporter and a copper-clad laminate (CCL-HL950K Type SK, manufactured by MITSUBISHI GAS CHEMICAL COMPANY. INC.) were caused to face each other, and the material for plating and the copper-clad laminate were heated and pressurized at 170° C. under a pressure of 1 MPa in a vacuum for 6 minutes, and thereafter the supporter was detached and the layer B and the copper-clad laminate were dried at 180° C. for 60 minutes in a hot-air oven. Thus, a laminate was obtained. Thereafter, a copper layer was formed on the surface of a layer A that was exposed. The copper layer was formed in such a manner that, after desmear and electroless copper plating, an electrolytic plating copper layer whose thickness was 18 μm was formed on the electroless plating copper. Thereafter, the laminate was dried at 180° C. for 30 minutes and then adhesive strength of the laminate was measured in an ordinary state and at a time after Pressure Cooker Test (PCT) in accordance with JPCA-BU01-1998 (published by Japan Printed Circuits Association). Further, adhesive strength at a high temperature of the laminate was measured under the following conditions. Desmear and electroless copper plating were performed through processes shown in Tables 1 and 2 of the aforementioned Example A.
Adhesive strength in an ordinary state: adhesive strength measured after the laminate was left for 24 hours in an atmosphere where the temperature was 25° C. and the moisture was 50%.
Adhesive strength after PCT: adhesive strength measured after the laminate was left for 96 hours in an atmosphere where the temperature was 121° C. and the moisture was 100%.
Adhesive strength at a high temperature: adhesive strength measured in an atmosphere where the temperature was 120° C. after the laminate was left for 24 hours in an atmosphere where the temperature was 25° C. and the moisture was 50%.

### [Solder Heat-resistance]

The layer B of the material for plating having a supporter and a copper-clad laminate (CCL-HL950K Type SK, manufactured by MITSUBISHI GAS CHEMICAL COMPANY. INC.) were caused to face each other, and the material for plating and the copper-clad laminate were heated and pressurized at 170° C. under a pressure of 1 MPa in a vacuum for 6 minutes, and thereafter the supporter was detached and the layer B and the copper-clad laminate were dried at 180° C. for 60 minutes in a hot-air oven. Thus, a laminate was obtained. Thereafter, a copper layer was formed on the surface of the layer A that was exposed. The copper layer was formed in such a manner that, after desmear and electroless copper plating, an electrolytic plating copper layer whose thickness was 18 μm was formed on the electroless plating copper. The laminate was subjected to a heating and dry treatment at 180° C. for 30 minutes and was cut into pieces each of which had a size of 15 mm by 30 mm. The pieces were left for 200 hours under conditions that the temperature was 30° C. and the moisture, was 70%, and thus test pieces were obtained. The test pieces were put in an IR reflow oven under a condition that peak temperature was 260° C. and thus a solder heat-resistance test was performed. The IR reflow oven was a reflow oven FT-04 manufactured by CIS. This test was repeated three times and an unswollen piece was regarded as ◯ and a swollen piece was regarded as X. Desmear and electroless copper plating were performed through processes shown in Tables 1 and 2 as presented above.

### Example 8 of Synthesizing Polyimide Resin

37 g (0.045 mol) of KF-8010 (manufactured by Shin-Etsu Chemical Co., Ltd.), 21 g (0.105 mol) of 4,4′-diaminodiphenylether, and N,N-dimethylformamide (hereinafter referred to as DMF) were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus was obtained a DMF solution having polyamide acid whose solid content density was 30%. The polyamide acid solution was put in a tray coated with Teflon® and was depressurized and heated at 200° C. for 120 minutes at 665 Pa in a vacuum oven. Thus, polyimide resin 8 was obtained.

### Example 9 of Synthesizing Polyimide Resin

60.6 g (0.073 mol) of KF-8010 (manufactured by Shin-Etsu Chemical Co., Ltd.), 15.4 g (0.077 mol) of 4,4′-diaminodiphenylether, and N,N-dimethylformamide (hereinafter referred to as DMF) were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus was obtained a DMF solution having polyamide acid whose solid content density was 30%. The polyamide acid solution was put in a tray coated with Teflon® and was depressurized and heated at 200° C. for 120 minutes at 665 Pa in a vacuum oven. Thus, polyimide resin 9 was obtained.

### Example 10 of Synthesizing Polyimide Resin

99.6 g (0.12 mol) of KF-8010 (manufactured by Shin-Etsu Chemical Co., Ltd.), 6 g (0.03 mol) of 4,4′-diaminodiphenylether, and N,N-dimethylformamide (hereinafter referred to as DMF) were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus was obtained a DMF solution having polyamide acid whose solid content density was 30%. The polyamide acid solution was put in a tray coated with Teflon® and was depressurized and heated at 200° C. for 120 minutes at 665 Pa in a vacuum oven. Thus, polyimide resin 10 was obtained.

### Example 11 of Synthesizing Polyimide Resin

6.2 g (0.0075 mol) of KF-8010 (manufactured by Shin-Etsu Chemical Co., Ltd.), 28.5 g (0.1425 mol) of 4,4′-diaminodiphenylether, and N,N-dimethylformamide (hereinafter referred to as DMF) were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus was obtained a DMF solution having polyamide acid whose solid content density was 30%. The polyamide acid solution was put in a tray coated with Teflon® and was depressurized and heated at 200° C. for 120 minutes at 665 Pa in a vacuum oven. Thus, polyimide resin 11 was obtained.

### Example 12 of Synthesizing Polyimide Resin

41 g (0.143 mol) of 1,3-bis(3-aminophenoxy)benzene, 1.6 g (0.007 mol) of 3,3′-dihydroxy-4,4′-diaminobiphenyl, and DMF were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus was obtained a DMF solution having polyamide acid whose solid content density was 30%. The polyamide acid solution was put in a tray coated with Teflon® and was depressurized and heated at 200° C. for 180 minutes at 665 Pa in a vacuum oven. Thus, polyimide resin 12 was obtained.

### Example 7 of Preparation of Solution for Forming Layer A

Polyimide resin 1 was dissolved in dioxolane and a solution (C-a) for forming a layer A was obtained. Solid content density was set to 5 weight %.

### Example 8 of Preparation of Solution for Forming Layer A

Polyimide resin 2 was dissolved in dioxolane and a solution (C-b) for forming a layer A was obtained. Solid content density was set to 5 weight %.

### Example 9 of Preparation of Solution for Forming Layer A

Polyimide resin 3 was dissolved in dioxolane and a solution (C-c) for forming a layer A was obtained. Solid content density was set to 5 weight %.

### Example 10 of Preparation of Solution for Forming Layer A

Polyimide Resin 4 was Dissolved in Dioxolane and a solution (C-d) for forming a layer A was obtained. Solid content density was set to 5 weight %.

### Example 11 of Preparation of Solution for Forming Layer A

3.21 g of YX4000H (biphenyl epoxy resin; manufactured by Japan Epoxy Resins Co., Ltd.), 1.79 g of bis[4-(3-aminophenoxy)phenyl]sulfone (diamine; manufactured by Wakayama Seika Kogyo Co., Ltd.), and 0.02 g of 2,4-diamino-6-[2′-undecylimidazolyl-(1′)]-ethyl-s-triazine (epoxy curing agent; manufactured by Shikoku Chemicals Corporation) were dissolved in dioxolane and a solution (C-e) whose solid content density was 5% was obtained. 45 g of the solution (C-a) and 45 g of the solution (C-e) were mixed with each other and a solution (C-f) for forming the layer A was obtained.

### Example 2 of Preparation of Solution for Forming Layer B

Polyimide resin 5 was dissolved in dioxolane and a solution (C-g) for forming the layer A was obtained. Solid content density of the solution (C-g) was set to weight %.

On the other hand, 32.1 g of YX4000H (biphenyl epoxy resin; manufactured by Japan Epoxy Resins Co., Ltd.), 17.9 g of bis[4-(3-aminophenoxy)phenyl]sulfone (diamine; manufactured by Wakayama Seika Kogyo Co., Ltd.), and 0.2 g of 2,4-diamino-6-[2′-undecylimidazolyl-(1′)]-ethyl-s-triazine (epoxy curing agent; manufactured by Shikoku Chemicals Corporation) were dissolved in dioxolane and a solution (C-h) whose solid content density was 50% was obtained. 40 g of the solution (C-g) and 20 g of the solution (C-h) were mixed with each other and a solution (C-i) for forming the layer B was obtained.

### Example 18

The solution (C-a) for forming the layer A was flow-casted and applied on a surface of a resin film (product name: SG-1, manufactured by PANAC) serving as a supporter. Thereafter, the solution and the supporter were dried at 60° C. in a hot-air oven and a material made of the layer A whose thickness was 2 μm/the supporter was obtained. Further, the solution (C-i) for forming the layer B was flow-casted and applied on the surface of the layer A of the material made of the layer A/the supporter, dried at 60° C., 100° C., 120° C., and 150° C. Thus was obtained a material for plating having a supporter, which was made of the layer B whose thickness was 38 μm/the layer A whose thickness was 2 μm/the supporter. The material for plating having the supporter was evaluated in accordance with evaluation procedure of the evaluation items as described above. The result of the evaluation is shown in Table 12.

### Examples 19 and 20

Using the solution for forming the layer A shown in Table 12, a material for plating having a supporter that was made of the layer B/the layer A/the supporter was obtained through the same procedure as Example 18. The obtained material for plating having the supporter was evaluated in accordance with evaluation procedure of the evaluation items. The result of the evaluation was shown in Table 12.

### Example 21

The solution (C-a) for forming the layer A was flow-casted and applied on a surface of polyimide film (i) (product name: APICAL NPI, manufactured by KANEKA CORPORATION) of 25 μm prepared as the layer C. Thereafter, the solution and the polyimide film were dried at 60° C. in the hot-air oven and a material made of the layer A whose thickness was 2 μm/the layer C (polyimide film) was obtained. Further, the solution for forming the layer A was flow-casted and applied on the surface of the layer C of the material made of the layer A/the layer C, and dried at 60° C. and then dried at 180° C. for 60 minutes. Thus was obtained a material for plating made of the layer A whose thickness was 2 μm/the layer C/the layer A whose thickness was 2 μm. Thereafter, a copper layer was formed on the layer A that was exposed. The copper layer was formed in such a manner that, after desmear and electroless copper plating, an electrolytic plating copper layer whose thickness was 18 μm was formed on the electroless plating copper. After the material for plating was dried at 180° C. for 30 minutes, adhesiveness of the material for plating was evaluated in the same manner as the adhesiveness evaluation. Further, a part of this sample was cut into a piece whose size was 15 mm by 30 mm, and solder heat-resistance of the piece was evaluated in the same manner as the solder heat-resistance evaluation. The results of the evaluations were shown in Table 12.

### Example 22

The solution (C-a) for forming the layer A was flow-casted and applied on a surface of polyimide film (j) (product name: APICAL NPI, manufactured by KANEKA CORPORATION) of 25 μm prepared as the layer C. Thereafter, the solution and the polyimide film were dried at 60° C. in the hot-air oven and a material made of the layer A whose thickness was 2 μm/the layer C (polyimide film) was obtained. Further, the solution for forming the layer B was flow-casted and applied on the surface of the layer C of the material made of the layer A/the layer C, and dried at 60° C., 100° C., 120° C., and 150° C. Thus was obtained a material for plating made of the layer B whose thickness was 38 μm/the layer C/the layer A whose thickness was 2 μm.

The surface B of the material for plating and a copper-clad laminate (CCL-HL950K Type SK, manufactured BY MITSUBISHI GAS CHEMICAL COMPANY INC.) were caused to face each other, and the material for plating and the copper-clad laminate were heated and pressurized at 170° C. with a pressure of 1 MPa in a vacuum for 6 minutes, and then dried at 180° C. for 60 minutes in a hot-air oven. Thus, a laminate was obtained. A resin film (product name: SG-1, manufactured by PANAC) was used as an inserting paper for lamination. Thereafter, a copper layer was formed on the surface of the layer A that was exposed. The copper layer was formed in such a manner that, after desmear and electroless copper plating, an electrolytic plating copper layer whose thickness was 18 μm was formed on the electroless plating copper. After the material for plating was dried at 18° C. for 30 minutes, adhesiveness of the material for plating was evaluated in the same manner as the adhesiveness evaluation. Further, a part of this sample was cut into a piece whose size was 15 mm by 30 mm, and solder heat-resistance of the piece was evaluated in the same manner as the solder heat-resistance evaluation. The results of the evaluations were shown in Table 12.

### Example 23

The solution (C-a) for forming the layer A was flow-casted and applied on a surface of a resin film (product name: AFLEX, manufactured by ASAHI GLASS CO., LTD.) serving as a supporter. Thereafter, the solution and the resin film were dried at 60° C. in the hot-air oven and a material made of the layer A whose thickness was 2 μm/the supporter was obtained. The material and a prepreg (k) (product name: ES-3306S, manufactured by RISHO KOGYO CO., LTD.) prepared as a layer C are laminated with each other so as to form a laminate made of the supporter/the layer A/the prepreg/the layer A/the supporter, and the laminate was integrated at 170° C. under a pressure of 4 MPa for 2 hours. Thereafter, the supporters at both sides were detached from the laminate and the resulting laminate was dried at 180° C. for 30 minutes in the hot-air oven. Thus was obtained a laminate made of the layer A/the layer C whose thickness was 70 μm/the layer A.

Thereafter, a copper layer was formed on the layer A that was exposed. The copper layer was formed in such a manner that, after desmear and electroless copper plating, an electrolytic plating copper layer whose thickness was 18 μm was formed on the electroless plating copper. After the laminate was dried at 180° C. for 30 minutes, adhesiveness of the laminate was evaluated in the same manner as the adhesiveness evaluation.

Further, a part of this sample was cut into a piece whose size was 15 mm by 30 mm, and solder heat-resistance of the piece was evaluated in the same manner as the solder heat-resistance evaluation. The results of the evaluations were shown in Table 12.

### Comparative Example 7

A material for plating having a supporter which was made of a layer B/a layer A/a supporter was obtained in the same manner as Example 18 except that the solution (C-c) for forming the layer A was used. The obtained material for plating having the supporter was evaluated in accordance with evaluation procedure of the evaluation items. The result of the evaluation is shown in Table 13.

As is evident from Table 13, although Comparative Example 7 uses polyimide resin having a siloxane structure, Comparative Example 7 is inferior in its adhesive strength at a high temperature and solder heat-resistance because Comparative Example 7 has low glass-transition temperature.

### Comparative Example 8

A material for plating having a supporter which was made of a layer B/a layer A/a supporter was obtained in the same manner as Example 18 except that the solution (C-d) for forming the layer A was used. The obtained material for plating having the supporter was evaluated in accordance with evaluation procedure of the evaluation items. The result of the evaluation is shown in Table 13.

As is evident from Table 13, although Comparative Example 8 uses polyimide resin having a siloxane structure, Comparative Example 8 is inferior in its adhesive strength and solder heat-resistance because Comparative Example 8 has low glass-transition temperature.

TABLE 12

| | | Ex. | Ex. | Ex. | Ex. | Ex. | Ex. |
|---|---|---|---|---|---|---|---|
| | | 18 | 19 | 20 | 21 | 22 | 23 |
| Solution for forming | | (C-a) | (C-b) | (C-f) | (C-a) | (C-a) | (C-a) |
| layer A | | | | | | | |
| Solution for forming | | (C-i) | (C-i) | (C-i) | — | (C-i) | — |
| layer B | | | | | | | |
| Layer C | | — | — | — | (j) | (j) | (k) |
| Structure | | Layer A/ | Layer A/ | Layer A/ | Layer A/ | Layer A/ | Layer A/ |
| | | layer B | layer B | layer B | layer C/ | layer C/ | layer C/ |
| | | | | | layer A | layer B | layer A |
| Glass-transition | | 164 | 117 | 164 | 164 | 164 | 164 |
| temperature of | | | | | | | |
| polyimide resin | | | | | | | |
| Adhesive | Ordinary | 11 | 11 | 8 | 10 | 10 | 10 |
| strength | state | | | | | | |
| (N/cm) | After PCT | 6 | 8 | 6 | 6 | 6 | 6 |
| | At high | 10 | 8 | 8 | 9 | 8 | 10 |
| | temperature | | | | | | |

| | | | | | | |
|---|---|---|---|---|---|---|
| Solder heat-resistance | ◯ | ◯ | ◯ | ◯ | ◯ | ◯ |

TABLE 13

| | | Comp. Ex. | Comp. Ex. |
|---|---|---|---|
| | | 7 | 8 |
| Solution for forming layer A | | (C-c) | (C-d) |
| Solution for forming layer B | | (C-i) | (C-i) |
| Layer C | | — | — |
| Structure | | Layer A/layer B | Layer A/layer B |
| Glass-transition temperature | | 45 | 220 |
| (° C.) | | | |
| Adhesive | Ordinary state | 9 | 3 |
| strength | After PCT | 6 | 1 |
| (N/cm) | At high | 3 | 2 |
| | temperature | | |

| | | |
|---|---|---|
| Solder heat-resistance | X | X |

### Example D

In the present example, properties of material for plating such as weight-average molecular weight Mw of polyamide acid and polyimide resin, adhesiveness, solder heat-resistance were evaluated as follows. A surface on which electroless plating is to be formed is referred to as a layer A and a surface to face a configured circuit is referred to as a layer B.

### [Weight-Average Molecular Weight Mw of Polyimide Resin]

The obtained polyimide resin was measured by gel permeation chromatography under the following conditions so as to calculate weight-average molecular weight Mw of the obtained polyimide resin. The sample used here was a solution obtained by dissolving polyimide resin in a solvent having the same mobile phase as presented below so that density of the polyimide resin was 0.1 weight %.

### (Measurement Conditions)

Measurement device: HLC-8220GPC (manufactured by Tosoh Corporation)
Column: two connected columns of TSK gel Super AWM-H manufactured by Tosoh Corporation
   Guardcolumn: TSK guardcolumn Super AW-H manufactured by Tosoh Corporation
Mobile phase: N,N-dimethylformamide containing 0.02M of phosphoric acid and 0.03M of lithium bromide
Column temperature: 40° C.
Flow rate: 0.6 ml/min

### [Adhesiveness]

A layer B of a material for plating having a supporter and a copper-clad laminate (CCL-HL950K Type SK, manufactured by MITSUBISHI GAS CHEMICAL COMPANY. INC.) were caused to face each other, and the material for plating and the copper-clad laminate were heated and pressurized at 170° C. under a pressure of 1 MPa in a vacuum for 6 minutes, and thereafter the supporter was detached and the layer B and the copper-clad laminate were dried at 180° C. for 60 minutes in a hot-air oven. Thus, a laminate was obtained. Thereafter, a copper layer was formed on the surface of a layer A that was exposed. The copper layer was formed in such a manner that, after desmear and electroless copper plating, an electrolytic plating copper layer whose thickness was 18 μm was formed on the electroless plating copper. Thereafter, the laminate was dried at 180° C. for 30 minutes and then adhesive strength of the laminate in an ordinary state and adhesive strength of the laminate at a time after Pressure Cooker Test (PCT) were measured in accordance with JPCA-BU01-1998 (published by Japan Printed Circuits Association). Desmear and electroless copper plating were performed through processes shown in Tables 1 and 2 of the aforementioned Example A.
Adhesive strength in an ordinary state: adhesive strength measured after the laminate was left for 24 hours in an atmosphere where the temperature was 25° C. and the moisture was 50%.
Adhesive strength after PCT: adhesive strength measured after the laminate was left for 96 hours at an atmosphere where the temperature was 121° C. and the moisture was 100%.

### [Solder Heat-resistance]

The layer B of the material for plating having a supporter and a copper-clad laminate (CCL-HL950K Type SK, manufactured by MITSUBISHI GAS CHEMICAL COMPANY. INC.) were caused to face each other, and the material for plating and the copper-clad laminate were heated and pressurized at 170° C. under a pressure of 1 MPa in a vacuum for 6 minutes, and thereafter the supporter was detached and the material for plating and the copper-clad laminate were dried at 180° C. for 60 minutes in a hot-air oven. Thus, a laminate was obtained. Thereafter, a copper layer was formed on the surface of the layer A that was exposed. The copper layer was formed in such a manner that, after desmear and electroless copper plating, an electrolytic plating copper layer whose thickness was 18 μm was formed on the electroless plating copper. The laminate was subjected to a heating and dry treatment at 180° C. for 30 minutes and was cut into pieces each of which had a size of 15 mm by 30 mm. The pieces were left for 200 hours under conditions that the temperature was 30° C. and the moisture was 70%, and thus test pieces were obtained. The test pieces were put in an IR reflow oven under a condition that peak temperature was 260° C. and thus a solder heat-resistance test was performed. The IR reflow oven was a reflow oven FT-04 manufactured by CIS. This test was repeated three times and an unswollen piece was regarded as ◯ and a swollen piece was regarded as X. Desmear and electroless copper plating were performed through processes shown in Tables 1 and 2 as presented above.

### Example 13 of Synthesizing Polyimide Resin

37.10 g (0.0447 mol) of KF-8010 (functional group equivalent weight 415) (manufactured by Shin-Etsu Chemical Co., Ltd.), 21.08 g (0.1053 mol) of 4,4′-diaminodiphenylether (purity 99%), and N,N-dimethylformamide (hereinafter referred to as DMF) were put in a glass flask whose capacity was 2000 ml, were stirred and dissolved. 78.34 g (0.1505 mol) of 4,4′-(4,4′-isopropylidenediphenoxy)bis(phthalic anhydride) (purity 99%) was added to the mixed solution and the solution was stirred for approximately 1 hour at a room temperature. Thus was obtained a DMF solution having polyamide acid whose solid content density was 35%. Viscosity of the solution was 340 poises. The polyamide acid solution was put in a tray coated with Teflon® and was depressurized and heated at 200° C. for 120 minutes at 665 Pa in a vacuum oven. Thus, polyimide resin 13 was obtained.

### Example 14 of Synthesizing Polyimide Resin

3.2 g of β-picoline and 3.5 g of acetic anhydride were added to 50 g of the polyamide acid solution obtained in the synthesization example 1 and the resulting solution was stirred at a room temperature for 10 hours so that the solution was imidized. Thereafter, the solution was poured little by little into isopropanol that had been stirred at high speed, so that filamentous polyimide resin was obtained. The polyimide resin was dried at 50° C. for 30 minutes and then pulverized by a mixer, rinsed twice with isopropanol, and dried at 50° C. for 2 hours, so that thermoplastic polyimide resin 14 was obtained.

### Example 15 of Synthesizing Polyimide Resin

37.10 g (0.0447 mol) of KF-8010 (functional group equivalent weight 415) (manufactured by Shin-Etsu Chemical Co., Ltd.), 21.08 g (0.1053 mol) of 4,4′-diaminodiphenylether (purity 99%), and N,N-dimethylformamide (hereinafter referred to as DMF) were put in a glass flask whose capacity was 2000 ml, were stirred and dissolved. 75.99 g (0.1460 mol) of 4,4′-(4,4′-isopropylidenediphenoxy)bis(phthalic anhydride) was added to the mixed solution and the solution was stirred for approximately 1 hour at a room temperature. Thus was obtained a DMF solution having polyamide acid whose solid content density was 35%. Viscosity of the solution was 23 poises. The polyamide acid solution was put in a tray coated with Teflon® and was depressurized and heated at 200° C. for 60 minutes at 665 Pa in a vacuum oven. Thus, polyimide resin 15 was obtained.

### Example 16 of Synthesizing Polyimide Resin

37.10 g (0.0447 mol) of KF-8010 (functional group equivalent weight 415) (manufactured by Shin-Etsu Chemical Co., Ltd.), 21.08 g (0.1053 mol) of 4,4′-diaminodiphenylether (purity 99%), and N,N-dimethylformamide (hereinafter referred to as DMF) were put in a glass flask whose capacity was 2000 ml, were stirred and dissolved. 80.68 g (0.1550 mol) of 4,4′-(4,4′-isopropylidenediphenoxy)bis(phthalic anhydride) was added to the mixed solution and the solution was stirred for approximately 1 hour at a room temperature. Thus was obtained a DMF solution having polyamide acid whose solid content density was 35%. Viscosity of the solution was 18 poises. The polyamide acid solution was put in a tray coated with Teflon® and was depressurized and heated at 200° C. for 60 minutes at 665 Pa in a vacuum oven. Thus, polyimide resin 16 was obtained.

### Example 17 of Synthesizing Polyimide Resin

37.10 g (0.0447 mol) of KF-8010 (functional group equivalent weight 415) (manufactured by Shin-Etsu Chemical Co., Ltd.), 21.08 g (0.1053 mol) of 4,4′-diaminodiphenylether (purity 99%), and N,N-dimethylformamide (hereinafter referred to as DMF) were put in a glass flask whose capacity was 2000 ml, were stirred and dissolved. 73.65 g (0.1415 mol) of 4,4′-(4,4′-isopropylidenediphenoxy)bis(phthalic anhydride) was added to the mixed solution and the solution was stirred for approximately 1 hour at a room temperature. Thus was obtained a DMF solution having polyamide acid whose solid content density was 35%. Viscosity of the solution was 5 poises. 3.2 g of β-picoline and 3.5 g of acetic anhydride were added to 50 g of the polyamide acid solution and the resulting solution was stirred at a room temperature for 10 hours so that the solution was imidized. Thereafter, the solution was poured little by little into isopropanol that had been stirred at high speed, so that filamentous polyimide resin was obtained. The polyimide resin was dried at 50° C. for 30 minutes and then pulverized by a mixer, rinsed twice with isopropanol, and dried at 50° C. for 2 hours, so that thermoplastic polyimide resin 17 was obtained.

### Example 18 of Synthesizing Polyimide Resin

37.10 g (0.0447 mol) of KF-8010 (functional group equivalent weight 415) (manufactured by Shin-Etsu Chemical Co., Ltd.), 21.08 g (0.1053 mol) of 4,4′-diaminodiphenylether (purity 99%), and N,N-dimethylformamide (hereinafter referred to as DMF) were put in a glass flask whose capacity was 2000 ml, were stirred and dissolved. 83.80 g (0.1610 mol) of 4,4′-(4,4′-isopropylidenediphenoxy)bis(phthalic anhydride) was added to the mixed solution and the solution was stirred for approximately 1 hour at a room temperature. Thus was obtained a DMF solution having polyamide acid whose solid content density was 35%. Viscosity of the solution was 4 poises. 3.2 g of β-picoline and 3.5 g of acetic anhydride were added to 50 g of the polyamide acid solution and the resulting solution was stirred at a room temperature for 10 hours so that the solution was imidized. Thereafter, the solution was poured little by little into isopropanol that had been stirred at high speed, so that filamentous polyimide resin was obtained. The polyimide resin was dried at 50° C. for 30 minutes and then pulverized by a mixer, rinsed twice with isopropanol, and dried at 50° C. for 2 hours, so that thermoplastic polyimide resin 18 was obtained.

### Example 19 of Synthesizing Polyimide Resin

41.72 g (0.1427 mol) of 1,3-bis(3-aminophenoxy)benzene (purity 98.1%), 1.58 g (0.0073 mol) of 3,3′-dihydroxy-4,4′-diaminobiphenyl (purity 99.6%), and DMF were put in a glass flask whose capacity was 2000 ml, were stirred and dissolved. 77.45 g (0.1488 mol) of 4,4′-(4,4′-isopropylidenediphenoxy)bis(phthalic anhydride) (purity 99.0%) was added to the mixed solution and the solution was stirred for approximately 1 hour. Thus was obtained a DMF solution having polyamide acid whose solid content density was 35%. Viscosity of the solution was 410 poises. The polyamide acid solution was put in a tray coated with Teflon® and was depressurized and heated at 200° C. for 180 minutes at 665 Pa in a vacuum oven. Thus, polyimide resin 19 was obtained.

### Example 12 of Preparation of Solution for Forming Layer A

Polyimide resin 1 was dissolved in dioxolane and a solution (D-a) for forming a layer A was obtained. Solid content density was set to 5 weight %.

### Example 13 of Preparation of Solution for Forming Layer A

Polyimide resin 2 was dissolved in dioxolane and a solution (D-b) for forming a layer A was obtained. Solid content density was set to 5 weight %.

### Example 14 of Preparation of Solution for Forming Layer A

Polyimide resin 3 was dissolved in dioxolane and a solution (D-c) for forming a layer A was obtained. Solid content density was set to 5 weight %.

### Example 15 of Preparation of Solution for Forming Layer A

Polyimide resin 4 was dissolved in dioxolane and a solution (D-d) for forming a layer A was obtained. Solid content density was set to 5 weight %.

### Example 16 of Preparation of Solution for Forming Layer A

Polyimide resin 5 was dissolved in dioxolane and a solution (D-e) for forming a layer A was obtained. Solid content density was set to 5 weight %.

### Example 17 of Preparation of Solution for Forming Layer A

Polyimide resin 6 was dissolved in dioxolane and a solution (D-f) for forming a layer A was obtained. Solid content density was set to 5 weight %.

### Example 3 of Preparation of Solution for Forming Layer B

Polyimide resin 7 was dissolved in dioxolane and a solution (D-g) whose solid content density was 25 weight % was obtained. On the other hand, 32.1 g of YX4000H (biphenyl epoxy resin; manufactured by Japan Epoxy Resins Co., Ltd.), 17.9 g of bis[4-(3-aminophenoxy)phenyl]sulfone (diamine; manufactured by Wakayama Seika Kogyo Co., Ltd.), and 0.2 g of 2,4-diamino-6-[2′-undecylimidazolyl-(1′)]-ethyl-s-triazine (epoxy curing agent; manufactured by Shikoku Chemicals Corporation) were dissolved in dioxolane and a solution (D-h) whose solid content density was 50% was obtained. 40 g of the solution (D-g) and 20 g of the solution (D-h) were mixed with each other and a solution (D-i) for forming the layer B was obtained.

### Example 24

The solution (D-a) for forming the layer A was flow-casted and applied on a surface of a resin film (product name: SG-1, manufactured by PANAC) serving as a supporter. Thereafter, the solution and the supporter were dried at 60° C. in a hot-air oven and an insulating sheet made of the layer A whose thickness was 2 μm/the supporter was obtained. Further, the solution (D-i) for forming the layer B was flow-casted and applied on the surface of the layer A of the insulating sheet made of the layer A/the supporter, dried at 60° C., 100° C., 120° C., and 150° C. Thus was obtained a material for plating having a supporter, which was made of the layer B whose thickness was 38 μm/the layer A whose thickness was 2 μm/the supporter. The insulating sheet having the supporter was evaluated in accordance with evaluation procedure of the evaluation items as described above. The result of the evaluation is shown in Table 14.

### Examples 25 to 27

Using the solution for forming the layer A shown in Table 14, an insulating sheet having a supporter that was made of the layer B/the layer A/the supporter was obtained through the same procedure as Example 24. The obtained insulating sheet having the supporter was evaluated in accordance with evaluation procedure of the evaluation items. The result of the evaluation was shown in Table 14.

### Example 28

The solution (D-a) for forming the layer A was flow-casted and applied on a surface of polyimide film 0) (product name: APICAL NPI, manufactured by KANEKA CORPORATION) of 25 μm prepared as the layer C. Thereafter, the solution and the polyimide film were dried at 60° C. in the hot-air oven and a material made of the layer A whose thickness was 2 μm/the layer C (polyimide film) was obtained. Further, the solution for forming the layer A was flow-casted and applied on the surface of the layer C of the material made of the layer A/the layer C, and dried at 60° C. and then dried at 180° C. for 60 minutes. Thus was obtained an insulating sheet made of the layer A whose thickness was 2 μm/the layer C/the layer A whose thickness was 2 μm. Thereafter, a copper layer was formed on the layer A that was exposed. The copper layer was formed in such a manner that, after desmear and electroless copper plating, an electrolytic plating copper layer whose thickness was 18 μm was formed on the electroless plating copper. After the insulating sheet on which the copper layer had been formed was dried at 180° C. for 30 minutes, adhesiveness of the insulating sheet on which the copper layer had been formed was evaluated in the same manner as the adhesiveness evaluation. Further, a part of this sample was cut into a piece whose size was 15 mm by 30 mm, and solder heat-resistance of the piece was evaluated in the same manner as the solder heat-resistance evaluation. The results of the evaluations were shown in Table 14.

### Example 29

The solution (D-a) for forming the layer A was flow-casted and applied on a surface of polyimide film (j) (product name: APICAL NPI, manufactured by KANEKA CORPORATION) of 251 μm prepared as the layer C. Thereafter, the solution and the polyimide film were dried at 60° C. in the hot-air oven and a material made of the layer A whose thickness was 2 μm/the layer C (polyimide film) was obtained. Further, the solution (D-i) for forming the layer B was flow-casted and applied on the surface of the layer C of the material made of the layer A/the layer C, and dried at 60° C., 100° C., 120° C., and 150° C. Thus was obtained a material for plating made of the layer B whose thickness was 38 μm/the layer C/the layer A whose thickness was 2 μm.

The surface B of the material for plating and a copper-clad laminate (CCL-HL950K Type SK, manufactured BY MITSUBISHI GAS CHEMICAL COMPANY INC.) were caused to face each other, and the material for plating and the copper-clad laminate were heated and pressurized at 170° C. with a pressure of 1 MPa in a vacuum for 6 minutes, and then dried at 180° C. for 60 minutes in a hot-air oven. Thus, a laminate was obtained. A resin film (product name: SG-1, manufactured by PANAC) was used as an inserting paper for lamination. Thereafter, a copper layer was formed on the surface of the layer A that was exposed. The copper layer was formed in such a manner that, after desmear and electroless copper plating, an electrolytic plating copper layer whose thickness was 18 μm was formed on the electroless plating copper. After the material for plating was dried at 180° C. for 30 minutes, adhesiveness of the material for plating was evaluated in the same manner as the adhesiveness evaluation. Further, a part of this sample was cut into a piece whose size was 15 mm by 30 mm, and solder heat-resistance of the piece was evaluated in the same manner as the solder heat-resistance evaluation. The results of the evaluations were shown in Table 14.

### Example 30

The solution (D-a) for forming the layer A was flow-casted and applied on a surface of a resin film (product name: AFLEX, manufactured by ASAHI GLASS CO., LTD.) serving as a supporter. Thereafter, the solution and the resin film were dried at 60° C. in the hot-air oven and a material made of the layer A whose thickness was 2 μm/the supporter was obtained. The material and a prepreg (k) (product name: ES-3306S, manufactured by RISHO KOGYO CO., LTD.) prepared as a layer C are laminated with each other so as to form a laminate made of the supporter/the layer A/the prepreg/the layer A/the supporter, and the laminate was integrated at 170° C. under a pressure of 4 MPa for 2 hours. Thereafter, the supporters at both sides were detached from the laminate and the resulting laminate was dried at 180° C. for 30 minutes in the hot-air oven. Thus was obtained a laminate made of the layer A/the layer C whose thickness was 70 μm/the layer A.

Thereafter, a copper layer was formed on the layer A that was exposed. The copper layer was formed in such a manner that, after desmear and electroless copper plating, an electrolytic plating copper layer whose thickness was 18 μm was formed on the electroless plating copper. After the laminate was dried at 180° C. for 30 minutes, adhesiveness of the laminate was evaluated in the same manner as the adhesiveness evaluation. Further, a part of this sample was cut into a piece whose size was 15 mm by 30 mm, and solder heat-resistance of the piece was evaluated in the same manner as the solder heat-resistance evaluation. The results of the evaluations were shown in Table 14.

### Comparative Example 9

A material for plating having a supporter which was made of a layer B/a layer A/a supporter was obtained in the same manner as Example 24 except that the solution (D-e) for forming the layer A was used. The obtained material for plating having the supporter was evaluated in accordance with evaluation procedure of the evaluation items. The result of the evaluation is shown in Table 15.

### Comparative Example 10

A material for plating having a supporter which was made of a layer B/a layer A/a supporter was obtained in the same manner as Example 24 except that the solution (D-f) for forming the layer A was used. The obtained material for plating having the supporter was evaluated in accordance with evaluation procedure of the evaluation items. The result of the evaluation is shown in Table 15.

As is evident from Table. 15, although Comparative Examples 9 and 10 use polyimide resin having a siloxane structure, Comparative Examples 9 and 10 are inferior in their adhesive strength and solder heat-resistance because the polyimide resin of Comparative Examples 9 and 10 has low weight-average molecular weight.

TABLE 14

| | | Ex. | Ex. | Ex. | Ex. | Ex. | Ex. | Ex. |
|---|---|---|---|---|---|---|---|---|
| | | 24 | 25 | 26 | 27 | 28 | 29 | 30 |
| Solution for forming layer | | (D-a) | (D-b) | (D-c) | (D-d) | (D-a) | (D-a) | (D-a) |
| A | | | | | | | | |
| Solution for forming layer | | (D-i) | (D-i) | (D-i) | (D-i) | — | (D-i) | — |
| B | | | | | | | | |
| Layer C | | — | — | — | — | (j) | (j) | (k) |
| Structure | | Layer A/ | Layer A/ | Layer A/ | Layer A/ | Layer A/ | Layer A/ | Layer A/ |
| | | layer B | layer B | layer B | layer B | layer C/ | layer C/ | layer C/ |
| | | | | | | layer A | layer B | layer A |
| Weight-average molecular | | 84000 | 52000 | 48000 | 45000 | 84000 | 84000 | 84000 |
| weight Mw of polyimide | | | | | | | | |
| used for layer A | | | | | | | | |
| Adhesive | Ordinary | 11 | 9 | 9 | 9 | 11 | 10 | 10 |
| strength | state | | | | | | | |
| (N/cm) | After PCT | 6 | 6 | 6 | 5 | 6 | 6 | 6 |

| | | | | | | | |
|---|---|---|---|---|---|---|---|
| Solder heat-resistance | ◯ | ◯ | ◯ | ◯ | ◯ | ◯ | ◯ |

TABLE 15

| | | Com. Ex. | Com. Ex. |
|---|---|---|---|
| | | 9 | 10 |
| Solution for forming | | (D-e) | (D-f) |
| layer A | | | |
| Solution for forming | | (D-i) | (D-i) |
| layer B | | | |
| Layer C | | — | — |
| Structure | | Layer A/layer B | Layer A/layer B |
| Weight-average | | 24000 | 17000 |
| molecular weight Mw of | | | |
| polyimide used for layer A | | | |
| Adhesive | Ordinary | 5 | 4 |
| strength | state | | |
| (N/cm) | After PCT | 2 | 2 |

| | | |
|---|---|---|
| (Solder heat-resistance | X | X |

### Example E

In the present example, properties of material for plating such as adhesiveness and solder heat-resistance were evaluated as follows. A surface on which electroless plating is to be formed is referred to as a layer A and a surface to face a configured circuit is referred to as a layer B.

### [Adhesiveness]

A layer B of a material for plating having a supporter and a copper-clad laminate (CCL-HL950K Type SK, manufactured by MITSUBISHI GAS CHEMICAL COMPANY. INC.) were caused to face each other, and the material for plating and the copper-clad laminate were heated and pressurized at 170° C. under a pressure of 1 MPa in a vacuum for 6 minutes, and thereafter the supporter was detached and the material for plating and the copper-clad laminate were dried at 180° C. for 60 minutes in a hot-air oven. Thus, a laminate was obtained. Thereafter, a copper layer was formed on the surface of a layer A that was exposed. The copper layer was formed in such a manner that, after desmear and electroless copper plating, an electrolytic plating copper layer whose thickness was 18 μm was formed on the electroless plating copper. Thereafter, the laminate was dried at 180° C. for 30 minutes and then adhesive strength of the laminate in an ordinary state and adhesive strength of the laminate at a time after Pressure Cooker Test (PCT) were measured in accordance with JPCA-BU01-1998 (published by Japan Printed Circuits Association). Desmear and electroless copper plating were performed through processes shown in Tables 1 and 2 of the aforementioned Example A.
Adhesive strength in an ordinary state: adhesive strength measured after the laminate was left for 24 hours in an atmosphere where the temperature was 25° C. and the moisture was 50%.
Adhesive strength after PCT: adhesive strength measured after the laminate was left for 96 hours at an atmosphere where the temperature was 121° C. and the moisture was 100%.

### [Solder Heat-resistance]

The layer B of the material for plating having a supporter and a copper-clad laminate (CCL-HL950K Type SK, manufactured by MITSUBISHI GAS CHEMICAL COMPANY. INC.) were caused to face each other, and the material for plating and the copper-clad laminate were heated and pressurized at 170° C. under a pressure of 1 MPa in a vacuum for 6 minutes, and thereafter the supporter was detached and the layer B and the copper-clad laminate were dried at 180° C. for 60 minutes in a hot-air oven. Thus, a laminate was obtained. Thereafter, a copper layer was formed on the surface of the layer A that was exposed. The copper layer was formed in such a manner that, after desmear and electroless copper plating, an electrolytic plating copper layer whose thickness was 18 μm was formed on the electroless plating copper. The laminate was subjected to a heating and dry treatment at 180° C. for 30 minutes and was cut into pieces each of which had a size of 15 mm by 30 mm. The pieces were left for 200 hours under conditions that the temperature was 30° C. and the moisture was 70%, and thus test pieces were obtained. The test pieces were put in an IR reflow oven under a condition that peak temperature was 260° C. and thus a solder heat-resistance test was performed. The IR reflow oven was a reflow oven FT-04 manufactured by CIS. This test was repeated three times and an unswollen piece was regarded as ◯ and a swollen piece was regarded as X. Desmear and electroless copper plating were performed through processes shown in Tables 1 and 2 as presented above.

### Example 20 of Synthesizing Polyimide Resin

37 g (0.045 mol) of KF-8010 (manufactured by Shin-Etsu Chemical Co., Ltd.), 19.52 g (0.0975 mol) of 4,4′-diaminodiphenylether, 1.62 g (0.0075 mol) of 3,3′-dihydroxy-4,4′-diaminobiphenyl and N,N-dimethylformamide (hereinafter referred to as DMF) were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus was obtained a DMF solution having polyamide acid whose solid content density was 35%. 3.2 g of β-picoline and 3.5 g of acetic anhydride were added to 50 g of the polyamide acid solution and the resulting solution was stirred at a room temperature for 10 hours so that the solution was imidized. Thereafter, the solution was poured little by little into isopropanol that had been stirred at high speed, so that filamentous polyimide resin was obtained. The polyimide resin was dried at 50° C. for 30 minutes and then pulverized by a mixer, rinsed twice with isopropanol, and dried at 50° C. for 2 hours, so that polyimide resin 20 was obtained.

### Example 21 of Synthesizing Polyimide Resin

37 g (0.045 mol) of KF-8010 (manufactured by Shin-Etsu Chemical Co., Ltd.), 18 g (0.09 mol) of 4,4′-diaminodiphenylether, 3.24 g (0.015 mol) of 3,3′-dihydroxy-4,4′-diaminobiphenyl and N,N-dimethylformamide (hereinafter referred to as DMF) were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus was obtained a DMF solution having polyamide acid whose solid content density was 30%. 3.2 g of β-picoline and 3.5 g of acetic anhydride were added to 50 g of the polyamide acid solution and the resulting solution was stirred at a room temperature for 10 hours so that the solution was imidized. Thereafter, the solution was poured little by little into isopropanol that had been stirred at high speed, so that filamentous polyimide resin was obtained. The polyimide resin was dried at 50° C. for 30 minutes and then pulverized by a mixer, rinsed twice with isopropanol, and dried at 50° C. for 2 hours, so that polyimide resin 21 was obtained.

### Example 22 of Synthesizing Polyimide Resin

37 g (0.045 mol) of KF-8010 (manufactured by Shin-Etsu Chemical Co., Ltd.), 19.52 g (0.0975 mol) of 4,4′-diaminodiphenylether, 2.15 g (0.0075 mol) of 5,5′-methylene-bis(anthranilic acid) and N,N-dimethylformamide (hereinafter referred to as DMF) were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus was obtained a DMF solution having polyamide acid whose solid content density was 30%. The polyamide acid solution was put in a tray coated with Teflon® and was depressurized and heated at 200° C. for 100 minutes at 665 Pa in a vacuum oven. Thus, polyimide resin 22 was obtained.

### Example 23 of Synthesizing Polyimide Resin

37 g (0.045 mol) of KF-8010 (manufactured by Shin-Etsu Chemical Co., Ltd.), 18 g (0.09 mol) of 4,4′-diaminodiphenylether, 3.41 g (0.015 mol) of 4,4′-diaminobenzanilide and N,N-dimethylformamide (hereinafter referred to as DMF) were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus was obtained a DMF solution having polyamide acid whose solid content density was 30%. The polyamide acid solution was put in a tray coated with Teflon® and was depressurized and heated at 200° C. for 100 minutes at 665 Pa in a vacuum oven. Thus, polyimide resin 23 was obtained.

### Example 24 of Synthesizing Polyimide Resin

41 g (0.143 mol) of 1,3-bis(3-aminophenoxy)benzene, 1.6 g (0.007 mol) of 3,3′-dihydroxy-4,4′-diaminobiphenyl, and DMF were put in a glass flask whose capacity was 2000 ml, were stirred and dissolved. 78 g (0.15 mol) of 4,4′-(4,4′-isopropylidenediphenoxy)bis(phthalic anhydride) was added to the mixed solution and the solution was stirred for approximately 1 hour. Thus was obtained a DMF solution having polyamide acid whose solid content density was 30%. The polyamide acid solution was put in a tray coated with Teflon® and was depressurized and heated at 200° C. for 180 minutes at 665 Pa in a vacuum oven. Thus, polyimide resin 24 was obtained.

### Example 18 of Preparation of Solution for Forming Layer A

Polyimide resin 1 was dissolved in dioxolane and a solution (E-a) for forming a layer A was obtained. Solid content density was set to 5 weight %.

### Example 19 of Preparation of Solution for Forming Layer A

Polyimide resin 2 was dissolved in dioxolane and a solution (E-b) for forming a layer A was obtained. Solid content density was set to 5 weight %.

### Example 20 of Preparation of Solution for Forming Layer A

Polyimide resin 3 was dissolved in dioxolane and a solution (E-c) for forming a layer A was obtained. Solid content density was set to 5 weight %.

### Example 21 of Preparation of Solution for Forming Layer A

Polyimide resin 4 was dissolved in dioxolane and a solution (E-d) for forming a layer A was obtained. Solid content density was set to 5 weight %.

### Example 22 of Preparation of Solution for Forming Layer A

3.21 g of YX4000H (Biphenyl Epoxy Resin; manufactured by Japan Epoxy Resins Co., Ltd.), 1.79 g of bis[4-(3-aminophenoxy)phenyl]sulfone (diamine; manufactured by Wakayama Seika Kogyo Co., Ltd.), and 0.02 g of 2,4-diamino-6-[2′-undecylimidazolyl-(1′)]-ethyl-s-triazine (epoxy curing agent; manufactured by Shikoku Chemicals Corporation) were dissolved in dioxolane and a solution (E-e) whose solid content density was 5% was obtained. 20 g of the solution (E-a) and 3 g of the solution (E-e) were mixed with each other so that a solution (E-f) was obtained.

### Example 23 of Preparation of Solution for Forming Layer A

20 g of the solution (E-d) and 8 g of the solution (E-e) were mixed with each other so that a solution (E-g) was obtained.

### Example 4 of Preparation of Solution for Forming Layer B

Polyimide resin 5 was dissolved in dioxolane and a polyimide resin solution (E-h) was obtained. Solid content density of the solution (E-h) was set to 25 weight %.

On the other hand, 32.1 g of YX4000H (biphenyl epoxy resin; manufactured by Japan Epoxy Resins Co., Ltd.), 17.9 g of bis[4-(3-aminophenoxy)phenyl]sulfone (diamine; manufactured by Wakayama Seika Kogyo Co., Ltd.), and 0.2 g of 2,4-diamino-6-[2′-undecylimidazolyl-(1′)]-ethyl-s-triazine (epoxy curing agent; manufactured by Shikoku Chemicals Corporation) were dissolved in dioxolane and a solution (E-i) whose solid content density was 50% was obtained. 40 g of the solution (E-h) and 20 g of the solution (E-i) were mixed with each other so that a solution (E-j) for forming the layer B was obtained.

### Example 31

The solution (E-a) for forming the layer A was flow-casted and applied on a surface of a resin film (product name: SG-1, manufactured by PANAC) serving as a supporter. Thereafter, the solution and the supporter were dried at 60° C. in a hot-air oven. Thus was obtained a material made of the layer A whose thickness was 2 μm/the supporter. Further, the solution for forming the layer B was flow-casted and applied on the surface of the layer A of the material made of the layer A/the supporter, dried at 60° C., 100° C., 120° C., and 150° C. Thus was obtained a material for plating having a supporter which was made of the layer B whose thickness was 38 μm/the layer A whose thickness was 2 μm/the supporter. The material for plating having the supporter was evaluated in accordance with evaluation procedure of the evaluation items as described above. The result of the evaluation is shown in Table 16.

### Examples 32 to 36

Using the solution for forming the layer A shown in Table 3, a material for plating having a supporter that was made of the layer B/the layer A/the supporter was obtained through the same procedure as Example 31. The obtained material for plating having the supporter was evaluated in accordance with evaluation procedure of the evaluation items. The result of the evaluation is shown in Table 16.

### Example 37

The solution (E-a) for forming the layer A was flow-casted and applied on a surface of polyimide film (k) (product name: APICAL NPI, manufactured by KANEKA CORPORATION) of 25 μm prepared as the layer C. Thereafter, the solution and the polyimide film were dried at 60° C. in the hot-air oven. Thus was obtained a material made of the layer A whose thickness was 2 μm/the layer C (polyimide film). Further, the solution for forming the layer A was flow-casted and applied on the surface of the layer C of the material made of the layer A/the layer C, and dried at 60° C. and then dried at 180° C. for 60 minutes. Thus was obtained a material for plating made of the layer A whose thickness was 2 μm/the layer C/the layer A whose thickness was 2 μm. Thereafter, a copper layer was formed on the layer A that was exposed. The copper layer was formed in such a manner that, after desmear and electroless copper plating, an electrolytic plating copper layer whose thickness was 18 μm was formed on the electroless plating copper. After the material for plating was dried at 180° C. for 30 minutes, adhesiveness of the material for plating was evaluated in the same manner as the adhesiveness evaluation. Further, a part of this sample was cut into a piece whose size was 15 mm by 30 mm, and solder heat-resistance of the piece was evaluated in the same manner as the solder heat-resistance evaluation. The results of the evaluations are shown in Table 16.

### Example 38

The solution (E-a) for forming the layer A was flow-casted and applied on a surface of polyimide film (k) (product name: APICAL NPI, manufactured by KANEKA CORPORATION) of 25 μm prepared as the layer C. Thereafter, the solution and the polyimide film were dried at 60° C. in the hot-air oven. Thus was obtained a material made of the layer A whose thickness was 2 μm/the layer C (polyimide film). Further, the solution for forming the layer B was flow-casted and applied on the surface of the layer C of the material made of the layer A/the layer C, and dried at 60° C., 100° C., 120° C., and 150° C. Thus was obtained a material for plating made of the layer B whose thickness was 38 μm/the layer C/the layer A whose thickness was 2 μm.

The surface B of the material for plating and a copper-clad laminate (CCL-HL950K Type SK, manufactured BY MITSUBISHI GAS CHEMICAL COMPANY INC.) were caused to face each other, and the material for plating and the copper-clad laminate were heated and pressurized at 170° C. with a pressure of 1 MPa in a vacuum for 6 minutes, and then dried at 180° C. for 60 minutes in a hot-air oven. Thus, a laminate was obtained. A resin film (product name: SG-1, manufactured by PANAC) was used as an inserting paper for lamination. Thereafter, a copper layer was formed on the surface of the layer A that was exposed. The copper layer was formed in such a manner that, after desmear and electroless copper plating, an electrolytic plating copper layer whose thickness was 18 μm was formed on the electroless plating copper. After the laminate was dried at 180° C. for 30 minutes, adhesiveness of the laminate was evaluated in the same manner as the adhesiveness evaluation. Further, a part of this sample was cut into a piece whose size was 15 mm by 30 mm, and solder heat-resistance of the piece was evaluated in the same manner as the solder heat-resistance evaluation. The results of the evaluations are shown in Table 16.

### Example 39

The solution (E-a) for forming the layer A was flow-casted and applied on a surface of a resin film (product name: AFLEX, manufactured by ASAHI GLASS CO., LTD.) serving as a supporter. Thereafter, the solution and the resin film were dried at 60° C. in the hot-air oven. Thus was obtained a material made of the layer A whose thickness was 2 μm/the supporter. The material and a prepreg (1) (product name: ES-3306S, manufactured by RISHO KOGYO CO., LTD.) prepared as a layer C were laminated with each other so as to form a laminate made of the supporter/the layer A/the prepreg/the layer A/the supporter, and the laminate was integrated at 170° C. under a pressure of 4 MPa for 2 hours. Thereafter, the supporters at both sides were detached from the laminate and the resulting laminate was dried at 180° C. for 30 minutes in the hot-air oven. Thus was obtained a laminate made of the layer A/the layer C whose thickness was 70 μm/the layer A.

Thereafter, a copper layer was formed on the layer A that was exposed. The copper layer was formed in such a manner that, after desmear and electroless copper plating, an electrolytic plating copper layer whose thickness was 18 μm was formed on the electroless plating copper. After the laminate was dried at 180° C. for 30 minutes, adhesiveness of the laminate was evaluated in the same manner as the adhesiveness evaluation. Further, a part of this sample was cut into a piece whose size was 15 mm by 30 mm, and solder heat-resistance of the piece was evaluated in the same manner as the solder heat-resistance evaluation. The results of the evaluations are shown in Table 16.

### Comparative Example 11

The solution (E-j) for forming the layer B was flow-casted and applied on a surface of a resin film (product name: SG-1, manufactured by PANAC) serving as a supporter. Thereafter, the solution and the supporter were dried at 60° C., 100° C., 120° C., and 150° C. in a hot-air oven. Thus was obtained a material for plating having a supporter that was made of the layer B whose thickness was 38 μm/the supporter. The layer B of the material for plating having the supporter and a copper-clad laminate (CCL-HL950K Type SK, manufactured by MITSUBISHI GAS CHEMICAL COMPANY. INC.) were caused to face each other and the material for plating and the copper-clad laminate were heated and pressurized at 170° C. under a pressure of 1 MPa in a vacuum. Thereafter, the supporter was detached and the material for plating and the copper-clad laminate were dried at 180° C. for 60 minutes in a hot-air oven. Thus, a laminate was obtained. Thereafter, a copper layer was formed on the surface of the layer B that was exposed. The copper layer was formed in such a manner that, after desmear and electroless copper plating, an electrolytic copper layer whose thickness was 18 μm was formed on the electroless plating copper. The laminate was dried at 180° C. for 30 minutes and then adhesiveness of the laminate was measured in the same manner as the adhesiveness evaluation as described above. Further, a part of this sample was cut into a piece whose size was 15 mm by 30 mm, and solder heat-resistance of the piece was evaluated in the same manner as the solder heat-resistance evaluation. The results of the evaluations are shown in Table 17.

TABLE 16

| | | Ex. | Ex. | Ex. | Ex. | Ex. | Ex. | Ex. | Ex. | Ex. |
|---|---|---|---|---|---|---|---|---|---|---|
| | | 31 | 32 | 33 | 34 | 35 | 36 | 37 | 38 | 39 |
| Solution for | | (E-a) | (E-b) | (E-c) | (E-d) | (E-f) | (E-g) | (E-a) | (E-a) | (E-a) |
| forming layer A | | | | | | | | | | |
| Solution for | | (E-j) | (E-j) | (E-j) | (E-j) | (E-j) | (E-j) | — | (E-j) | — |
| forming layer B | | | | | | | | | | |
| Solution C | | — | — | — | — | — | — | (k) | (k) | (l) |
| Structure | | Layer A/ | Layer A/ | Layer A/ | Layer A/ | Layer A/ | Layer A/ | Layer A/ | Layer A/ | Layer A/ |
| | | layer B | layer B | layer B | layer B | layer B | layer B | layer C/ | layer C/ | layer C/ |
| | | | | | | | | layer A | layer B | layer A |
| Adhesive | Ordinary | 12 | 12 | 11 | 12 | 12 | 12 | 11 | 11 | 12 |
| strength | state | | | | | | | | | |
| (N/cm) | After | 8 | 8 | 7 | 8 | 8 | 8 | 6 | 6 | 7 |
| | PCT | | | | | | | | | |

| | | | | | | | | | |
|---|---|---|---|---|---|---|---|---|---|
| Solder | ◯ | ◯ | ◯ | ◯ | ◯ | ◯ | ◯ | ◯ | ◯ |
| heat-resistance | | | | | | | | | |

TABLE 17

| | | Com. Ex. 11 |
|---|---|---|
| Solution for forming layer A | | — |
| Solution for forming layer B | | (E-j) |
| Layer C | | — |
| Structure | | layer B |
| Adhesive | Ordinary state | 3 |
| strength | After PCT | 1 |
| (N/cm) | | |

| | |
|---|---|
| Solder heat-resistance | X |

### INDUSTRIAL APPLICABILITY

The material for plating of the present invention has high adhesiveness with resin materials as well as with electroless plating films. Further, even when the material for plating has low surface roughness, the material for plating has high adhessiveness with electroless plating films and resin materials, and further has excellent solder heat-resistance. Consequently, the material for plating is preferably applicable to manufacture etc. of printed wiring boards that require formation of fine wires. Therefore, the present invention is preferably applicable not only to material processing industries and chemical industries that deal with resin compositions and adhesives, but also to industrial fields that deal with electronic members.

Specifically, the present invention is preferably applicable to: functional plating for plastics, glasses, ceramics, timbers etc.; ornamental plating for members such as grills and marks of cars and knobs of home electric appliances; and manufacture of printed wiring boards in particular. Further, the present invention is applicable to printed wiring boards such as flexible printed wiring boards, rigid printed wiring boards, multi-layered flexible printed wiring boards, and build-up wiring boards that require formation of fine wires.

1. A material for plating, comprising a resin layer to be subjected to electroless plating,
the resin layer containing polyimide resin having at least a siloxane structure, and
a thermosetting component,
the polyimide resin being obtained by causing an acid dianhydride component to react with a diamine component containing diamine represented by general formula (1): 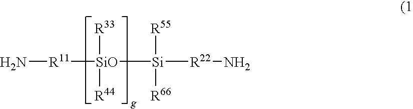
where g is an integer of 1 or more, R¹¹ and R²² are identical with each other or are different from each other and are selected from a C1-C6 alkylene group and a C1-C6 phenylene group, and R³³, R⁴⁴, R⁵⁵, and R⁶⁶ are identical with one another or are different from one another and are selected from a C1-C6 alkyl group, a C1-C6 phenyl group, a C1-C6 alkoxy group, and a C1-C6 phenoxy group.

2. The material for plating as set forth in claim 1, wherein the polyimide resin is made of a diamine component having 1 to 49 mol % of the diamine represented by general formula (1) with respect to all diamines.

3. (canceled)

4. The material for plating as set forth in claim 1, wherein the thermosetting component contains an epoxy resin component including an epoxy compound and a curing agent.

5. The material for plating as set forth in claim 1, wherein the polyimide resin has a glass-transition temperature ranging from 100 to 200° C.

6. The material for plating as set forth in claim 5, wherein the polyimide resin contains 10 to 75 mol % of the diamine represented by general formula (1) with respect to all diamines.

7. The material for plating as set forth in claim 1, wherein the polyimide resin has a weight-average molecular weight Mw of 30000 to 150000 as determined by gel permeation chromatography.

8. The material for plating as set forth in claim 1, wherein the polyimide resin contains a functional group and/or a group obtained by protecting the functional group.

9. The material for plating as set forth in claim 8, wherein the functional group is at least one selected from a hydroxyl group, an amine group, a carboxyl group, an amide group, a mercapto group, and a sulfonic acid group.

10. The material for plating as set forth in claim 1, wherein the electroless plating is electroless copper plating.

11. The material for plating as set forth in claim 1, further comprising one or more layers other than the resin layer, the material for plating including at least two layers as a whole.

12. The material for plating as set forth in claim 11, wherein said one or more layers is a macromolecule film layer, and the resin layer to be subjected to electroless plating is formed on at least one surface of the macromolecule film layer.

13. The material for plating as set forth in claim 11, wherein said one or more layers are a macromolecule film layer and an adhesive layer, the resin layer to be subjected to electroless plating is formed on at least one surface of the macromolecule film layer, and the adhesive layer is formed on the other surface of the macromolecule film layer.

14. The material for plating as set forth in claim 12, wherein the macromolecule film layer is a non-thermoplastic polyimide film.

15. A single layer sheet, prepared from a material for plating as set forth in claim 1, the sheet being made only of the resin layer.

16. An insulating sheet, comprising a material for plating as set forth in claim 11.

17. A laminate, obtained by laminating an electroless plating layer on a material for plating as set forth in claim 1.

18. A printed wiring board, comprising a material for plating as set forth in claim 1.

19. The printed wiring board as set forth in clam 18, wherein, in a case where surface roughness of the resin layer is less than 0.5 μm represented in arithmetic mean roughness Ra as measured at a cutoff value of 0.002 mm, adhesive strength at 150° C. between the resin layer and a plating layer is 5N/cm or more.

20. A solution for forming a resin layer to be subjected to electroless plating, comprising one selected from (i) polyimide resin having at least a siloxane structure and (ii) polyamide acid that is a precursor of the polyimide resin,
a thermosetting component,
the polyimide resin being obtained by causing an acid dianhydride component to react with a diamine component containing diamine represented by general formula (1): 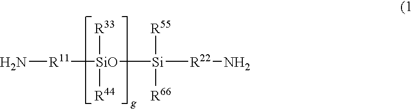
where g is an integer of 1 or more, R¹¹ and R²² are identical with each other or are different from each other and are selected from a C1-C6 alkylene group and a C1-C6 phenylene group, and R³³, R⁴⁴, R⁵⁵, and R⁶⁶ are identical with one another or are different from one another and are selected from a C1-C6 alkyl group, a C1-C6 phenyl group, a C1-C6 alkoxy group, and a C1-C6 phenoxy group.

21. The solution as set forth in claim 20, wherein the polyimide resin is made of a diamine component having 1 to 49 mol % of the diamine represented by general formula (1) with respect to all diamines.

22. (canceled)

23. The solution as set forth in claim 20, wherein the thermosetting component contains an epoxy resin component including an epoxy compound and a curing agent.

24. The solution as set forth in claim 20, wherein the polyimide resin has a glass-transition temperature ranging from 100 to 200° C.

25. The solution as set forth in claim 24, wherein the polyimide resin contains 10 to 75 mol % of the diamine represented by general formula (1) with respect to all diamines.

26. The solution as set forth in claim 20, wherein the polyimide resin has a weight-average molecular weight Mw of 30000 to 150000 as determined by gel permeation chromatography.

27. The solution as set forth in claim 20, wherein the polyimide resin contains a functional group and/or a group obtained by protecting the functional group.

28. The solution as set forth in claim 27, wherein the functional group is at least one selected from a hydroxyl group, an amine group, a carboxyl group, an amide group, a mercapto group, and a sulfonic acid group.
